(19) United States
(12) Patent Application Publication
(10) Pub. No.: US 2026/0178266 A1
(43) Pub. Date: Jun. 25, 2026

(54) DISPLAY DEVICE AND PROCESSING METHOD FOR DISPLAY DEVICE

(71) Applicant: HISENSE VISUAL TECHNOLOGY CO., LTD., Qingdao (CN)

(72) Inventors: Guili JIA, Qingdao (CN); Tao LI, Qingdao (CN); Xiaoming SHAO, Qingdao (CN); Jie FAN, Qingdao (CN)

(21) Appl. No.: 19/536,119

(22) Filed: Feb. 10, 2026

Related U.S. Application Data
(63) Continuation of application No. PCT/CN2024/100987, filed on Jun. 24, 2024.

(30) Foreign Application Priority Data
Aug. 24, 2023 (CN) 202311077897.3
Aug. 31, 2023 (CN) 202311117858.1
Aug. 31, 2023 (CN) 202311118112.2

(51) Int. Cl. G06F 3/16; H03G 3/02; H04N 21/439

(52) U.S. Cl. CPC G06F 3/165; H03G 3/02; H04N 21/4394

(57) ABSTRACT

The present application relates to a display device and a processing method of the display device. In a multi-window mode, in response to a command of a user, the display device can display a volume control button in a designated window. In response to a control command inputted by the user on the basis of the volume control button, the control command indicating a first trend of adjusting the volume, when it is identified that both the designated window and another window are playing audio/videos, the display device can adjust the amplitude ratio of the audio/video in the designated window on the basis of the first trend, and can adjust the amplitude ratio of the audio/video in another window on the basis of a second trend opposite to the first trend.

### CROSS-REFERENCE TO RELATED APPLICATIONS

The present application is a continuation application of PCT/CN2024/100987, filed on Jun. 24, 2024, which claims priority to Chinese patent applications No. 202311118112.2, filed on Aug. 31, 2023; No. 202311077897.3, filed on Aug. 24, 2023; and No. 202311117858.1, filed on Aug. 31, 2023, the entire contents of all of which are incorporated by reference herein.

### TECHNICAL FIELD

The present application relates to the technical field of display devices, and in particular to a display device and a processing method of the display device.

### BACKGROUND

Display devices refer to terminal devices that can output specific display images, which can be terminal devices such as smart televisions (TVs), mobile terminals, smart advertising screens, projectors, etc. Taking smart TVs as an example, smart TVs are based on Internet application technology, have open operating systems and chips, have open application platforms, can realize two-way human-computer interaction functions, and are TV products that integrate multiple functions such as audio or video, entertainment, and data to meet the diverse and personalized needs of users.

The display device is configured with multi-window modes, such as Picture-in-Picture (PiP) mode, Split-Screen mode, freeform window mode, etc. In multi-window mode, if the display device plays audio or video in each window, the display device will play the sounds of the multiple windows at the same time to present a mixed sound effect. When the user adjusts the volume, the display device adjusts the system volume. Therefore, when the user increases or decreases the volume, the display device increases or decreases the system volume, thereby increasing or decreasing the overall volume of the mixed sound of the multiple windows, that is, adjusting the volume of the sound of the multiple windows in the same direction. As a result, the user cannot adjust the volume of the sound of the multiple windows in different directions by adjusting the volume, and cannot adjust the mixed sound effect of the multiple windows.

### SUMMARY

A display device according to some embodiments of the present application can include: a display, configured to, in a first multi-window mode, display a first window and a second window, where the first window is displayed above the second window, the second window is in a full screen state, and a size of the first window is smaller than a size of the second window, where a first audio or video is played in the first window; a memory, configured to store computer instructions and/or data associated with the display device; and at least one processor, connected to the display and the memory, and configured to execute the computer instructions to cause the display device to: in response to detecting that a focus is on the first window, display a volume control button in the first window, where the volume control button includes a volume up key and a volume down key; receive a control command input by a user based on the volume control button, where the control command indicates a first trend of adjusting a volume, and the first trend is to increase the volume or decrease the volume; in response to the control command, identify whether an audio or video is played in the second window; and in response to identifying that a second audio or video is played in the second window, adjust an amplitude ratio of the first audio or video based on the first trend, and adjust an amplitude ratio of the second audio or video based on a second trend opposite to the first trend, where a sum of the adjusted amplitude ratio of the first audio or video and the adjusted amplitude ratio of the second audio or video is equal to a preset total ratio.

### BRIEF DESCRIPTION OF FIGURES

FIG. 1 is a usage scenario of a display device according to some embodiments of the present application.

FIG. 2 is a configuration block diagram of a control device according to some embodiments of the present application.

FIG. 3 is a configuration diagram of a display device according to some embodiments of the present application.

FIG. 4 is a configuration diagram of an operating system of a display device according to some embodiments of the present application.

FIG. 5A is a schematic diagram of a media architecture for multi-channel audio or video playback in a multi-window mode in an operating system of a display device according to some embodiments of the present application.

FIG. 5B is a schematic diagram of a media architecture for two-channel video playback in a PiP mode in an operating system of a display device according to some embodiments of the present application.

FIG. 5C is a schematic diagram of a system architecture related to enabling the PiP mode in the operating system of the display device according to some embodiments of the present application.

FIG. 5D is a schematic diagram of a system architecture related to displaying the PiP window in the operating system of the display device according to some embodiments of the present application.

FIG. 5E is a schematic diagram of a system architecture related to playback control of a video in the PiP window in the operating system of the display device according to some embodiments of the present application.

FIG. 5F is a schematic diagram of a system architecture related to multi-window mode switching in an operating system of a display device according to some embodiments of the present application.

FIG. 6 is a flowchart of a display device determining a decoder for decoding a first video before entering a PiP mode according to some embodiments of the present application.

FIG. 7 is a flowchart of a display device determining a decoder for decoding a first video when entering a PiP mode according to some embodiments of the present application.

FIG. 8 is a flowchart of a display device decoding a first video and a second video according to some embodiments of the present application.

FIG. 9 is a flowchart of a display device acquiring a hardware decoder that supports decoding of a second video according to some embodiments of the present application.

FIG. 10 is a flowchart of a display device decoding a first video and a second video according to some embodiments of the present application.

FIG. 11 is a flowchart of a display device decoding a first video according to some embodiments of the present application.

FIG. 12 is a flowchart of a display device returning a first hardware decoder and decoding a first video according to some embodiments of the present application.

FIG. 13 is a schematic diagram of Example 1 according to some embodiments of the present application.

FIG. 14 is a flowchart of a display device adjusting a volume when entering a first multi-window mode according to some embodiments of the present application.

FIG. 15 is a flowchart of a display device acquiring applications in a first window and a second window according to some embodiments of the present application.

FIG. 16 is a flowchart of a display device displaying a volume control button within a first window according to some embodiments of the present application.

FIG. 17 is a flowchart of a display device adjusting a volume according to some embodiments of the present application.

FIG. 18 is a flowchart of a display device adjusting a ratio of an amplitude of the first audio or video and a ratio of an amplitude of a second audio or video according to some embodiments of the present application.

FIG. 19 is a flowchart of a display device displaying a volume according to some embodiments of the present application.

FIG. 20 is a schematic diagram of Example 2 according to some embodiments of the present application.

FIG. 21 is a flowchart of a display device adjusting a volume according to some embodiments of the present application.

FIG. 22 is a flowchart of a display device displaying a volume control menu according to some embodiments of the present application.

FIG. 23 is a schematic diagram of Example 3 of a display device according to some embodiments of the present application.

FIG. 24 is a flowchart of a display device adjusting a volume according to some embodiments of the present application.

FIG. 25 is a schematic diagram of Example 4 of a display device according to some embodiments of the present application.

FIG. 26 is a flowchart of a display device enabling a PiP mode according to some embodiments of the present application.

FIG. 27 is a flowchart of a display device enabling a PiP mode according to some embodiments of the present application.

FIG. 28 is a flowchart of a display device identifying whether a first page supports the PiP mode according to some embodiments of the present application.

FIG. 29 is an interactive schematic diagram of a display device enabling a PiP mode according to some embodiments of the present application.

FIG. 30 is an interactive schematic diagram of a display device enabling a PiP mode according to some embodiments of the present application.

FIG. 31 is an interactive schematic diagram of a display device enabling a PiP mode according to some embodiments of the present application.

FIG. 32 is an interactive schematic diagram of a display device enabling a PiP mode according to some embodiments of the present application.

FIG. 33 is a flowchart of a display device enabling a PiP mode according to some embodiments of the present application.

FIG. 34 is an interactive schematic diagram of a display device switching to display a page in a PiP mode according to some embodiments of the present application.

FIG. 35 is an interactive schematic diagram of a display device switching to display a page in a PiP mode according to some embodiments of the present application.

FIG. 36 is a flowchart of a display device displaying a PiP window according to some embodiments of the present application.

FIG. 37 is a flowchart of a display device shrinking a first window according to some embodiments of the present application.

FIG. 38 is a flowchart of a display device displaying a PiP window when entering a PiP mode according to some embodiments of the present application.

FIG. 39 is an interactive schematic diagram of a display device displaying a PiP window when entering a PiP mode according to some embodiments of the present application.

FIG. 40 is a flowchart of a display device displaying a PiP window after switching according to some embodiments of the present application.

FIG. 41 is an interactive schematic diagram of a display device displaying a PiP window after switching on according to some embodiments of the present application.

FIG. 42 is a flowchart of a display device adjusting a size of a PiP window according to some embodiments of the present application.

FIG. 43 is a flowchart of a display device adjusting a size of a PiP window according to some embodiments of the present application.

FIG. 44 is a flowchart of a display device adjusting a size of a PiP window according to some embodiments of the present application.

FIG. 45 is a flowchart of a display device adjusting a PiP window according to some embodiments of the present application.

FIG. 46 is an interactive schematic diagram of a display device adjusting a PiP window according to some embodiments of the present application.

FIG. 47 is an interactive schematic diagram of a display device adjusting a PiP window according to some embodiments of the present application.

FIG. 48 is a schematic diagram of a PiP menu according to some embodiments of the present application.

FIG. 49 is a flowchart of a display device displaying a PiP window according to some embodiments of the present application.

FIG. 50 is a flowchart of a display device displaying a playback control button according to some embodiments of the present application.

FIG. 51 is a flowchart of a display device identifying whether a first page is a video page according to some embodiments of the present application.

FIG. 52 is a flowchart of a display device obtaining a package name of a first application according to some embodiments of the present application.

FIG. 53 is a flowchart of a display device obtaining information of a top-level PiP application according to some embodiments of the present application.

FIG. 54 is a flowchart of a display device displaying a playback control menu according to some embodiments of the present application.

FIG. 55 is a flowchart of a display device displaying different playback control buttons according to some embodiments of the present application.

FIG. 56 is an interactive schematic diagram of a display device displaying a PiP window according to some embodiments of the present application.

FIG. 57 is an interactive schematic diagram of a display device displaying a PiP window according to some embodiments of the present application.

FIG. 58 is a flowchart of a display device implementing playback control for a video based on a playback control button according to some embodiments of the present application.

FIG. 59 is a flowchart of a display device implementing playback control for a video according to some embodiments of the present application.

FIG. 60 is an interactive schematic diagram of a display device updating a playback control button according to some embodiments of the present application.

FIG. 61 is a flowchart of a display device updating a playback control button according to some embodiments of the present application.

FIG. 62 is a flowchart of a display device switching to a multi-window mode according to some embodiments of the present application.

FIG. 63 is a flowchart of a display device entering a first multi-window mode according to some embodiments of the present application.

FIG. 64 is a flowchart of a display device controlling an application in a first window according to some embodiments of the present application.

FIG. 65 is a flowchart of a display device switching from a second multi-window mode to a first multi-window mode according to some embodiments of the present application.

FIG. 66 is a flowchart of a display device switching to a multi-window mode according to some embodiments of the present application.

FIG. 67 is an interactive schematic diagram of a display device switching to a multi-window mode according to some embodiments of the present application.

FIG. 68 is a flowchart of a display device entering a second multi-window mode according to some embodiments of the present application.

FIG. 69 is an interactive schematic diagram of a display device switching to a multi-window mode in some embodiments of the present application.

### DETAILED DESCRIPTION

The following embodiments are described in detail, and examples thereof are shown in the accompanying drawings. When the following description refers to the drawings, unless otherwise indicated, the same numbers in different drawings represent the same or similar elements. The implementations described in the following embodiments do not represent all implementations consistent with the present application. They are only examples of systems and methods consistent with some aspects of the present application as detailed in the claims.

It should be noted that the brief description of terms in the present application is only for the convenience of understanding the embodiments described below, and is not intended to limit the embodiments of the present application. Unless otherwise specified, these terms should be understood according to their common and usual meanings.

The terms “first”, “second”, “third”, etc., in the specification and claims of the present application and the above drawings are used to distinguish similar or similar objects or entities, and do not necessarily mean to limit a specific order or sequence, unless otherwise noted. It should be understood that the terms used in this way can be interchangeable under appropriate circumstances.

The terms “includes”, “including”, and “having”, and any variations thereof, are intended to cover but not exclude inclusion, for example, a product or device including a list of components is not necessarily limited to all the components expressly listed but may include other components not expressly listed or inherent to such product or device.

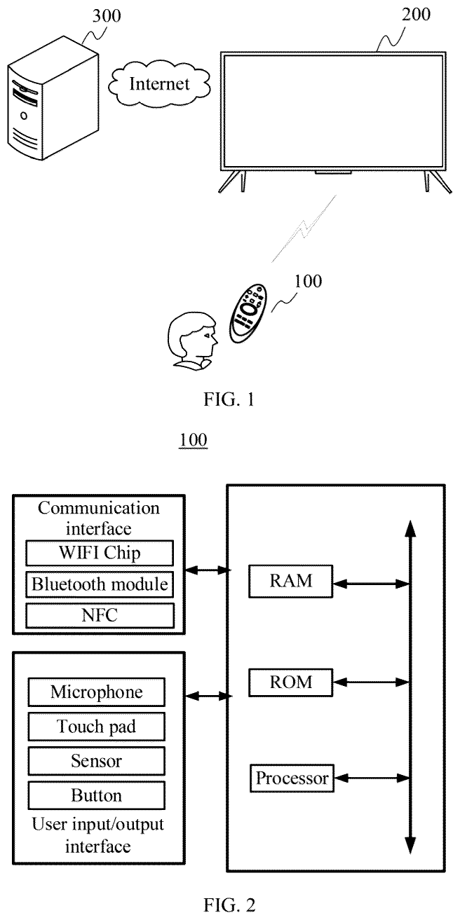

The display device provided in the embodiments of the present application may have various implementation forms, for example, it may be a television, a laser projection device, a monitor, an electronic whiteboard, an electronic table, etc., or it may be a device with a display screen such as a mobile phone, a tablet computer, a smart watch, etc. FIG. 1 and FIG. 2 are a specific implementation of the display device of the present application.

FIG. 1 is a schematic diagram of a usage scenario of a display device according to some embodiments of the present application. As shown in FIG. 1, a user can operate a display device 200 through a control device 100, and the display device 200 can obtain network data through a server 300, or obtain a live broadcast signal through a satellite.

FIG. 2 is a block diagram of a configuration of a control device according to some embodiments of the present application. In some embodiments, the control device 100 may be a remote controller, and the communication between the remote controller and the display device 200 may include at least one of infrared protocol communication, or Bluetooth protocol communication, or other short-range communication manners, to control the display device 200 wirelessly or wired. The user may input user commands through buttons on the remote controller, voice input, control panel input, etc., to control the display device 200.

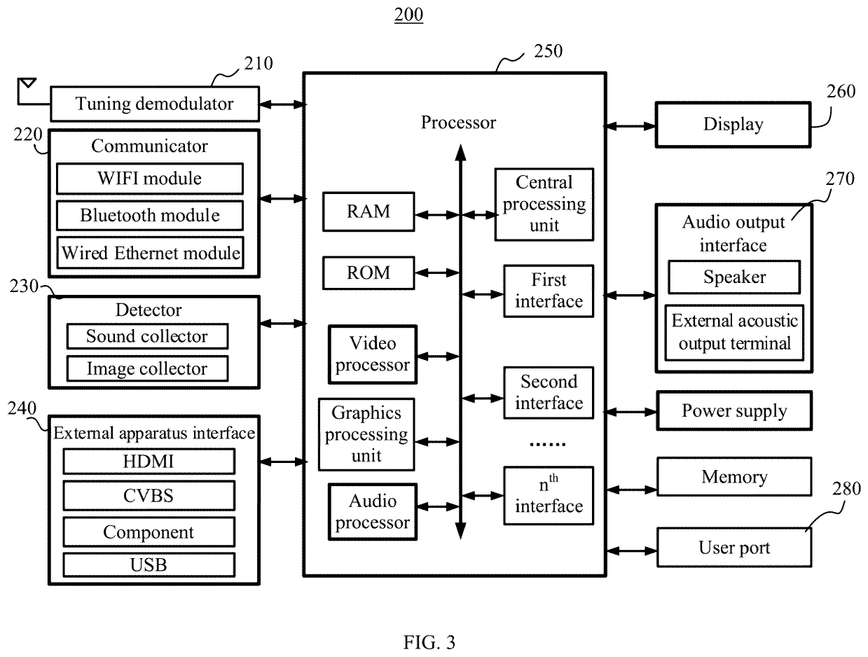

FIG. 3 is a configuration block diagram of a display device according to some embodiments of the present application.

The display device 200 includes at least one of a tuning demodulator 210, a communicator 220, a detector 230, an external apparatus interface 240, at least one processor 250, a display 260, an audio output interface 270, a memory, a power supply, or a user interface 280.

In some embodiments, the display device 200 can establish transmission and reception of control signals and data signals with the control device 100 or the server 300 through the communicator 220.

In some embodiments, the detector 230 may include a sound collector. The display device 200 may collect user voices through the sound collector and transmit the collected user voices to the at least one processor 250 for processing.

In some embodiments, at least one processor 250 and tuning demodulator 210 may be located in different separate devices, that is, tuning demodulator 210 may also be located in an external device, such as an external set-top box, of the main device where at least one processor 250 is located. In some embodiments, at least one processor 250 controls the operation of the display device and responds to user operations through various software control programs stored in the memory. At least one processor 250 controls the overall operation of the display device 200.

In some embodiments, the processor may include at least one of a central processing unit (CPU), a video processor, an audio processor, a graphics processing unit (GPU), a random access memory (RAM), a read-only memory (ROM), a first interface to an n^{th} interface for input/output, or a communication bus (Bus), etc.

In some embodiments, the display 260 may include a display screen component for presenting images, a driving component for driving image display, and a component for receiving an image signal outputted from at least one processor 250 to display video content, image content, and a menu control interface and a user control UI interface. In some embodiments, the display 260 may be a liquid crystal display, an organic light-emitting diode (OLED) display, and a projection display, and may also be a projection apparatus and a projection screen.

In some embodiments, the user may input a user command in a graphical user interface (GUI) displayed on the display 260, and the user input interface receives the user input command through the graphical user interface (GUI). Alternatively, the user may input a user command by inputting a specific sound or gesture, and the user input interface recognizes the sound or gesture through a sensor to receive the user input command. In some embodiments, the “user interface” is a medium interface for interaction and information exchange between an application or an operating system and a user, which realizes the conversion between the internal form of information and the form acceptable to the user. The commonly used form of the user interface is a graphical user interface (GUI), which refers to a user interface related to computer operations displayed in a graphical manner. It can be an interface element such as an icon, a window, a control, etc., displayed on the display screen of an electronic device, where the control may include at least one of the visual interface elements such as icons, buttons, menus, tabs, text boxes, dialog boxes, state bars, navigation bars, or widgets, etc.

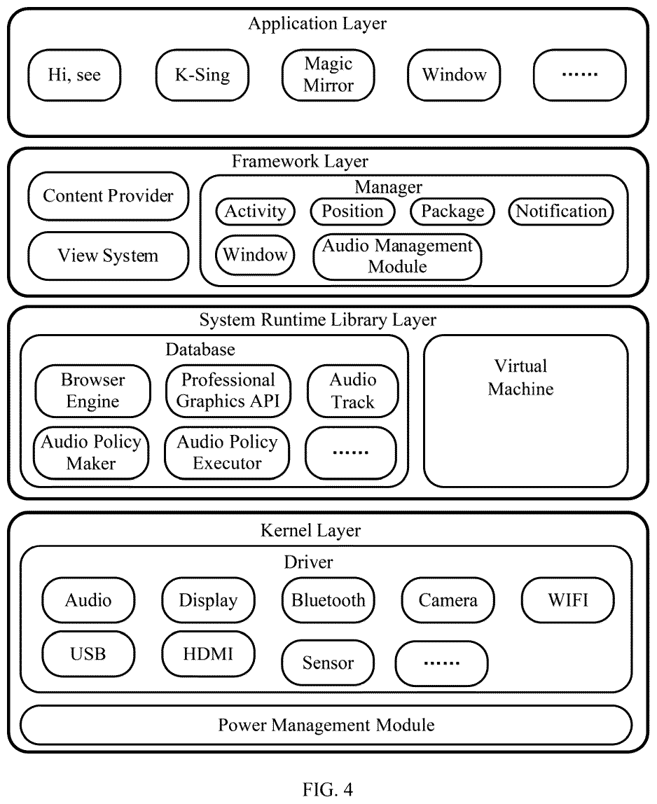

Referring to FIG. 4, in some embodiments, the operating system of the display device 200 can be divided into four layers, which are respectively the application layer (hereinafter referred to as the “application layer”), the application framework layer (hereinafter referred to as the “framework layer”), the Android runtime and the system library layer (hereinafter referred to as the “system runtime library layer”), and the kernel layer from top to bottom. In some embodiments, at least one application can be run in the application layer, and these applications can be window programs, system setting programs, or clock programs that come with the operating system, such as live broadcast applications, which can be used to play live programs; or they can be applications developed by third-party developers.

In some embodiments, the display device may be configured with a variety of multi-window modes, such as a picture-in-picture (PiP) mode, a split-screen mode, a freeform window mode, etc. In a multi-window mode, the display device may display at least two windows at the same time, and may display pages in the at least two windows respectively, so that the user can browse pages in multiple windows at the same time. For example, the display device 200 may play videos in the at least two windows respectively, and the user may watch multiple videos at the same time.

Compared with non-multi-window mode, when the display device plays audio or video in multi-window mode, it is necessary to coordinate the playback effects, such as image quality, volume, etc., of the audio or video played in each window, so that the overall effect of the audio or video played in each window can better meet the needs of users.

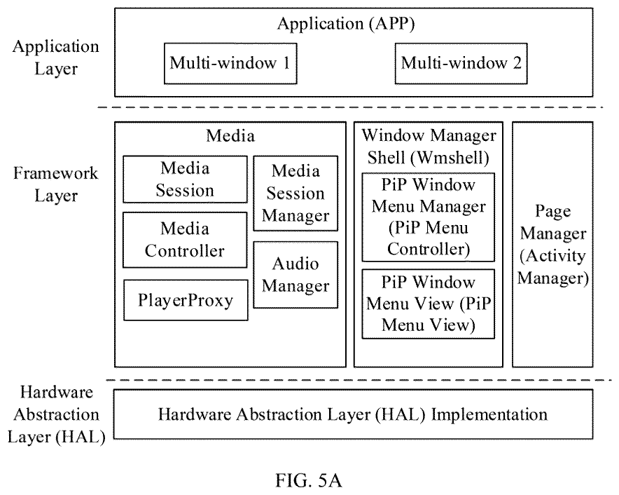

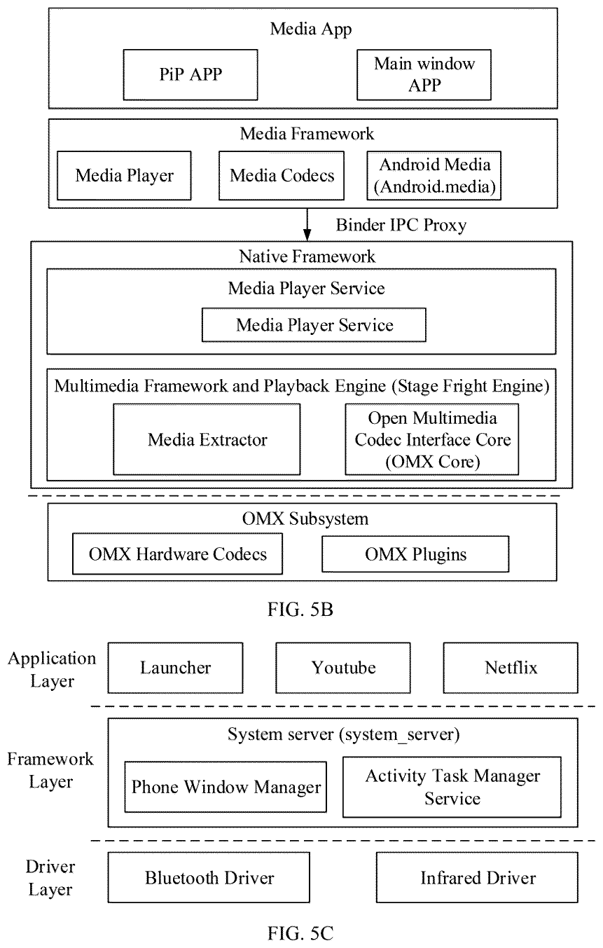

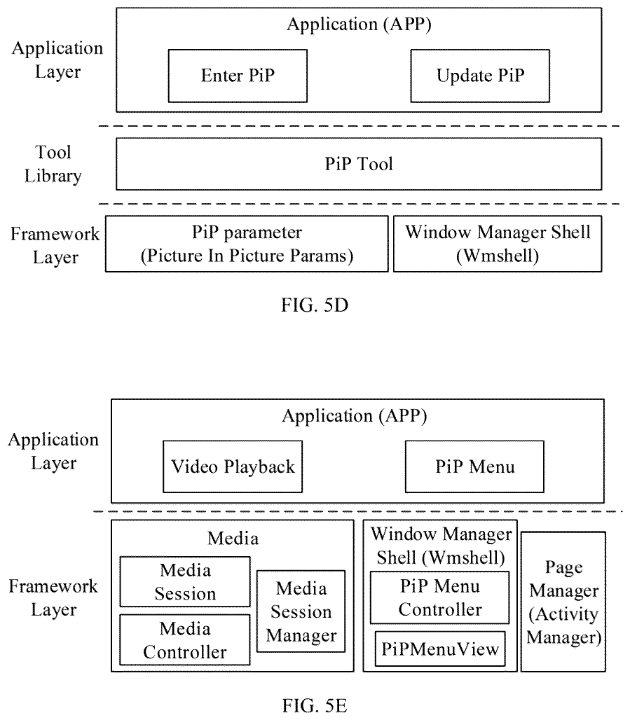

FIG. 5A is a schematic diagram of a media architecture for multi-channel audio or video playback in a multi-window mode in an operating system of a display device according to some embodiments of the present application. As shown in FIG. 5A, the media architecture mainly involves an application layer, a framework layer, and a system runtime library layer. The application layer may include the application(s) displayed in each window. The framework layer may include a media module, a window manager shell (Wmshell) and a page manager (Activity Manager). The Media module may include a media session, a media session manager, a media controller, an audio manager and a player proxy. Wmshell may include a window menu manager, such as a PiP window menu manager (e.g., PiP Menu Controller), and may also include a window menu view, such as a PiP window menu view (PiP Menu View). The system runtime library layer may include a hardware abstraction layer (HAL) implementation.

The Activity Manager is responsible for determining the top-level application in each of windows, distinguishing the windows, and controlling the volumes of the window respectively. The Activity Manager can obtain the package name from Running Task Info, and obtain the Running Process Info list through the method of getRunningAppProcesses, and obtain the Process ID (PID) consistent with the package name of Running Task Info from the Running Process Info list. The Media Session Manager can be used to obtain the media controller list that is active in the system. If the list includes the top-level application in each window, it means that the window is playing audio or video. The window menu controller can be used to control the window menu. When determining that the audio or video is played in the window, the window menu controller can automatically add a volume adjustment button in the window menu view. The Audio Manager can be used to obtain the active Audio Playback Configuration list, and the corresponding PID and player proxy can be obtained based on the audio playback configuration list. The package name is obtained according to the PID and Running Task Info list, and thus the Audio Playback Configuration object of each window is obtained. Then, the player proxy object corresponding to each window can be determined through the Audio Playback Configuration object. The player proxy object can provide an interface for adjusting the sound. Therefore, through the sound adjustment interface corresponding to each window, the volume of the corresponding window can be adjusted separately.

FIG. 5B is a schematic diagram of a media architecture for playing videos in two channels in the PiP mode in the operating system of a display device according to some embodiments of the present application. As a specific implementation of the media architecture shown in FIG. 5A, as shown in FIG. 5B, the media architecture also mainly involves an application layer, a framework layer, and a system runtime library layer, where the application layer may include applications displayed in the main window and the PiP window. The framework layer may also include a media framework and a native framework, and the media framework may include a media player, a media codec, and Android media. The native framework may include a media player service and a multimedia framework and a playback engine (Stage Fright Engine), and the multimedia framework and the playback engine may include a media extractor and an open multimedia codec interface core (Open Max Core, OMX Core). The system runtime library layer may also include an OMX subsystem, and the OMX subsystem may include an OMX hardware codec and an OMX plug-in. The application in the PiP window and the application in the main window can request to play the video through the application programming interface (API) of the media framework. The media framework can call the interface of the local framework through inter-process communication (IPC). The media player service creates a media player instance, and the video playback can be controlled through the media player instance. The media codec provides the ability to access the Android underlying codec, and the Stage Fright Engine is the underlying implementation of the media architecture.

5C is a schematic diagram of a system architecture related to enabling PiP mode in an operating system of a display device according to some embodiments of the present application. As shown in FIG. 5C, the system architecture related to enabling PiP mode mainly involves an application layer, a framework layer, and a driver layer. The driver layer may include a Bluetooth driver and an infrared driver. The system service (system_server) of the framework layer includes a phone window manager (PhoneWindowManager) class and a page task manager service (ActivityTaskManagerService). The application layer may also include various applications, such as a launcher, Youtube, Netflix, etc. Based on the system architecture shown in FIG. 5C, the display device can configure a designated entry supported by the operating system for each application to enable PiP mode. The designated entry is independent of the application itself and is not affected by the application itself, that is, the designated entry can be a unified entry for each application to enable PiP mode.

FIG. 5D is a schematic diagram of a system architecture related to displaying a PiP window in an operating system of a display device according to some embodiments of the present application. As shown in FIG. 5D, the system architecture related to displaying a PiP window mainly involves an application layer, a tool library, and a framework layer. The application layer may include an application that enables PiP mode, such as an application that supports a designated entry of an operating system configured to enable PiP mode for each application in the system architecture shown in FIG. 5C. The tool library may include a PiP tool, which is a layer of encapsulation for an application to enter PiP mode, and is a bridge connecting the application layer and the framework layer. Based on the media architecture shown in FIG. 5A, in the system architecture shown in FIG. 5D, the framework layer may also include a PiP parameter (Picture In Picture Params) class. Wmshell can provide a set of toolkits for more efficient management of windows, which can be located in the directory of framework/base/libs/WindowManager. Wmshell provides various window management tool sub-packages, such as PiP sub-packages, SplitScreen sub-packages, FreeForm sub-packages, Compatibility User Interface (CompatUI), desktop mode, etc.

Based on the system architecture shown in FIG. 5D, in some embodiments of the present application, the PiP parameter class, the PiP tool, and the Wmshell are customized (see the subsequent content for details). New width and height size (hereinafter referred to as width and height) attributes and corresponding methods for setting the attributes are added to the PiP parameter class, so that when the current page enters the PiP mode, the screen size required for displaying it in the PiP window can be passed to the PiP parameter class. Methods related to setting the size of the PiP window are provided for the PiP tool to pass the screen size passed by the application to the PiP parameter class to Wmshell. Wmshell is customized to be able to draw the PiP window based on the screen size passed in by the PiP tool.

FIG. 5E is a schematic diagram of a system architecture related to the playback control of a video in a PiP window in an operating system of a display device according to some embodiments of the present application. As shown in FIG. 5E, the system architecture related to the playback control of a video in a PiP window mainly involves an application layer and a framework layer. The application layer may include an application displayed in the PiP mode, and video playback, display of a playback control menu, etc., may be implemented in the application layer. An application displayed in a PiP window may be an application that can draw a PiP window based on the screen size by customizing the PiP parameter class, PiP tool, and Wmshell in the system architecture shown in FIG. 5D.

Based on the media architecture shown in FIG. 5A, in the framework layer of the system architecture shown in FIG. 5E, the Media Session Manager included in the Media module can query all currently active Media Controllers in the system by obtaining an active media controller list in the system, and can also provide interactive support with the Media Session. The Media Session can also provide interactive support with the Media Controller. The Media Controller can implement playback control, such as play, pause, stop, fast forward and rewind, for audio or video. The Wmshell part can customize the menu function of PiP, and the corresponding playback control menu can be displayed when the video is played in the PiP window. The Activity Manager can also be used to manage the PiP window and interact with Wmshell for playback control.

FIG. 5F is a schematic diagram of a system architecture related to multi-window mode switching in an operating system of a display device according to some embodiments of the present application. As shown in FIG. 5F, the system architecture related to multi-window mode switching mainly involves an application layer and a framework layer. The application layer may include applications that support the multi-window mode, such as App 1 and App 2, such as applications that support PiP mode and applications that support split-screen mode.

The application layer may also include a multi-screen (MultiScreen) module. The multi-screen module can be used to implement the core function of multi-window mode switching. The multi-screen module may include a multi-screen receiver (Multi Screen Receiver), a multi-screen service (Multi Screen Service), a focus manager (Focus Manager), an application manager (App Manager) and a multi-window manager (Multi Window Manager). The multi-screen receiver can be used to receive a control command indicating a multi-window mode and start the foreground multi-screen service. The multi-screen service is a core service. After receiving the broadcast of the multi-screen receiver, the multi-screen service can determine the current working mode, such as multi-window mode or non-multi-window mode, of the application. Since the multi-window mode is enabled by the multi-screen service, the multi-screen service itself can save the multi-window mode that the application is currently in. The multi-window mode may include the PiP mode and split-screen mode. The multi-screen service can trigger the next working mode based on the current working mode of the application. The focus manager can be used to manage the manager of the window focus. Through the obtained page information (Activity info), the focus manager can control the window focus in the split-screen mode. The application manager can be used to manage applications that support split-screen. The application manager can obtain page information, such as stack, activity, etc. The multi-window manager is the main manager for multi-window management and can be used to switch windows between the PiP mode and split-screen mode.

The framework layer may include a phone window manager, a page manager (Activity Manager), and a window manager. The phone window manager can be used to receive control commands, such as through a split-screen button, indicating multi-window mode and convert it into a broadcast to send to a multi-screen receiver in the multi-screen. The page manager is a Manager class that the system can use to manage Activities. Through this class, the application manager can obtain relevant information, such as package name, activity, activity stack, etc., about App 1 and App 2 that support split screens. The window manager can be used to manage application windows. The switching of windows in the PiP mode and split-screen mode is controlled and processed by the window manager.

After introducing the system/media architecture in some embodiments of the present application, the following first mainly describes the two aspects of the image quality and sound effects of coordinating the playback of audio or video in multi-window mode, and then describes the volume adjustment, enabling the PiP mode, displaying the PiP window, video playback in the PiP window, and multi-window mode switching in multi-window in turn.

First, the image quality of playing audio or video in coordinated multi-window mode is explained.

In the split-screen mode or the free-window mode, the display device can display multiple windows at the same time. There may be no overlapping relationship between the multiple windows. The display positions of the windows in the display may be relatively uniform, and the sizes of the windows are usually slightly different. Therefore, if the multiple windows play videos at the same time, the image quality of the video in each window will have little impact on the user's viewing experience. Based on this, in the split-screen mode or the free-window mode, it is difficult for the display device to determine the image quality of the video in which window or windows has a greater impact on the user's viewing experience. Usually, the user customizes the window of special concern, and the display device improves the playback quality of the video in the window to improve the user's viewing experience.

In the PiP mode, the display device can display two windows at the same time, and the two windows may include a main window and a PiP window. In some embodiments, the size of the PiP window is smaller than that of the main window, and the PiP window is usually displayed near the edge, such as the top corner, the middle frame, etc., of the display. Therefore, if the two windows play videos at the same time, the image quality of the video in the main window is more likely to affect the user's viewing experience. Based on this, the display device can be configured to default to the image quality of the video in the main window having a greater impact on the user's viewing experience, and can improve the user's viewing experience by improving the playback quality of the video in the main window. Based on the above analysis, some embodiments of the present application mainly focus on the description of how the display device improves the image quality of the main window to improve the user's viewing experience in the PiP mode.

When playing a video, the display device may first use a decoder to decode the video, and then play the decoded video. The stronger the decoding capability of the decoder, the higher the image quality of the decoded video. Generally, the display device may be configured with a hardware decoder and a software decoder, where the hardware decoder has a stronger decoding capability, while the software decoder has a stronger decoding flexibility. In order to ensure the image quality of the video, the display device gives priority to using the hardware decoder to decode the video. Therefore, when the display device enters the PiP mode, the hardware decoder may be used to decode the video in the PiP window to ensure the image quality of the video in the PiP window. If the display device plays a video in the main window after entering the PiP mode, and the hardware decoder that supports decoding of the video played in the main window is the same as the hardware decoder that decodes the video in the PiP window, the decoder is allocated to the video in the main window in a competitive or yield manner. If the hardware decoder is allocated in a competitive manner, and the main window fails to compete successfully, the display device may allocate the software decoder to the video in the main window. Since the decoding capability of the software decoder is weak, the image quality of the video in the main window will be reduced. If the hardware decoder is allocated in a yield manner, the PiP window will not be able to use the hardware decoder for decoding normally, resulting in the video in the PiP window not being able to be played normally.

The display device according to some embodiments of the present application may include: a display, which can be configured to: in the PiP mode, display a first window (such as the aforementioned PiP window) and a second window (such as the aforementioned main window), where the size of the first window may be smaller than the second window, and the second window may be in the full screen state, a first video may be played in the first window, and no video may be played in the second window, and the first video may be decoded by a first hardware decoder; a memory, which can be configured to store computer instructions and/or data associated with the display device; and at least one processor, connected to the display and the memory, and configured to execute computer instructions to cause the display device to: when a second video can be played in the second window, obtain a hardware decoder supporting decoding of the second video, where the hardware decoder supporting decoding of the second video may be preferentially used to decode the second video; if the hardware decoder supporting decoding of the second video is the first hardware decoder, and the first hardware decoder does not support multi-channel decoding, use the first hardware decoder to decode the second video, and allocate a first software decoder to the first video, and use the first software decoder to decode the first video. In this way, the display device can automatically and dynamically allocate decoders for the video in the main window and the video in the PiP window to ensure the image quality of the video in the main window and the normal playback of the video in the PiP window.

Based on the media architecture shown in FIG. 5B, a processing method of a display device according to some embodiments of the present application is mainly used for video decoding. Based on this method, when the display device is in the PiP mode, and videos are played in both the PiP window and the main window, a hardware decoder can be preferentially allocated to the video in the main window, and when the hardware decoder allocated to the video in the main window conflicts with the hardware decoder originally used for the video in the PiP window, a software decoder can be switched to be used for the video in the PiP window, thereby ensuring the playback quality of the video in the main window and the normal playback of the video in the PiP window.

Before entering the PiP mode, the display device has created the first window and the second window. The first window may be located above the second window. For example, the first window and the second window may be located in one layer, and the window level of the first window may be higher than the window level of the second window. Alternatively, the first window and the second window may be located in different layers, and the level of the layer to which the first window belongs may be higher than the level of the layer to which the second window belongs. The first window is in the full screen state, and the second window may also be in the full screen state. In this way, the display device may preferentially display the page in the first window above.

In some embodiments, a video, such as the first video, may be played in the first window, and no video may be played in the second window.

The process of the display device playing the first video in the first window can refer to the following example.

For example, when the display device displays the Launcher page, the Launcher page may include an option for the first video. If the user inputs a control command based on the option, the display device 200 may create a new window in response to the control command, and may play the first video in the window. The newly created window may be the first window, and the window where the Launcher page is located may be the second window. The first window may be located above the second window, so the user can view the playback page of the first video but cannot see the Launcher page located below.

For another example, when the display device displays the Launcher page, the Launcher page may include a video application option. If the user inputs a control command based on the video application option, the display device creates a new window in response to the control command, and may display the video application page in the window, and the video application page may include an option for the first video. If the user inputs a control command based on the option for the first video, the display device may create another window in response to the control command, and may play the first video in the another window created. The window where the playback page of the first video is located may be the first window, and the window where the video application page is located may be the second window. The first window may be located above the second window, and the level of the layer of the window where the Launcher page is located may be the lowest. At this time, the user can watch the first video, but cannot see the video application page located below and the Launcher page.

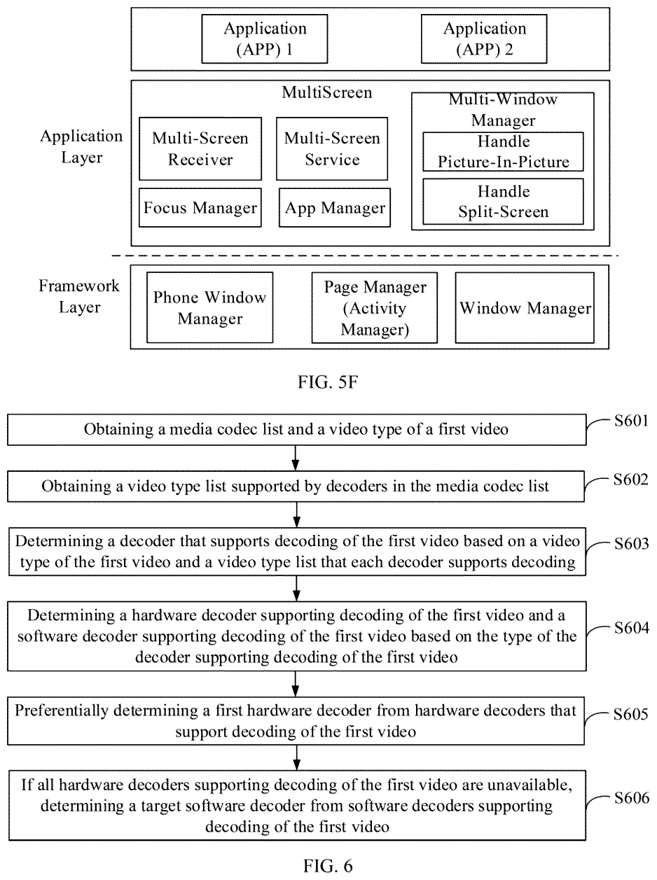

When the display device plays the first video, the decoder for decoding the first video before entering the PiP mode may be determined according to the process shown in FIG. 6. The specific steps may include but are not limited to the following.

S601, a media codec list and a video type of a first video are obtained.

In some embodiments, the media codec list may include all encoders and decoders provided by the display device.

In some embodiments, the video type of the first video may be a Multipurpose Internet Mail Extensions (MIME) type.

S602, a video type list that decoders support decoding in the media codec list is obtained.

The display device can obtain MediaCodecInfo through the MediaCodecList. getCodecInfoAt method. MediaCodecInfo provides the isDecoder api, which can be used to determine whether it is a decoder. MediaCodecInfo also provides the getSupportedTypes method, which can be used to obtain the video type list supported by the codec. After determining the decoders in the media codec list, the display device can obtain the video type list supported by each decoder. The video type list may include the video type(s) that the corresponding decoder supports decoding.

S603, a decoder that supports decoding of the first video is determined based on a video type of the first video and a video type list that each decoder supports decoding.

In some embodiments, if the video type list of the decoder includes the video type of the first video, the decoder may support decoding of the first video. In some other embodiments, if the video type list of the decoder does not include the video type of the first video, the decoder does not support decoding of the first video. Based on this, the display device can determine all decoders that support decoding of the first video.

S604, a hardware decoder supporting decoding of the first video and a software decoder supporting decoding of the first video is determined based on the type of the decoder supporting decoding of the first video.

In some embodiments, the type of decoder supporting decoding of the first video may include the hardware decoder and the software decoder. The display device may determine whether the decoder is a hardware decoder based on the MediaCodecInfo name, where if the MediaCodecInfo name contains OMX or .hw, it can be determined that the decoder is a hardware decoder; and if the MediaCodecInfo name does not contain OMX or .hw, it can be determined that the decoder is a software decoder.

In some embodiments, the display device can manage decoders that support decoding of the first video through a hardware decoder list and a software decoder list. The display device can add a hardware decoder that supports decoding of the first video to the hardware decoder list, and can add a software decoder that supports decoding of the first video to the software decoder list.

S605, a first hardware decoder is preferentially determining from hardware decoders that support decoding of the first video.

In some embodiments, before entering the PiP mode, the first window is equivalent to the main window, and thus, the image quality of the first video will seriously affect the user's viewing experience. At least one processor of the display device may be configured to execute computer instructions to cause the display device to: before entering the PiP mode, preferentially allocate the hardware decoder to the video played in the first window to ensure the image quality of the video in the first window.

The display device may preferentially determine the first hardware decoder from hardware decoders supporting decoding of the first video.

The display device may mark the state of each decoder, which may include an idle state and an occupied state. For example, the display device may carry the state, such as an idle state of 0 and an occupied state of 1, of the decoder in the media codec list.

In some embodiments, the display device may identify the state of each hardware decoder supporting decoding of the first video, and may select one hardware decoder from hardware decoders in an idle state as the first hardware decoder.

In some other embodiments, if all hardware decoders supporting decoding of the first video are in an occupied state, it can be identified whether these hardware decoders support multi-channel decoding. If there is a hardware decoder supporting multi-channel decoding, the hardware decoder can be determined as the first hardware decoder.

S606, if all hardware decoders supporting decoding of the first video are unavailable, a target software decoder is determined from software decoders supporting decoding of the first video.

For example, if all hardware decoders supporting decoding of the first video are in an occupied state and do not support multi-channel decoding, and all hardware decoders supporting decoding of the first video cannot be released at present, then all hardware decoders supporting decoding of the first video are unavailable. The display device may determine a target software decoder from the software decoders supporting decoding of the first video to use the target software decoder to decode the first video.

In some embodiments, if there is no hardware decoder that supports decoding of the first video, the target software decoder may be determined from software decoders that support decoding of the first video.

In some embodiments, if the user needs to view advanced features and special effects of the first video, such as image enhancement, real-time filters, etc., the display device needs to use the software decoder to decode the first video, and cannot use the hardware decoder.

In some other embodiments, a video, such as the first video, may be played in the first window, and a video, such as the second video, may be played in the second window.

The process of the display device playing the first video in the first window can refer to the following example.

For example, when the display device displays the Launcher page, the Launcher page may include an option for the second video. If the user inputs a control command based on the option, the display device may create a new window in response to the control command, and the second video can be played in the window. The newly created window may be the second window, which may be located above the window where the Launcher page is located. If the user inputs a control command based on the shortcut key on the control device, the display device may display a shortcut menu in response to the control command, and the shortcut menu may include an option for the first video. If the user inputs a control command based on the option of the first video, the display device may create another window in response to the control command, and the first video may be played in the another window created. The another window created may be the first window, and may be located above the second window. At this time, it is equivalent to placing the second video in the background, and in order not to affect the playback of the first video, the playback of the second video can be paused.

When the display device plays the second video, the decoder used to decode the second video can be determined by referring to the steps S601-S606, which will not be described in detail here.

When the display device plays the first video, the display device can determine the decoder used to decode the first video by referring to the steps S601-S606. When the display device allocates a decoder for the first video, if the decoder used by the first video conflicts with the decoder used by the second video, the decoder used by the second video can be released to preferentially allocated this decoder to the first video, or the decoder used by the second video can be not released to allocate other decoders to the first video. In some embodiments, if the decoder used by the first video can only be the decoder used by the second video, in order to ensure the normal playback of the first video, the decoder used by the second video can be released, and the decoder released can be used to decode the first video.

In some embodiments, the first video and the second video occupy different hardware decoders or one hardware decoder supporting multi-channel decoding. In some embodiments, the first video may occupy a hardware decoder and the second video may occupy a software decoder. In some embodiments, the first video may occupy a software decoder and the second video may occupy a hardware decoder. In some embodiments, both the first video and the second video may occupy different software decoders or one software decoder supporting multi-channel decoding.

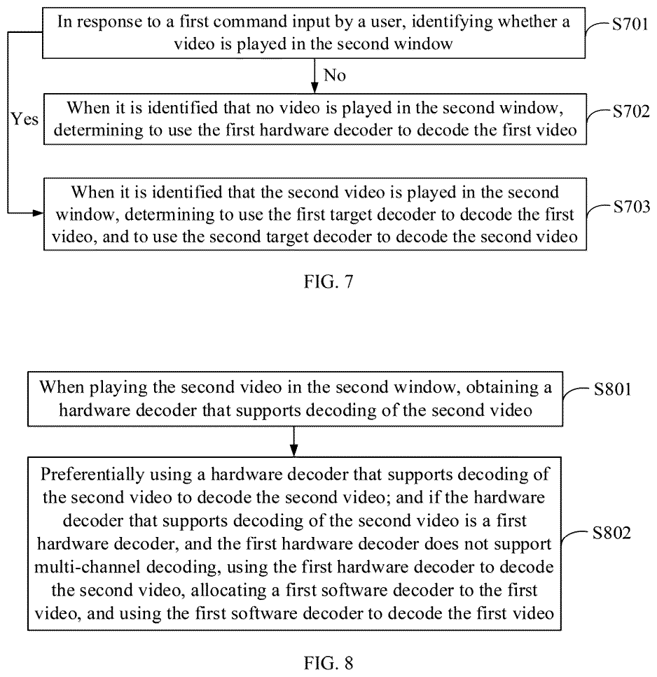

The display device may use a first hardware decoder to decode the first video. The decoder for decoding the first video when entering the PiP mode may be determined according to the process shown in FIG. 7. The specific steps may include but are not limited to the following.

S701, in response to a first command input by a user, whether a video is played in the second window is identified.

The first command may be used to indicate entering the PiP mode. Taking the control device 100 as a remote controller and the display device 200 as a television as an example, the remote controller may include a PiP key, and the user may input the first command by pressing the PiP key; and the virtual keyboard displayed on the television may include a PiP key, and the user may click the PiP key to input the first command.

The display device 200 can obtain the first application in the first window and the second application in the second window through the page manager (Activity Manager), and determine whether the videos are played in the first window and the second window based on the media controller list (Media Controller). The media controller list may include a media controller, and the media controller can be used to control the corresponding application to play the video. If the media controller list includes the media controller corresponding to the first application, it can be determined that the video is played in the first window. If the media controller list includes the media controller corresponding to the second application, it can be determined that the video is played in the second window.

S702, when it is identified that no video is played in the second window, the first hardware decoder is determined to be used to decode the first video.

Continuing with the above example, when it is identified that no video is played in the second window, if the media controller list does not include the media controller corresponding to the second application, the display device 200 can determine that there is no problem of preempting the hardware decoder between the video in the first window and the application in the second window, and can determine to continue using the first hardware decoder to decode the first video.

The display device 200 enters the PiP mode and can use the first hardware decoder to decode the first video. The display device 200 can reduce the first window in size and expose the second window located below. The display device 200 can play the first video in the reduced first window and display the corresponding page, such as the Launcher page, the video application page, etc., in the second window, thereby entering the PiP mode. At this time, the image quality of the first video can be guaranteed.

In the PiP mode, the display device 200 can play the first video in the first window and can use the first hardware decoder to decode the first video. If the display device 200 starts playing the second video in the second window, the display device 200 can decode the first video and the second video according to the process shown in FIG. 8, and the specific steps may include but are not limited to the following.

S801, when playing the second video in the second window, obtaining a hardware decoder that supports decoding of the second video.

For example, a second page may be displayed in the second window, and the second page may be a Launcher page. The Launcher page may include an option for the second video. The user may input a control command based on the option for the second video. The display device 200 may create a new window in response to the control command, and the second video may be played in this window. This window may be used as a new second window, and may be located above the original second window, and may be located below the first window.

For another example, a second page may be displayed in the second window, and the second page may be a Launcher page, which may include a video application option. The user may input a control command based on the video application option, and the display device 200 may create a new window in response to the control command, and a video application page may be displayed in this window, and the video application page may include an option for the second video. The user may input a control command based on the option for the second video, and the display device 200 may create another new window in response to the control command, and the second video may be played in this window. The another window created may serve as a new second window, and may be located above the original second window, and may be located below the first window.

In the PiP mode, the display device 200 can preferentially allocate a hardware decoder for the video in the main window to ensure the image quality of the video in the main window. Thus, before starting to play the second video, the display device 200 can obtain a hardware decoder that supports decoding of the second video to determine the hardware decoder that can be used to decode the second video.

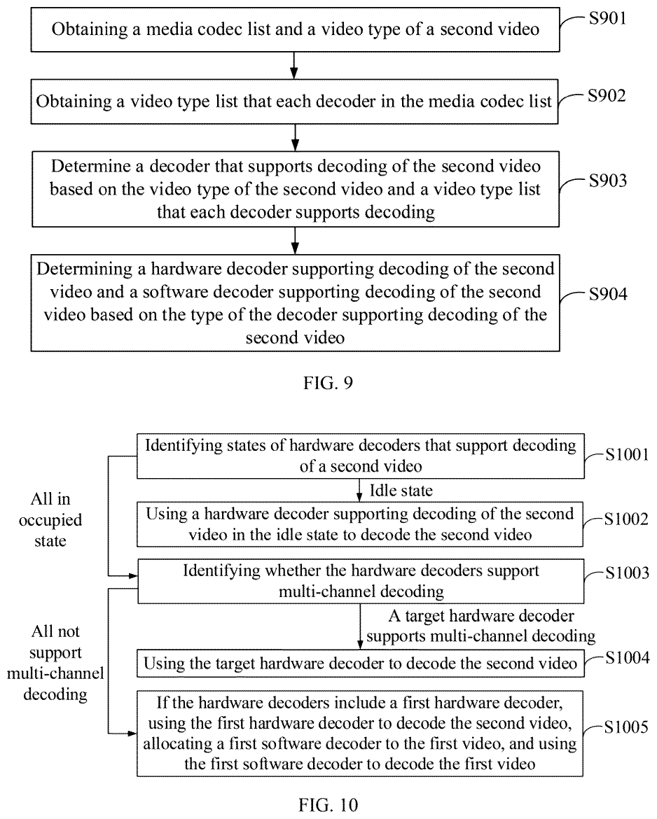

The display device may obtain a hardware decoder that supports decoding of the second video according to the process shown in FIG. 9, and the specific steps may include but are limited to the following.

S901, a media codec list and a video type of a second video is obtained.

S902, a video type list that each decoder supports decoding in the media codec list is obtained.

S903, a decoder that supports decoding of the second video is determined based on the video type of the second video and the video type list that each decoder supports decoding.

S904, a hardware decoder supporting decoding of the second video and a software decoder supporting decoding of the second video is determined based on the type of the decoder supporting decoding of the second video.

Steps S901-S904 are similar to steps S601-S604 and are not described again here.

S802, a hardware decoder that supports decoding of the second video is preferentially used to decode the second video; and if the hardware decoder that supports decoding of the second video is a first hardware decoder and the first hardware decoder does not support multi-channel decoding, the first hardware decoder is used to decode the second video, a first software decoder is allocated to the first video, and the first software decoder is used to decode the first video.

The display device may preferentially use the hardware decoder to decode the video in the main window. Therefore, in the PiP mode, the display device may preferentially use the hardware decoder to decode the second video.

The display device may decode the first video and the second video according to the process shown in FIG. 10, and the specific steps may include but are not limited to the following.

S1001, states of hardware decoders that support decoding of a second video are identified.

The states of the hardware decoders supporting decoding of the second video may include an idle state and an occupied state. The display device may poll the list of hardware decoders supporting decoding of the second video to determine the state of each hardware decoder. This step may refer to step S605 and will not be repeated here.

S1002, if the state of the hardware decoder supporting decoding of the second video is an idle state, the hardware decoder supporting decoding of the second video in the idle state is used to decode the second video.

If there are multiple hardware decoders in an idle state that support decoding of the second video, the display device can select any one of the hardware decoders to decode the second video. Alternatively, in the order of polling, after identifying a hardware decoder in an idle state, the display device can use this hardware decoder to decode the second video and may no longer continue to identify the state of other hardware decoders in the list.

The display device may continue to decode the first video using the first hardware decoder.

S1003, if the states of the hardware decoders supporting decoding of the second video are all in an occupied state, whether the hardware decoders support multi-channel decoding is identified.

If the hardware decoder supports multi-channel decoding, the hardware decoder can decode multiple videos simultaneously.

S1004, if there is a target hardware decoder that supports multi-channel decoding, the target hardware decoder is used to decode the second video.

If the states of all hardware decoders supporting decoding of the second video are in an occupied state, but there is a hardware decoder supporting multi-channel decoding, i.e., a target hardware decoder, the target hardware decoder may be used to decode the second video.

If the target hardware decoder is the first hardware decoder, the first hardware decoder can be used to decode the first video and the second video simultaneously; if the target hardware decoder is not the first hardware decoder, for example, is a hardware decoder for decoding other background videos, the target hardware decoder can be used to decode the second video, and the first hardware decoder can continue to be used to decode the first video.

S1005, if all hardware decoders do not support multi-channel decoding, and the hardware decoders include a first hardware decoder, the first hardware decoder is used to decode the second video, a first software decoder is allocated to the first video, and the first software decoder is used to decode the first video.

If the states of the hardware decoders that support decoding of the second video are all the occupied state, and the hardware decoders all do not support multi-channel decoding, then the display device uses these hardware decoders to decode the second video, which will affect the playback of the videos originally decoded by these hardware decoders.

In some embodiments, if these hardware decoders include the first hardware decoder, that is, a hardware decoder for decoding the second video conflicts with a hardware decoder for decoding the first video, the hardware decoder (i.e., the first hardware decoder) may be used preferentially to decode the second video. At this time, in order to ensure the normal playback of the first video, the display device may reallocate a software decoder (such as the first software decoder) for the first video to use the first software decoder to decode the first video.

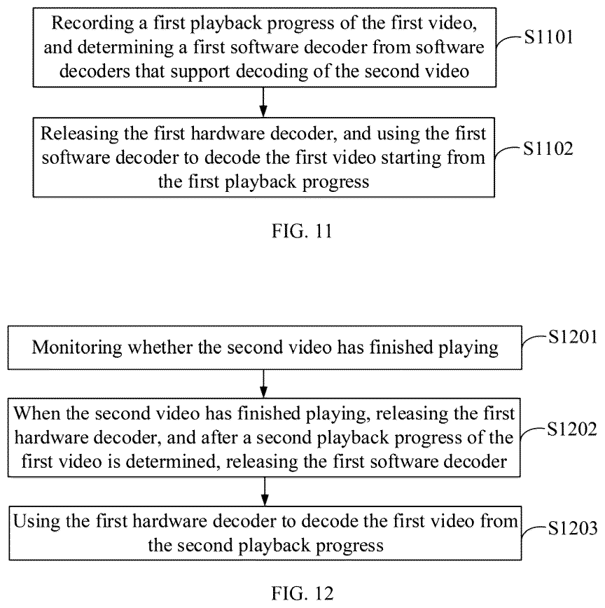

The display device may decode the first video according to the process shown in FIG. 11, and the specific process may include but is not limited to the following.

S1101, a first playback progress of the first video is recorded, and a first software decoder is determined from software decoders that support decoding of a second video.

The display device can record the current playback position, i.e., the first playback progress, of the first video through the PiP window (i.e., the first window). The first playback progress can be the starting progress for subsequent decoding, and decoding based on the first playback progress can effectively ensure the playback integrity of the first video.

The fact that the second video can be decoded using the first hardware decoder indicates that there is overlap between the hardware decoders and software decoders that can be used for the first and second videos. Therefore, the software decoder used to decode the first video, i.e., the first software decoder, can be determined from the software decoders that support decoding of the second video.

In some embodiments, the display device may reallocate a decoder for the first video according to steps S601-S606, which will not be described in detail here.

S1102, the first hardware decoder is released, and the first software decoder is used to decode the first video starting from the first playback progress.

The display device may release the first hardware decoder to restore the first hardware decoder to be in an idle state. At this time, the first hardware decoder may be used to decode the second video.

The display device may use the first software decoder to decode the first video starting from the first playback progress to ensure normal playback of the first video and playback integrity of the first video.

In some other embodiments, the hardware decoders occupied by other videos (such as background videos) may be released first, and these hardware decoders may be used to decode the second video. When these hardware decoders are released, the playback progress of the corresponding video may be recorded, so that when a decoder is allocated to the video again, decoding may be started from the recorded playback progress to ensure the playback integrity of the video.

In some embodiments, if none of the hardware decoders can be used to decode the second video, the display device may allocate a second software decoder for the second video and may use the second software decoder to decode the second video.

The cases where all hardware decoders cannot be used to decode the second video may include but is not limited to the following cases.

In case 1, all hardware decoders are in an occupied state and do not support multi-channel decoding. All hardware decoders cannot be released at present, for example, they are all occupied by videos/applications with higher priority.

In case 2, all hardware decoders are in an occupied state and do not support multi-channel decoding. If all hardware decoders include the first hardware decoder, but the user customizes the priority of guaranteeing the image quality of the video in the PiP window, that is, the priority of guaranteeing the image quality of the first video in the first window, then the first hardware decoder cannot be used to decode the second video.

In case 3, all hardware decoders are in an occupied state and do not support multi-channel decoding, and the first hardware decoder does not support decoding of the second video.

In any of the above cases, the display device cannot use the hardware decoder to decode the second video. In order to ensure normal playback of the second video, the display device needs to allocate a software decoder for the second video. The display device can select a software decoder, i.e., a second software decoder, from the software decoders that support decoding of the second video, and can use the second software decoder to decode the second video.

If the display device uses the first hardware decoder to decode the second video, the display device may return the first hardware decoder and decode the first video according to the process shown in FIG. 12, and the specific steps may include but are not limited to the following.

S1201, whether the second video has finished playing is monitored.

The display device can determine whether the second video has finished playing based on a playback completion message sent by the receiving application, or can determine whether the second video has finished playing based on whether the current playback position is the end playback position through the PiP window.

S1202, when the second video has finished playing, the first hardware decoder is released, and after a second playback progress of the first video is determined, the first software decoder is released.

When the second video is finished playing, the display device can release the first hardware decoder, such as changing an occupied flag of the first hardware decoder to an idle flag. At this time, the first hardware decoder can be used to decode other videos.

The display device may determine to reuse the first hardware decoder to continue decoding the first video to improve the image quality of the first video. The display device may first determine the current playback progress, such as the second playback progress, of the first video, and may release the first software decoder.

S1203, the first hardware decoder is used to decode the first video from the second playback progress.

The display device may use the first hardware decoder to decode the first video starting from the second playback progress to ensure the image quality of the first video and the playback integrity of the first video.

Therefore, after the display device enters the PiP mode, if it starts playing the video in the main window, it can ensure the image quality of the video in the main window by preferentially using the hardware decoder to decode the video in the main window. At the same time, if the hardware decoder allocated by the display device to the video in the main window is the hardware decoder originally used to decode the video in the PiP window, in order to ensure the normal playback of the video in the PiP window, the software decoder can be reallocated to the video in the PiP window, and the software decoder can be used to decode the video in the PiP window. After the video in the main window is finished playing, the display device can reuse the released hardware decoder to decode the video in the PiP window to improve the image quality of the video in the PiP window.

In some embodiments, if the first hardware decoder supports multi-channel decoding, the display device can monitor the playback state of the second video in the second window when using the first hardware decoder to decode the first video and the second video at the same time. If the playback state of the second video is detected to be abnormal, the occupation of the first video on the first hardware decoder can be released, and a software decoder can be reallocated to the first video to ensure normal playback of the second video.

S703, when it is identified that the second video is played in the second window, it is determined to use the first target decoder to decode the first video, and to use the second target decoder to decode the second video.

In some embodiments, before entering the PiP mode, the display device may use the hardware decoder to decode the second video, for example, both the first video and the second video occupy the hardware decoders, or the first video occupies the software decoder and the second video occupies the hardware decoder. At this time, when the display device enters the PiP mode, it can be determined to continue to use the originally allocated decoders to decode the first video and the second video.

For example, before entering the PiP mode, the display device 200 may use the first hardware decoder to decode the first video, and may use the second hardware decoder to decode the second video. When entering the PiP mode, the display device 200 may determine to continue to use the first hardware decoder to decode the first video, that is, the first hardware decoder is the first target decoder, and may determine to continue to use the second hardware decoder to decode the second video, that is, the second hardware decoder is the second target decoder.

For another example, before entering the PiP mode, the display device 200 may use the first software decoder to decode the first video, and may use the second hardware decoder to decode the second video. When entering the PiP mode, the display device 200 may determine to continue to use the first software decoder to decode the first video, that is, the first software decoder is the first target decoder, and may determine to continue to use the second hardware decoder to decode the second video, that is, the second hardware decoder is the second target decoder.

In some other embodiments, the display device may use a software decoder to decode the second video before entering the PiP mode, for example, the first video and the second video both occupy the software decoders, or the first video occupies the hardware decoder and the second video occupies the software decoder. At this time, when tentering the PiP mode, the display device 200 may reallocate a hardware decoder for the second video.

For example, before entering the PiP mode, the display device 200 may use the first software decoder to decode the first video, and may use the second software decoder to decode the second video. When entering the PiP mode, the display device 200 determines to continue to use the first software decoder to decode the first video, that is, the first software decoder is the first target decoder. The display device 200 needs to reallocate a hardware decoder for the second video. The process of allocating the hardware decoder for the second video can refer to steps S601-S606, which will not be repeated here. The reallocated decoder is the second target decoder.

For another example, before entering the PiP mode, the display device 200 may use the first hardware decoder to decode the first video, and may use the second software decoder to decode the second video. When entering the PiP mode, the display device 200 may reallocate the decoders for the first video and the second video with reference to the steps S801-S802, where if the hardware decoders used by the first video and the second video do not conflict, or the first hardware decoder supports multi-channel decoding, the first hardware decoder may continue to be used to decode the first video, the first hardware decoder may be the first target decoder, and the reallocated hardware decoder may be used to decode the second video, and the reallocated hardware decoder may be the second target decoder. If the hardware decoders used by the first video and the second video do not conflict, the reallocated hardware decoder may be another hardware decoder. If the hardware decoders used by the first video and the second video conflict, and the first hardware decoder supports multi-channel decoding, the reallocated hardware decoder may be the first hardware decoder. If the hardware decoders used by the first video and the second video conflict, and the first hardware decoder does not support multi-channel decoding, the first hardware decoder can be used to decode the second video, and the first hardware decoder can be the second target decoder, and a software decoder can be reallocated for the first video, and the software decoder can be used to decode the first video, and the software decoder can be the first target decoder.

Taking the display device as a TV as an example, the process of decoding a video by the display device in the PiP mode is explained with the following examples.

### Example 1

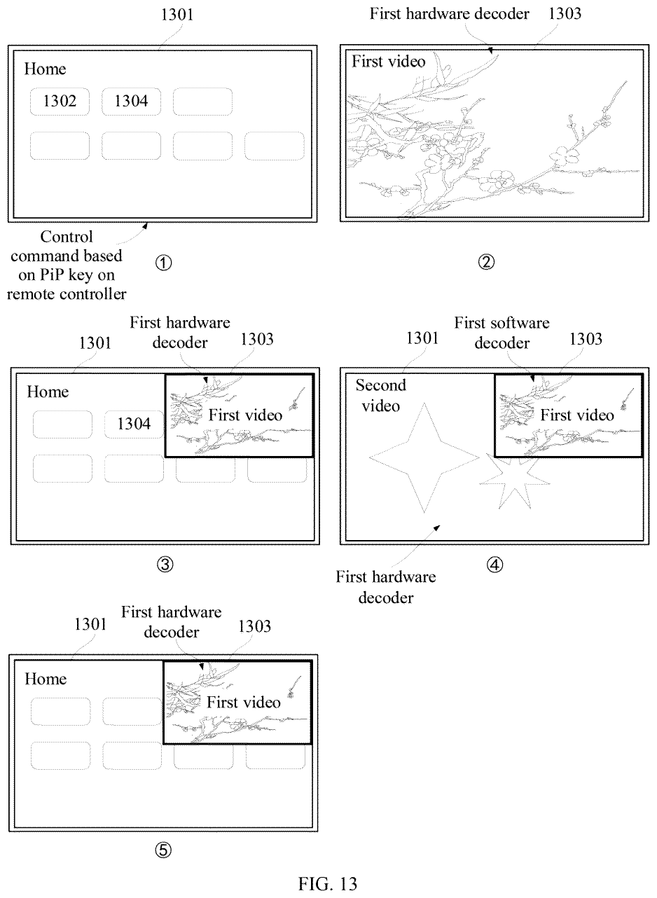

As shown in \textcircled{1} in FIG. 13, the TV may display a Launcher page in the second window 1301. The Launcher page may include an option 1302 for the first video. If the user inputs a control command based on the option 1302, the TV, in response to the control command, as shown in \textcircled{2} in FIG. 13, creates a first window 1303, and plays the first video in the first window 1303, such as using the first hardware decoder to decode the first video. Taking the first window 1303 and the second window 1301 as being located in one layer, and the window level of the first window 1303 is higher than the window level of the second window 1301 as an example, the TV preferentially displays the first window 1303. If the user inputs a control command to the TV indicating to enter the PiP mode, the TV, in response to the control command, as shown in \textcircled{3} in FIG. 13, reduces the first window 1303 in size, and displays the second window 1301 with a lower window level. The first video is played in the first window 1303, and the Launcher page is displayed in the second window 1301. At this time, the TV still uses the first hardware decoder to decode the first video. The Launcher page also includes an option 1304 for the second video. If the user inputs a control command based on the option 1304, the TV can play the second video in the second window 1301. Before playing the second video, the TV obtains the media codec list and the video type of the second

video, and determines the hardware decoder and software decoder that support decoding of the second video. The hardware decoder that supports decoding of the second video can be used to decode the second video preferentially, where, if the hardware decoder that supports the second video is the first hardware decoder, and the first hardware decoder does not support multi-channel decoding, the first hardware decoder can be used to decode the second video, a software decoder such as the first software decoder can be reallocated to the first video, and the first software decoder can be used to decode the first video. As shown in \textcircled{4} of FIG. 13, the first video is played in the first window 1303, and the first software decoder can be used to decode the first video; and the second video is played in the second window 1301, and the first hardware decoder can be used to decode the second video. After the second video is finished playing, the TV can release the first hardware decoder and switch to use

the first hardware decoder to decode the first video. As shown in \textcircled{5} in FIG. 13, the TV can display the Launcher page in the second window 1301, can play the first video in the first window 1303, and can continue to decode the first video using the first hardware decoder. Secondly, the sound effects of playing audio or video in coordinated multi-window mode are explained.

If the display device is in multi-window mode, it can play multiple audio or video at the same time, and the sounds corresponding to different windows are mixed together to present a mixed sound effect. When the user adjusts the volume, the display device adjusts the system volume. Therefore, when the user increases or decreases the volume, the display device increases or decreases the system volume, thereby increasing or decreasing the overall volume of the mixed sound of the multiple windows, that is, adjusting the volume of the sound of the multiple windows in the same direction (increase or decrease). As a result, the user cannot adjust the volume of the sound of the multiple windows in different directions by adjusting the volume, and cannot adjust the mixed sound effect of the multiple windows.

According to a display device of some embodiments of the present application, the display device includes a display, which can be further configured to: in a first multi-window mode, display a first window and a second window, where the first window can be displayed above the second window, the second window is in the full screen state, a size of the first window can be smaller than a size of the second window, a first audio or video can be played in the first window; and at least one processor, which can be further configured to execute computer instructions stored in a memory to cause the display device to: when it is detected that the focus is on the first window, display a volume control button in the first window, where the volume control button may include a volume up key and a volume down key; receive a control command input by a user based on the volume control button, where the control command indicates a first trend of adjusting a volume, and the first trend is to increase the volume or decrease the volume; in response to the control command, identify whether an audio or video is played in the second window; if it is identified that a second audio or video is played in the second window, adjust an amplitude ratio of the first audio or video based on the first trend, and adjust an amplitude ratio of the second audio or video based on a second trend opposite to the first trend, where a sum of the adjusted amplitude ratio of the first audio or video and the adjusted amplitude ratio of the second audio or video is equal to a preset total ratio. In this way, in multi-window mode, the display device can adjust the volume of the audio or video in each window in different directions to adjust the mixed sound effect.

Based on the media architecture shown in FIG. 5A, another processing method of a display device according to some embodiments of the present application is mainly used for volume adjustment under multi-windows. Based on this method, in multi-window mode, if multiple audios or videos are played at the same time, the display device can adjust the mixed sound effect adjusting the volumes of the audios or videos in the windows in different directions.

The following describes the process of adjusting the volume of a display device in different multi-window modes, where the first multi-window mode may be the PiP mode, the second multi-window mode may be a split-screen mode, and the third multi-window mode may be a free-window mode.

Before entering the first multi-window mode, the display device has created the first window and the second window. The first window may be located above the second window, such as the first window and the second window may be located in one layer, and the window level of the first window may be higher than the window level of the second window, or the first window and the second window may be located in different layers, and the level of the layer to which the first window belongs may be higher than the level of the layer to which the second window belongs.

In some embodiments, an audio or video, such as the first audio or video, can be played in the first window and no audio or video is played in the second window. In some embodiments, no audio or video is played in the first window, and an audio or video, such as the second audio or video, can be played in the second window. In some embodiments, an audio or video, such as the first audio or video, can be played in the first window, and an audio or video, such as the second audio or video, can be played in the second window, and the second audio or video can be paused.

If the user inputs a volume adjustment command, such as inputting the volume adjustment command based on a volume up key or a volume down key on a control device, or inputting the volume adjustment command based on a system volume bar or a system menu in the first window, the display device may adjust the system volume in response to the volume adjustment command. If the user inputs the volume adjustment command based on a volume control menu in the first window, the volume control menu may include a volume up key and a volume down key, and the volume up key and the volume down key may be used to adjust the volume of an application in the first window, then the display device may adjust the amplitude of the audio or video played in the first window in response to the volume adjustment command to adjust the volume of the audio or video itself played in the first window, without adjusting the system volume.

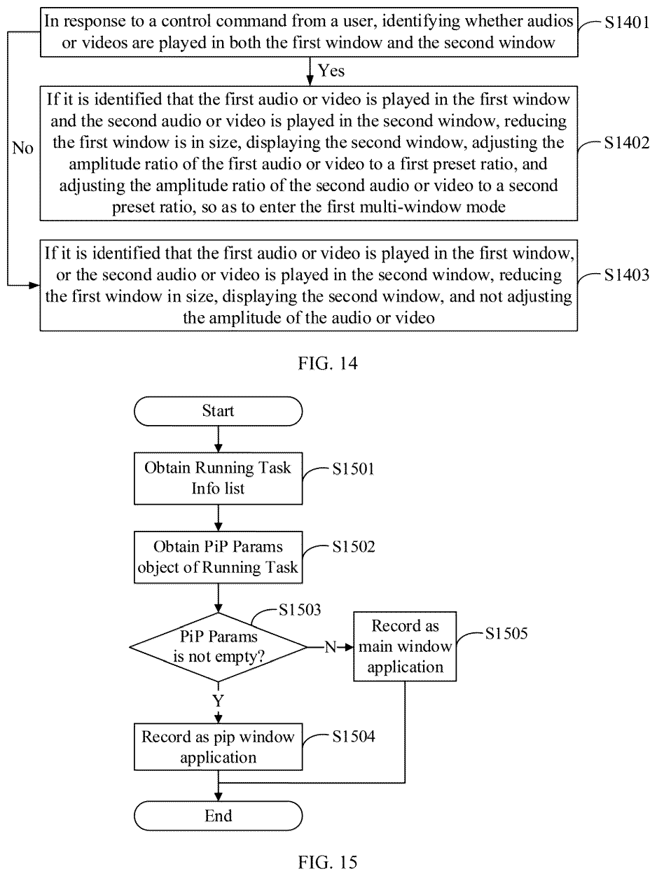

The display device may adjust the volume when entering the first multi-window mode according to the process shown in FIG. 14, and the specific steps may include but are not limited to the following.

S1401, in response to a control command from a user, whether audios or videos are played in both the first window and the second window is identified.

The control command can be used to indicate entering the PiP mode, such as a user inputting a control command based on a PiP key on a control device, or a user inputting a control command based on a PiP key in a virtual keyboard displayed on a display device. The specific process of the display device entering the PiP mode in response to a control command from a user in the present application is described in subsequent content and will not be repeated here.

The display device can determine the applications in the first window and the second window through the Activity Manager, and can obtain the application that is playing audio or video through the Media Session Manager, and then determine whether audios or videos are played in the first window and the second window.

S1402, if it is identified that the first audio or video is played in the first window and the second audio or video is played in the second window, the first window is reduced in size, the second window is displayed, the amplitude ratio of the first audio or video is adjusted to a first preset ratio, and the amplitude ratio of the second audio or video is adjusted to a second preset ratio, so as to enter the first multi-window mode. The sum of the first preset ratio and the second preset ratio is the preset total ratio.

When the display device enters the first multi-window mode in response to the control command, the first window may be reduced in size, and the second window located below may be exposed.

If audios or videos are played in both the first window and the second window, it means that the audios or videos played in the first window and the second window present the mixed sound effect. In this state, the display device can allocate initial volumes to the volumes of the audios or videos played in the first window and the second window, so that the user can adjust the mixed sound effect based on the initial volumes.

The display device can adjust the volumes of the first audio or video and the second audio or video by adjusting the amplitudes of the first audio or video and the second audio or video respectively. The display device can obtain the player proxy objects corresponding to the first window and the second window respectively through the Audio Manager, so as to adjust the corresponding amplitude and further adjust the volume by using the sound adjustment interface provided by the player proxy object.

When the display device plays multiple audios or videos, the amplitude ratio of the audio or video can be adjusted to a corresponding preset ratio to allocate an initial volume to each audio or video. The amplitude ratio is used to characterize the volume of the audio or video itself. When the system volume is constant, the amplitude ratio of the audio or video can be directly proportional to the output volume when playing the video. For example, the larger the amplitude ratio of the audio or video, the larger the output volume of the display device when playing the audio or video; the smaller the amplitude ratio of the audio or video, the smaller the output volume of the display device when playing the audio or video.

In some embodiments, the preset total ratio can be 100%, or the preset total ratio can be any ratio less than 100%, such as 80%, 60%, etc. For example, when audio or video are played in the background and the audio or video are in a playing state, the display device 200 can also allocate an amplitude ratio for the audio or video played in the background, and the preset total ratio corresponding to the first audio or video and the second audio or video is less than 100%. Alternatively, the display device 200 can set a lower preset total ratio in some special scenarios, such as when the ambient sound is small, to avoid excessive volume of the audio or video. In some embodiments, the preset total ratio can be a fixed ratio, or the preset total ratio can also change dynamically according to user needs.

In some embodiments, the first preset ratio and the second preset ratio may be ratios by evenly distributing the preset total ratio, and the first preset ratio and the second preset ratio may be ratios by proportionally distributing the preset total ratio. For example, a higher first preset ratio may be set for the first window located above, and a lower second preset ratio may be set for the second window located below. In some embodiments, the first preset ratio and the second preset ratio may be fixed ratios, and the first preset ratio and the second preset ratio may also change dynamically according to user needs.

When adjusting the amplitude ratios of the first audio or video and the second audio or video, based on the current amplitudes of the first audio or video and the second audio or video, and the first preset ratio and the second preset ratio, the adjusted amplitudes of the audio or video may include the following cases: the amplitudes of the first audio or video and the second audio or video do not change; the amplitude of the first audio or video decreases, and the amplitude of the second audio or video increases; the amplitude of the first audio or video increases, and the amplitude of the second audio or video decreases; the amplitudes of both the first audio or video and the second audio or video increase; the amplitudes of both the first audio or video and the second audio or video decrease.

In the above process of adjusting the volume, the amplitudes of the first audio or video and the second audio or video are adjusted, and the system volume of the display device remains unchanged.

S1403, if it is identified that the first audio or video is played in the first window, or the second audio or video is played in the second window, the first window is reduced in size, the second window is displayed, and the amplitude of the audio or video is not adjusted.

If the audio or video is played in the first window or the second window, it means that there is no mixed sound effect at this time, and only the sound of one audio or video is played. In this state, the display device can use the current amplitude of the audio or video to play, and cannot adjust the amplitude of the audio or video. For example, currently only the first audio or video is played in the first window, and no audio or video is played in the second window, then after entering the PiP mode, the first audio or video can continue to be played at the current amplitude of the first audio or video, and the amplitude of the first audio or video will not be adjusted.

After entering the PiP mode, if the display device identifies that the first audio or video is played in the first window, the volume up key and the volume down key may also be displayed in the reduced first window. The volume up key and the volume down key can be displayed in the PiP menu and can be used to adjust the volume of the first audio or video itself. Since the application in the first window cannot obtain focus in the PiP mode, the user cannot directly control the application in the first window. By displaying the volume up key and the volume down key in the first window, the display device can provide the user with a control entry that can directly adjust the volume of the first audio or video, so that the user can control the playback state of the application in the first window.

In some embodiments, the display device can obtain the applications in the first window and the second window according to the process shown in FIG. 15. The Running Task Info list is obtained through the Activity Manager (S1501). The first application and the second application in the list can be the applications in the main window and the PiP window. The PiP parameter (Picture In Picture Params or PiP Params) object of the Running Task Info is obtained (S1502). By determining whether the PiP Params of the Running Task Info is not empty, it can be determined which application the above two applications correspond to (S1503). The application whose PiP Params is not empty is the application in the PiP window, and the application whose PiP Params is empty is the application in the main window. If PiP Params is not empty, it is recorded as the PiP window application (S1504); if PiP Params is empty, it is recorded as the main window application (S1505).

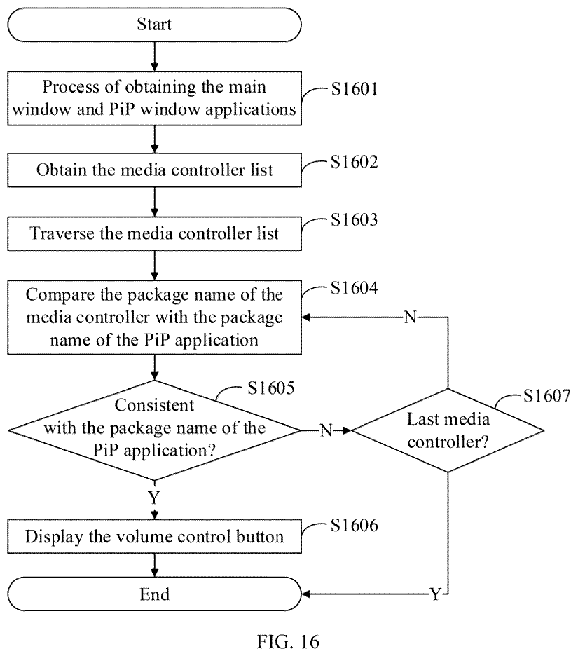

In some embodiments, the display device may display a volume control button in the first window according to the process shown in FIG. 16. After executing the process (S1601) of obtaining the main window and PiP window applications shown in FIG. 15, that is, after obtaining the applications in the first window and the second window, the active media controller list may be obtained through MediaSessionManager. getActiveSessions (S1602), and the media controller list may be traversed (S1603) to determine whether the media controller corresponding to the application in the PiP window is included. For example, the application package name of the PiP window is compared with the package names of the items in the media controller list (S1604), and it is determined whether the application package name is the same as /consistent to the package names of the items in the media controller list (S1605). If they are the same, it means that the media resource is being played in the PiP window, and when the PiP menu is displayed, the volume control button (S1606), such as the volume up key and the volume down key, may be displayed in the PiP menu. If they are different, it means that there is no media resource being played in the PiP window, and the volume control button may not be displayed when the PiP menu is displayed. It is further determined whether the media controller currently being processed is the last media controller in the media controller list (S1607). If not, the process returns to step S1604.

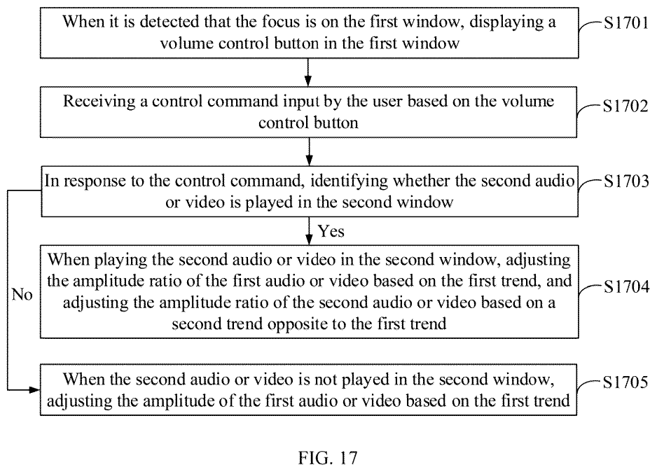

The display device may adjust the volume in the first multi-window mode according to the process shown in FIG. 17, and the specific steps may include but are not limited to the following.

S1701, when it is detected that the focus is on the first window, a volume control button is displayed in the first window.

The user may move the focus to the first window by controlling the device.

The display device controls the PiP menu through the PiP Menu Controller of Wmshell. When it is identified that the first audio or video is played in the first window, the PiP Menu Controller can automatically add volume adjustment buttons in the PiP Menu View, such as a volume up key and a volume down key.

S1702, a control command input by the user is received based on the volume control button.

The control command may indicate a first trend of adjusting the volume, and the first trend may include increasing the volume or decreasing the volume. For example, if the user inputs a control command based on the volume up key, the first trend is to increase the volume; and if the user inputs a control command based on the volume down key, the first trend is to decrease the volume.

S1703, in response to the control command, whether the second audio or video is played in the second window is identified.

Please refer to step S1401, which will not be repeated here.

S1704, when playing the second audio or video in the second window, the amplitude ratio of the first audio or video is adjusted based on the first trend, and the amplitude ratio of the second audio or video is adjusted based on a second trend opposite to the first trend. The sum of the adjusted amplitude ratio of the first audio or video and the adjusted amplitude ratio of the second audio or video is equal to the preset total ratio.

In some embodiments, when entering the PiP mode, audios or videos can be played in both the first window and the second window. In some other embodiments, when entering the PiP mode, the first audio or video can be played in the first window, and no audio or video is played in the second window. After entering the PiP mode, the display device, in response to the user's command and starts playing the second audio or video in the second window. When audios or videos are played in both the first window and the second window, the first window and the second window can correspond to the initial volumes.

When the first window and the second window play audios or videos at the same time, the display device can adjust the volumes of the first audio or video and the second audio or video respectively based on opposite trends. The volume of the first audio or video can be adjusted based on the same trend as the first trend indicated by the control command, and the volume of the second audio or video can be adjusted based on the trend opposite to the first trend indicated by the control command. For example, if the first trend is to increase the volume, the volume of the first audio or video can be increased, and the volume of the second audio or video can be reduced.

In the process of adjusting the volumes of the first audio or video and the second audio or video, the display device can adjust the volumes corresponding to the first window and the second window respectively through the sound adjustment interfaces provided by the player proxies corresponding to the first window and the second window respectively. The display device can adjust the amplitudes of the first audio or video and the second audio or video by adjusting the amplitude ratios, thereby adjusting the volumes of the two. In the process of adjusting the amplitude ratios of the first audio or video and the second audio or video, the display device can always keep the sum of the amplitude ratios of the two to be a preset total ratio, thereby, when the amplitude ratio of the first audio or video is increased, the amplitude ratio of the second audio or video can be decreased; and when the amplitude ratio of the first audio or video is decreased, the amplitude ratio of the second audio or video can be increased.

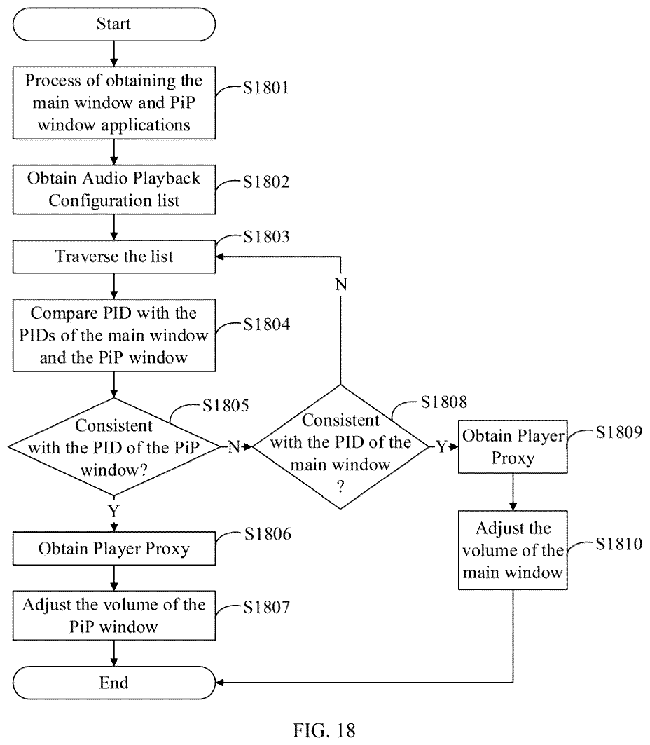

The display device executes the process of obtaining the main window and PiP window applications shown in FIG. 15 (S1801), that is, after obtaining the applications in the first window and the second window, the display device can adjust the amplitude ratios of the first audio or video and the second audio or video according to the process shown in FIG. 18. After the user inputs a control command based on the volume control button in the PiP menu, the display device, in response to the control command, obtains the currently active Audio Playback Configuration list through the AudioManager. getActivePlaybackConfigurations method (S1802). The display device traverses the list (S1803) by comparing the PIDs of the Audio Playback Configurations with the PIDs corresponding to the Running Task Info of the first window and the second window (S1804). If the PIDs of the Audio Playback Configurations are the same as the PIDs corresponding to the Running Task Info of the first window and the second window, the Audio Playback Configurations corresponding to the first window and the second window can be determined. Through the getPlayerProxy method of the Audio Playback Configuration, the corresponding player proxy object can be obtained to control the corresponding player through the player proxy. The player proxy can provide a setVolume API. When the display device adjusts the volume corresponding to the first window, the setVolume method of the player proxy of the first window can be called to set the volume of the audio track of the first audio or video in the first window. For example, whether the PID of the Audio Playback Configuration is consistent with the PID corresponding to the Running Task Info of the PiP window is determined (S1805). If they are consistent, the Player Proxy can be obtained (S1806), and the volume of the PiP window can be adjusted (S1807). If they are inconsistent, whether the PID of the Audio Playback Configuration is consistent with the PID corresponding to the Running Task Info of the main window is determined (S1808). If they are consistent, the PlayerProxy can be obtained (S1809), and the volume of the main window can be adjusted (S1810). If they are inconsistent, the traversal list is returned (S1803).

The value of the setVolume method can be 0 to 1 (including 0 and 1), and the amplitude ratio corresponding to the audio track volume of the set first audio or video can be any value in 0 to 100%. For example, when the audio track volume of the first audio or video is 0.5, the amplitude ratio of the first audio or video can be 50%. After setting the audio track volume of the first audio or video, the display device can call the setVolume method of the player proxy of the second window to set the audio track volume of the second audio or video in the second window. When setting the audio track volume of the second audio or video, the amplitude ratio of the second audio or video can be calculated based on the formula (100−volumePiP)/100. The volumePiP can represent 100 times the audio track volume of the first audio or video in the first window. For example, when the audio track volume of the first audio or video is 0.5, volumePiP can be 50. After calculation, it can be obtained that the amplitude ratio of the second audio or video can be 50%.

In this way, the display device can adjust the mixed sound effect of the first audio or video and the second audio or video by adjusting the volumes corresponding to the first window and the second window respectively.

In some embodiments, if the control command is a command input by the user single clicking the volume control button, the amplitude ratio of the first audio or video can be adjusted in equal steps based on the first trend, and the amplitude ratio of the second audio or video can be adjusted in equal steps based on the second trend. The step size can be a preset value. Taking the first trend of increasing the volume as an example, the display device, in response to a control command, can increase the amplitude ratio of the first audio or video by 1% and decrease the amplitude ratio of the second audio or video by 1%. Before adjustment, if the amplitude ratio of the first audio or video is 50% and the amplitude ratio of the second audio or video is 50%, then after adjustment, the amplitude ratio of the first audio or video can be 51%, and the amplitude ratio of the second audio or video can be 49%.

In some embodiments, if the control command is a command input by the user continuously clicking or long pressing the volume control button, the amplitude ratio of the first audio or video can be adjusted with a gradient step based on the first trend, and the amplitude ratio of the second audio or video can be adjusted with a gradient step based on the second trend. If the user continuously clicks the volume control button to input the control command, the step size can change once for each specified number of clicks, and the step size after the change can be greater than the step size before the change. If the user long presses the volume control button to input the control command, the step size can change once for each specified duration, and the step size after the change can be greater than the step size before the change. For example, taking the first trend of increasing the volume as an example, the display device, in response to a control command, can increase the amplitude ratio of the first audio or video by 1% and decrease the amplitude ratio of the second audio or video by 1%. The user inputs a control command by long pressing the volume control button for 3 seconds, where the step size can change once every 1 second, and the gradient of change can be 1%, 2%, 3% . . . and so on. Taking the first trend of increasing the volume as an example, the display device 200, in response to the control command, can increase the amplitude ratio of the first audio or video by 1%, 2%, and 3% in turn, and can decrease the amplitude ratio of the second audio or video by 1%, 2%, and 3% in total. Before adjustment, if the amplitude ratio of the first audio or video is 50% and the amplitude ratio of the second audio or video is 50%, then after adjustment, the amplitude ratio of the first audio or video can be 56%, and the amplitude ratio of the second audio or video can be 44%.

S1705, when the second audio or video is not played in the second window, the amplitude of the first audio or video is adjusted based on the first trend.

In some embodiments, when entering the PiP mode, the first audio or video can be played in the first window, and no audio or video is played in the second window. In some embodiments, when entering the PiP mode, audios or videos can be played in both the first window and the second window. After entering the PiP mode, the display device exits the playback of the audio or video in the second window in response to the user's command. At this time, when adjusting the amplitude of the first audio or video, it is not necessary to adjust based on the amplitude ratio, and the amplitude of the first audio or video can be adjusted. That is, when the display device adjusts the amplitude of the first audio or video with equal steps or gradient steps based on the first trend, the step size may correspond to the amplitude.

In some embodiments, during the process of adjusting the volume, if the amplitude ratio of the first audio or video reaches the preset total ratio or 0, the system volume can be adjusted based on the first trend.

For example, if the user inputs a control command based on the volume up key, the display device 200 can increase the amplitude ratio of the first audio or video and decrease the amplitude ratio of the second audio or video in response to the control command. Taking the preset total ratio as 100% as an example, when the amplitude ratio of the first audio or video reaches 100%, if the user continues to input a control command based on the volume up key, the display device 200 can switch to increasing the system volume in response to the control command. At this time, the amplitude ratio of the first audio or video can be maintained at 100%, and the amplitude ratio of the second audio or video can be maintained at 0.

For another example, if the user inputs a control command based on the volume down key, the display device 200 can decrease the amplitude ratio of the first audio or video and increase the amplitude ratio of the second audio or video in response to the control command. When the amplitude ratio of the first audio or video reaches 0, if the user continues to input a control command based on the volume down key, the display device 200 can switch to decreasing the system volume in response to the control command. Taking the preset total ratio of 100% as an example, the amplitude ratio of the first audio or video can be maintained at 0, and the amplitude ratio of the second audio or video can be maintained at 100%.

In some other embodiments, after switching to adjusting the system volume, if the display device, in response to a control command from the user, can adjust the system volume to a specified volume based on the second trend, e.g., switch to a volume when the system volume is adjusted or the maximum value of the system volume on the second trend, then the display device can switch back to adjusting the amplitude ratio of the first audio or video based on the second trend.

For example, the user inputs a control command based on decreasing the volume, and when the amplitude ratio of the first audio or video reaches 0, it can be switched to decreasing the system volume. If the user inputs a control command based on the volume up key in the PiP menu, the display device 200 can increase the system volume in response to the control command. Taking the specified volume as 20 as an example, when the system volume reaches 20, if the user continues to input a control command based on the volume up key, the display device 200 can switch to increasing the amplitude ratio of the first audio or video in response to the control command, and can decrease the amplitude ratio of the second audio or video. At this time, the system volume can be maintained at 20.

For another example, the user inputs a control command based on increasing the volume, and when the amplitude ratio of the first audio or video reaches 100%, it can be switched to increasing the system volume. If the user inputs a control command based on the volume down key in the PiP menu, the display device 200 can decrease the system volume in response to the control command. Taking the specified volume as 50 as an example, when the system volume reaches 50, if the user continues to input a control command based on the volume down key, the display device 200 can switch to reducing the amplitude ratio of the first audio or video in response to the control command, and can increase the amplitude ratio of the second audio or video. At this time, the system volume can be maintained at 50.

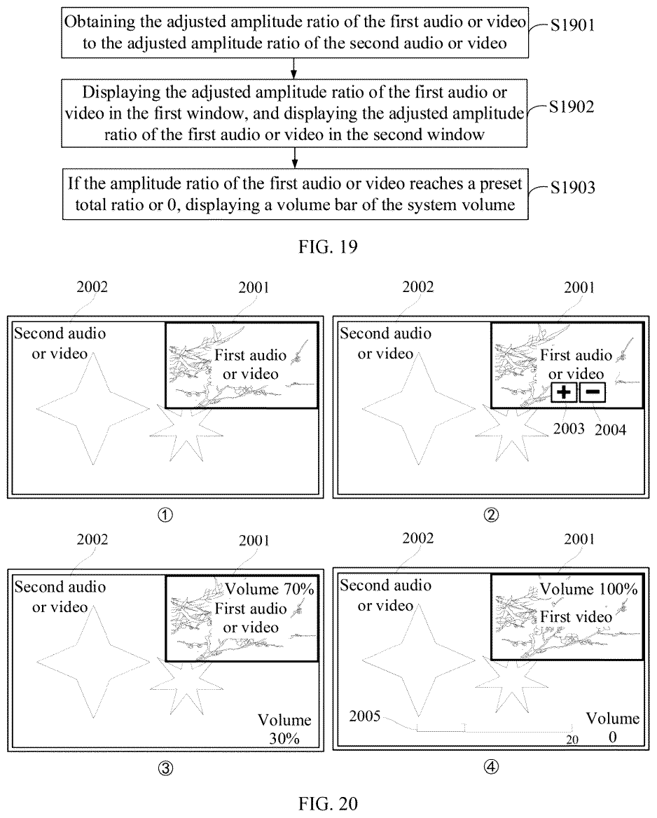

During the process of adjusting the volume, the display device may display the volume according to the process shown in FIG. 19, and the specific steps may include but are not limited to the following.

S1901, the adjusted amplitude ratio of the first audio or video to the adjusted amplitude ratio of the second audio or video are obtained.

S1902, the adjusted amplitude ratio of the first audio or video is displayed in the first window, and displaying the adjusted amplitude ratio of the first audio or video is displayed in the second window.

The amplitude ratio of the first audio or video and the amplitude ratio of the second audio or video can be displayed in the first window and the second window respectively, which can help users quickly grasp the volume in the two windows.

S1903, if the amplitude ratio of the first audio or video reaches a preset total ratio or 0, display a volume bar of the system volume.

When switching to adjusting the system volume, the display device can display the volume bar of the system volume. When the volume bar of the system volume is displayed, the volume bar may correspond to the current volume of the system volume. In response to the control command continuously input by the user, the display device may update the displayed volume bar.

Taking a TV as an example, the process of adjusting the volume of the display device in the first multi-window mode is described.

### Example 2

In the first multi-window mode, as shown in \textcircled{1} in FIG. 20, the TV can play the first audio or video in the first window 2001, and play the second audio or video in the second window 2002. The user controls the TV to move the focus to the first window 2001 through the control device 100. When the TV detects that the focus is on the first window 2001 and that the audio or video is played in the first window 2001, as shown in \textcircled{2} in FIG. 20, the TV displays a PiP menu in the first window 2001. The PiP menu may include volume control buttons, such as a volume up key 2003 and a volume down key 2004. If the user inputs a control command based on the volume up key 2003, the TV, in response to the control command, identifies that the second audio or video is played in the second window 2002, then the TV may increase the amplitude ratio of the first audio or video, and may decrease the amplitude ratio of the second audio or video. Taking the amplitude ratio of the first audio or video before adjustment as 50%, and the amplitude ratio of the second audio or video before adjustment as 50% as an example, if the amplitude ratio of the first audio or video is increased by 20%, the amplitude ratio of the first audio or video after adjustment is 70%, and the amplitude ratio of the second audio or video after adjustment is 30%. As shown in \textcircled{3} in FIG. 20, the TV displays the volume of 70% in the first window 2001 and the volume of 30% in the second window 2002. The user continues to input the control command based on the volume up key 2003, and the TV responds to the control command to increase the amplitude ratio of the first audio or video to 100% and decrease the amplitude ratio of the second audio or video to 0. If the user continues to input control commands based on the volume up key 2003, the TV, in response to the control command, switches to increase the system volume. As shown in \textcircled{4} in FIG. 20, the TV displays the volume bar 2005 of the system volume, such as the current volume is 20.

Before entering the second multi-window mode, the display device 200 has created the first window and the second window. The first window may be located above the second window, such as the first window and the second window may be located in one layer, and the window level of the first window may be higher than the window level of the second window, or the first window and the second window may be located in different layers, and the level of the layer to which the first window belongs may be higher than the level of the layer to which the second window belongs. In some embodiments, an audio or video, such as the first audio or video, can be played in the first window, and an audio or video, such as the second audio or video, are not played in the second window. In some embodiments, an audio or video, such as the first audio or video, are not played in the first window, and an audio or video, such as the second audio or video, can be played in the second window. In some embodiments, an audio or video, such as the first audio or video, can be played in the first window, and an audio or video, such as the second audio or video, can be played in the second window, and the second audio or video can be paused.

Before entering the second multi-window mode, the process of the display device 200 adjusting the volume of the first audio or video can refer to the process of adjusting the volume of the first audio or video before entering the first multi-window mode, which will not be repeated here.

When the display device 200 enters the second multi-window mode, the volume can be adjusted with reference to steps S1401-S1403. When entering the second multi-window mode, the display device 200 determines the applications in the first window and the second window according to the following process to further determine the audios or videos played in the first window and the second window.

The display device 200 can obtain the Running Task Info list through the getRunningTaskInfo method of Activity Manager, poll the list, and obtain the window mode of each Task Info through the getWindowingMode method of Running Task Info. When the window mode is WindowConfiguration. WINDOWING_MODE_MULTI_WINDOW, WINDOWING_MODE_SPLIT_SCREEN_PRIMARY, WINDOWING_MODE_SPLIT_SCREEN_SECONDARY, it means that the current Task Info is in the split-screen mode (i.e., the second multi-window mode), and the display device 200 can obtain the Running Task Info of the corresponding application in the window in split-screen mode. Running Task Info can include the package name attribute of packageName. The display device 200 can obtain the Running App Process Info list through ActivityManager.getRunningAppProcesses, and the list may include a package name list attribute and a PID attribute. By comparing the package name attribute of the Running Task Info with the package name list attribute of the Running App Proces Info, the PID corresponding to the consistent package name attributes can be determined, and the player proxy object corresponding to the window to which the application belongs can be determined based on the PID.

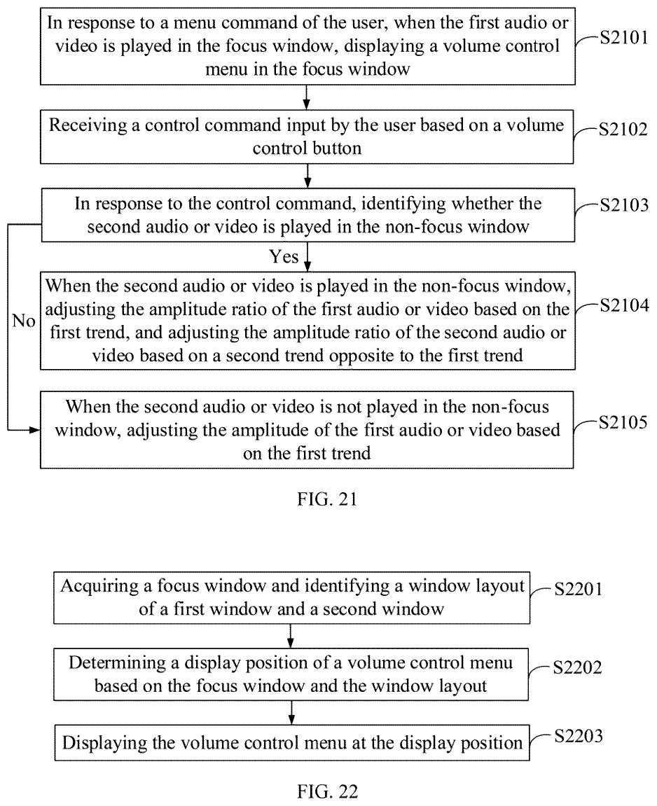

The display device may adjust the volume in the second multi-window mode according to the process shown in FIG. 21, and the specific steps may include but are not limited to the following.

S2101, in response to a menu command from the user, when the first audio or video is played in the focus window, a volume control menu is displayed in the focus window.

The user can input the menu command based on the menu key on the control device.

Compared to the volume control button added and managed by Wmshell in the first multi-window mode, in the second multi-window mode, the display device can add a volume control menu separately. The display device can add the volume control menu in the split-screen window through the WindowManager. addView method, and add control logic to an independent system application or an existing system application to record the window focus and control the display and hiding of the volume control menu. The display device, in response to the menu command, determines whether it is in the second multi-window mode through the Phone Window Manager, send a broadcast notification to the system application when it is determined to be in the second multi-window mode. After receiving the broadcast, the system application identifies whether audio or video is played in the focus window. If it is determined that audio or video is played in the focus window, the volume control menu can be added through the Window Manager.

The display device may display the volume control menu according to the process shown in FIG. 22, and the specific steps may include but are not limited to the following.

S2201, a focus window is acquired and a window layout of a first window and a second window is identified.

The window layout of the first window and the second window may include horizontal split screen, that is, the first window and the second window are arranged left and right, and the window layout of the first window and the second window may also include vertical split screen, that is, the first window and the second window are arranged up and down.

S2202, a display position of a volume control menu is determined based on the focus window and the window layout.

The position of the focus window in the display can be determined based on the focus window and the window layout, and then the display position of the volume control menu in the display can be determined based on the display position of the volume control menu in the window, and the display position can be located in the focus window.

For example, if the window layout is horizontal split screen and the focus window is on the left, the volume control menu can be displayed at the horizontal center of the bottom of the left window.

For example, if the window layout is horizontal split screen and the focus window is on the right, the volume control menu can be displayed at the horizontal center of the bottom of the right window.

For example, if the window layout is vertical split screen and the focus window is located at the upper side, the volume control menu can be displayed at the horizontal center of the bottom of the upper window.

For example, if the window layout is vertical split screen and the focus window is located at the lower side, the volume control menu can be displayed at the horizontal center of the bottom of the lower window.

S2203, the volume control menu is displayed at the display position.

The volume control menu may include a volume up key and a volume down key. The volume up key and the volume down key may be used to adjust the volume of the audio or video in the focus window.

S2102, a control command input by the user is received based on the volume control button.

S2103, in response to the control command, whether the second audio or video is played in the non-focus window is identified.

S2104, when the second audio or video is played in the non-focus window, the amplitude ratio of the first audio or video is adjusted based on the first trend, and the amplitude ratio of the second audio or video is adjusted based on a second trend opposite to the first trend. The sum of the adjusted amplitude ratio of the first audio or video and the adjusted amplitude ratio of the second audio or video is equal to the preset total ratio.

S2105, when the second audio or video is not played in the non-focus window, the amplitude of the first audio or video is adjusted based on the first trend.

Steps S2102-S2105 are similar to steps S1702-S1705 and are not repeated here.

In the second multi-window mode, the display device, during adjusting the volume, if the amplitude ratio of the first audio or video reaches the preset total ratio or 0, can adjust the system volume based on the first trend. This process can refer to the process in which the display device, in the first multi-window mode, adjusts the system volume based on the first trend if the amplitude ratio of the first audio or video reaches the preset total ratio or 0, and will not be repeated here.

After switching from adjusting the volume of the audio or video to adjusting the system volume, during the process of adjusting the system volume, if the display device, in response to the control command from the user, can adjust the system volume to the specified volume based on the second trend, e.g., switch to a volume when the system volume is adjusted or the maximum value of the system volume on the second trend, then the display device can switch back to adjusting the amplitude ratio of the first audio or video based on the second trend. This process can refer to the process in which if the display device is in the first multi-window mode, and in response to the control command from the user, adjusts the system volume to the specified volume based on the second trend, then it can switch back to adjusting the amplitude ratio of the first audio or video based on the second trend, and it will not be repeated here.

In the second multi-window mode, the display device may display the volume with reference to steps S1901-S1903, which will not be described in detail here.

If the user switches the focus to another window, the display device can use the another window as the focus window and use the control command to adjust the volumes of the audios or videos in the focus window and non-focus window according to a process similar to the above, which is not repeated here.

Taking a TV as an example, the process of adjusting the volume of the display device in the second multi-window mode is described.

### Example 3

In the second multi-window mode, as shown in \textcircled{1} in FIG. 23, the TV plays the first audio or video in the first window 2301, and plays the second audio or video in the second window 2302. The user inputs a menu command through the menu key on the control device 100, and the TV, in response to the menu command, determines the focus window, such as the first window 2301 (the focus is shown in a thick black solid line frame). When the TV identifies that the audio or video is played in the first window 2301, the TV determines the display position, such as the horizontal center position at the bottom of the left window, of the volume control menu based on the first window 2301 and the window distribution (horizontal distribution). As shown in \textcircled{2} in FIG. 23, the TV displays the volume control menu in the first window 2301, and the volume control menu may include volume control buttons, such as the volume up key 2303 and the volume down key 2304. If the user inputs a control command based on the volume down key 2304, the TV, in response to the control command, identifies that the non-focus window, such as the second window 2302 in which the second audio or video is played, and then the TV decreases the amplitude ratio of the first audio or video, and increases the amplitude ratio of the second audio or video. Taking the amplitude ratio of the first audio or video before adjustment is 50% and the amplitude ratio of the second audio or video before adjustment is 50% as an example, if the amplitude ratio of the first audio or video is decreased by 20%, the amplitude ratio of the first audio or video after adjustment is 30%, and the amplitude ratio of the second audio or video after adjustment is 70%. As shown in \textcircled{3} in FIG. 23, the TV displays the volume of 30% in the first window 2301 and the volume of 70% in the second window 2302.

The user continues to input the control command based on the volume down key 2304, and the TV, in response to the control command, decreases the amplitude ratio of the first audio or video to 0 and increasing the amplitude ratio of the second audio or video to 100%. If the user continues to input the control command based on the volume down key 2304, the TV, in response to the control command, switches to decreasing the system volume. As shown in \textcircled{4} of FIG. 23, the TV displays a volume bar 2305 of the system volume, such as the current volume is 20.

In some embodiments, in the third multi-window mode, the display device may display at least two

windows.

In some embodiments, in the third multi-window mode, if the display device displays two windows, the display device can adjust the volumes of audios or videos in the two windows in accordance with the method of adjusting the volume in the second multi-window mode, which is not repeated here.

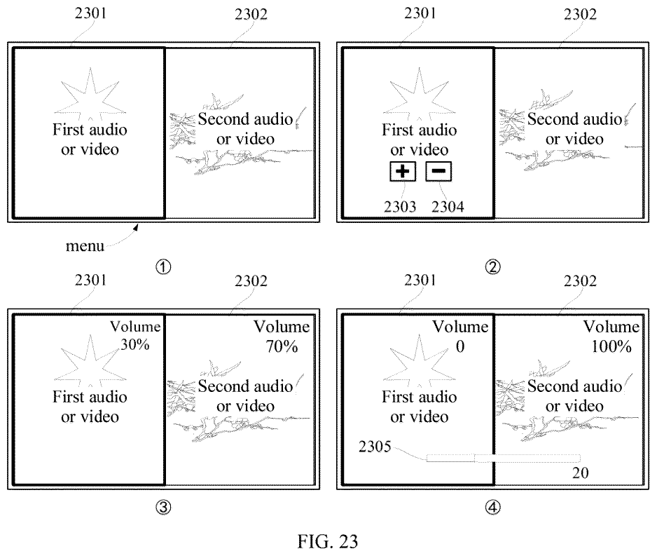

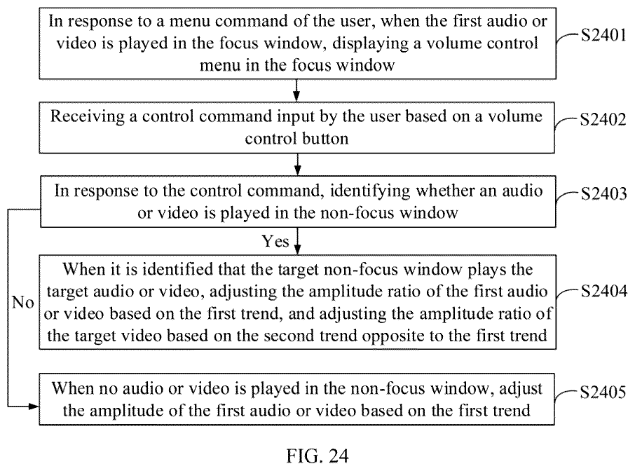

In some embodiments, in the third multi-window mode, if the display device displays three windows, the display device may adjust the volume according to the process shown in FIG. 24, and the specific steps may include but are not limited to the following.

S2401, in response to a menu command from the user, when the first audio or video is played in the focus window, a volume control menu is displayed in the focus window.

S2402, a control command input by the user is received based on the volume control button.

S2403, in response to the control command, whether an audio or video is played in the non-focus window is identified.

Steps S2401-S2403 may refer to steps S2101-S2103, which are not described in detail here. The process of displaying the volume control menu in the focus window may refer to steps S2201-S2203. In the third multi-window mode, the window distribution is more complex and may include: horizontal distribution, vertical distribution, and a combination of horizontal distribution and vertical distribution.

S2404, when it is identified that a target non-focus window plays a target audio or video, the amplitude ratio of the first audio or video is adjusted based on the first trend, and the amplitude ratio of the target video is adjusted based on the second trend opposite to the first trend. The sum of the adjusted amplitude ratio of the first audio or video and the adjusted amplitude ratio of the target audio or video is equal to the preset total ratio.

In some embodiments, if only one of the two non-focus windows plays audio or video, the non-focus window playing the audio or video may be the target non-focus window, and the audio or video may be the target audio or video. The display device may refer to the step S2104 to adjust the amplitude ratio of the first audio or video and the amplitude ratio of the target audio or video, which will not be repeated here.

In some embodiments, if audios or videos are played in two non-focus windows, the two non-focus windows are both target non-focus windows, and the two audios or videos are both target audios or videos. For ease of description, the two non-focus windows are respectively a first non-focus window and a second non-focus window, where the second audio or video can be played in the first non-focus window, and the third audio or video can be played in the second non-focus window. The display device can adjust the amplitude ratio of the first audio or video based on the first trend, and can adjust the amplitude ratios of the second audio or video and the third audio or video based on the second trend opposite to the first trend. The sum of the adjusted amplitude ratio of the first audio or video, the adjusted amplitude ratio of the second audio or video, and the adjusted amplitude ratio of the third audio or video can be equal to the preset total ratio.

When the display device adjusts the amplitude ratios of the second audio or video and the third audio or video based on the second trend, the amplitude ratios of the second audio or video and the third audio or video can be adjusted based on the same ratio. For example, the display device 200 can increase the amplitude ratio of the first audio or video, such as by 4%, and can decrease the amplitude ratios of the second audio or video and the third audio or video by 2%.

When the display device adjusts the amplitude ratios of the second audio or video and the third audio or video based on the second trend, the amplitude ratios of the second audio or video and the third audio or video can be adjusted based on different ratios. For example, the display device 200 can increase the amplitude ratio of the first audio or video, such as by 4%, and can decrease the amplitude ratio of the second audio or video by 1%, and decrease the amplitude ratio of the third audio or video by 3%.

S2405, when no audio or video is played in the non-focus window, the amplitude of the first audio or video is adjusted based on the first trend.

Step S2405 is similar to step S1705 and will not be described again here.

In some embodiments, in the third multi-window mode, if the display device displays more than three windows, the display device can adjust the volume with reference to steps S2401-S2405, which are not described in detail here.

In the third multi-window mode, during the display device adjusts the volume, if the amplitude ratio of the first audio or video reaches the preset total ratio or 0, the system volume can be adjusted based on the first trend. This process can refer to the process in which the display device, in the first multi-window mode, the system volume is adjusted based on the first trend if the amplitude ratio of the first audio or video reaches the preset total ratio or 0, and will not be repeated here.

After switching from adjusting the volume of the audio or video to adjusting the system volume, during the process of adjusting the system volume, if the display device, in response to the control command from the user, adjusts the system volume to the specified volume based on the second trend, e.g., switch to a volume when the system volume is adjusted or the maximum value of the system volume on the second trend, then the display device can switch back to adjusting the amplitude ratio of the first audio or video based on the second trend. This process can refer to the process in which if the display device is in the first multi-window mode, and in response to the control command from the user, adjusts the system volume to the specified volume based on the second trend, then it can switch back to adjusting the amplitude ratio of the first audio or video based on the second trend, and it will not be repeated here.

In the third multi-window mode, the display device may display the volume with reference to steps S1901-S1903, which will not be described in detail here.

If the user switches the focus to another window, the display device can use the another window as the focus window and adjust the volumes of the audios or videos in the focus window and the non-focus window according to a process similar to the above, which is not repeated here.

Taking a TV as an example, the process of adjusting the volume of the display device in the third multi-window mode is described.

### Example 4

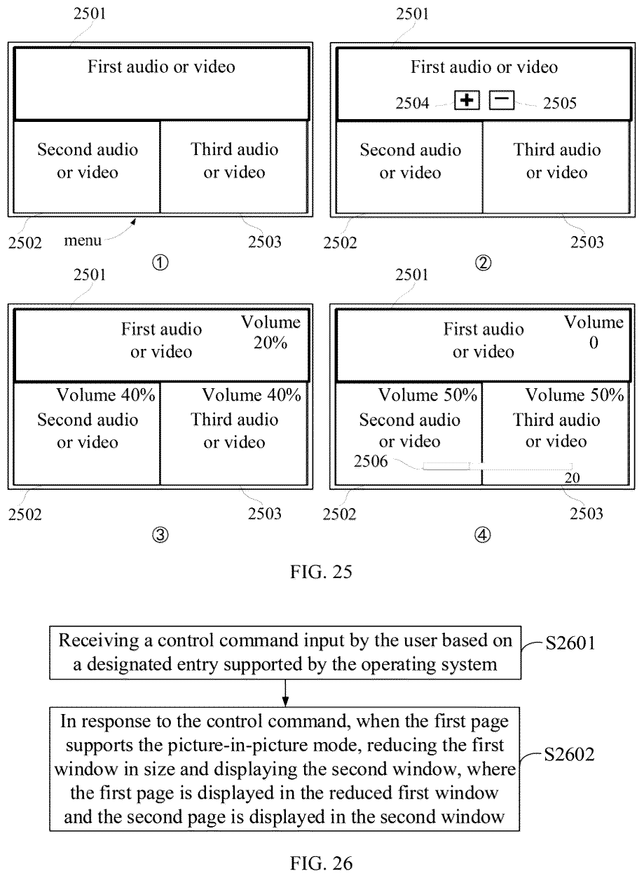

In the second multi-window mode, as shown in \textcircled{1} in FIG. 25, the TV plays the first audio or video in the first window 2501, plays the second audio or video in the second window 2502, and plays the third audio or video in the third window 2503. The user inputs a menu command through the menu key on the control device 100, and the TV, in response to the menu command, determines the focus window, such as the first window 2501 (the focus is shown in a thick black solid line frame). When the TV identifies that the audio or video is played in the first window 2501, the TV can determine the display position of the volume control menu based on the first window 2501 and the window distribution (one window on the upper side and two windows horizontally distributed on the lower side), such as the horizontal center position at the bottom of the upper window. As shown in \textcircled{2} in FIG. 25, the TV can display the volume control menu in the first window 2501, and the volume control menu may include volume control buttons, such as a volume up key 2504 and a volume down key 2505. If the user inputs a control command based on the volume down key 2505, the TV, in response to the control command, identifies a non-focus window, such as the second window 2502 in which the second audio or video is played, and playing the third window 2503 in which the third audio or video is played, then the TV can decrease the amplitude ratio of the first audio or video, and can increase the amplitude ratio of the second audio or video and the third audio or video. Taking the amplitude ratio of the first audio or video before adjustment as 40%, the amplitude ratio of the second audio or video before adjustment as 30%, and the amplitude ratio of the third audio or video before adjustment as 30% as an example, if the amplitude ratio of the first audio or video is decreased by 20%, the amplitude ratio of the first audio or video after adjustment can be 20%, the amplitude ratio of the second audio or video after adjustment can be 40%, and the amplitude ratio of the third audio or video after adjustment can be 40%. As shown in \textcircled{3} in FIG. 25, the TV displays a volume of 20% in the first window 2501, a volume of 40% in the second window 2502, and a volume of 40% in the second window 2503. The user can continue to input the control command based on the volume down key 2505, and the TV, in response to the control command, can decrease the amplitude ratio of the first audio or video to 0, increase the amplitude ratio of the second audio or video to 50%, and increase the amplitude ratio of the third audio or video to 50%. If the user continues to input the control command based on the volume down key 2505, the TV, in response to the control command, can switch to decreasing the system volume. As shown in \textcircled{4} of FIG. 25, the TV can display a volume bar 2506 of the system volume, such as the current volume is 20.

The following is an explanation of how to enable the PiP mode on display devices.

After enabling the PiP mode, the display device displays two windows, which may include a main window and a PiP window. The PiP window can be displayed above the main window, the main window is in the full screen state, the size of the PiP window can be smaller than the size of the main window, the main window can be used to display the application currently mainly used by the user, and the PiP window can be used to display a page of the application that the user currently needs to browse at the same time as the application currently mainly used. The page can be a complete page of the application or a partial page of the application. If the page is a partial page of the application, the partial page may include the main content of the complete page. For example, the PiP window can display the complete video page of a video application, and can also display the video screen in the video page.

Usually, the application itself provides an entry to enable the PiP mode, and the application itself calls the interface of the PiP mode to enter the PiP mode. For example, the operating system can provide an interface, such as enterPictureInPictureMode, for entering the PiP mode for the application, and allow the application to customize the scene to switch the page to the PiP window for display. The application usually provides an entry to enable the PiP mode in the application page based on the developer's page design. If the user wants to enable the PiP mode and switch the current application page to the PiP window for display, the user needs to find the entry to enable the PiP mode provided by the application and input a command based on the entry. In response to the command, the application declares the current page as supporting the PiP mode, such as setting the android: supportsPictureInPicture of the corresponding page (Activity) to true in the application manifest file. The application calls the enterPictureInPictureMode interface provided by the system in a customized scene to switch the Activity to the PiP window for display, thereby enabling the PiP mode. It can be seen that the user can only place the application page in the PiP window through the entry provided by the application, and the application can only control its own page to enter the PiP mode.

Limited by the fact that the PiP mode must be enabled by the application itself, the user can only make the application enter the PiP mode through the entry provided by the application. However, the entries provided by different applications have different display positions, triggering methods, etc., in the corresponding applications, which is not convenient for users to quickly enable the PiP mode. In view of this, the display device according to some embodiments of the present application can provide a unified entry supported by the operating system for the applications each to enter the PiP mode. Based on the system architecture shown in FIG. 5C, the display device can configure a designated entry supported by the operating system for each application to enable the PiP mode, and the designated entry may include a first button (e.g., a PiP key) on the control device, a second button (e.g., a PiP key) on the virtual keyboard of the display device, and a first entry in the system menu. The first button corresponds to a first key value, such as PiP, and the second button corresponds to a second key value, such as PiP, and the first key value and the second key value correspond to enabling the PiP mode. In some embodiments, the system menu can be a shortcut menu. The designated entry is independent of the application itself and is not affected by the application itself. Therefore, the designated entry is a unified entry for the applications each to enable the PiP mode.

According to another processing method of the display device in some embodiments of the present application, it is mainly used to enable the PiP mode. Based on this method, the user can quickly enable the PiP mode based on the unified entry for enabling the PiP mode provided by the display device, and display the current page in the PiP mode.

In some embodiments, the display device is not in the PiP mode. The display device has created the first window and the second window, and displays the first page in the first window and the second page in the second window. The first window and the second window are located in one layer, the window level of the first window is higher than the window level of the second window, and the first window is in the full screen state. Therefore, the display device preferentially displays the first page in the first window. In this state, the user can only see the first page and cannot see the second page.

The process of creating multiple windows on the display device can be referred to as the following example.

For example, based on the system architecture shown in FIG. 5C, when the display device displays the Launcher page, the Launcher page may include a video option. If the user inputs a control command based on the video option, the display device plays the video in response to the control command. The playback page of the video is the first page, and the window where the playback page of the video is located is the first window; the Launcher page is the second page, and the window where the Launcher page is located is the second window. The playback page of the video is displayed above the Launcher page, and the user can view the playback page of the video, but cannot view the Launcher page located below.

For another example, still based on the system architecture shown in FIG. 5C, when the display device displays the Launcher page, the Launcher page includes a video application option. If the user inputs a control command based on the video application option, the display device 200 enters the video application page in response to the control command, and the video application page includes a video option. If the user inputs a control command based on the video option, the display device plays the video in response to the control command. The playback page of the video is the first page, and the window where the playback page of the video is located is the first window; the video application page is the second page, and the window where the video application page is located is the second window. The playback page of the video is displayed above the video application page, and the window where the Launcher page is located has the lowest level, so the Launcher page is displayed below the video application page. At this time, the user can watch the video, but cannot see the video application page and Launcher page located below.

In some embodiments, the second window may also be in the full screen state.

The display device may enable the PiP mode according to the process shown in FIG. 26, and the specific steps may include but are not limited to the following.

S2601, a control command input by the user is received based on a designated entry supported by the operating system.

The control command can be used to indicate to enable the PiP mode.

In some embodiments, the user may input the control command to the display device by pressing the first button on the control device.

In some other embodiments, the user can input a command to the display device through the control device to make the display device display a virtual keyboard (keypad), and the virtual keyboard may include a second button. The user can control the focus to move to the second button in the virtual keyboard through the control device, and input a control command to the display device by pressing the OK key on the control device.

In some other embodiments, the user may input a command to the display device through the control device to cause the display device to display the system menu, and the system menu may include a first entry, such as an option for the PiP mode. The user may control the focus to move to the first entry in the system menu through the control device, and may input a control command to the display device by pressing the OK key on the control device.

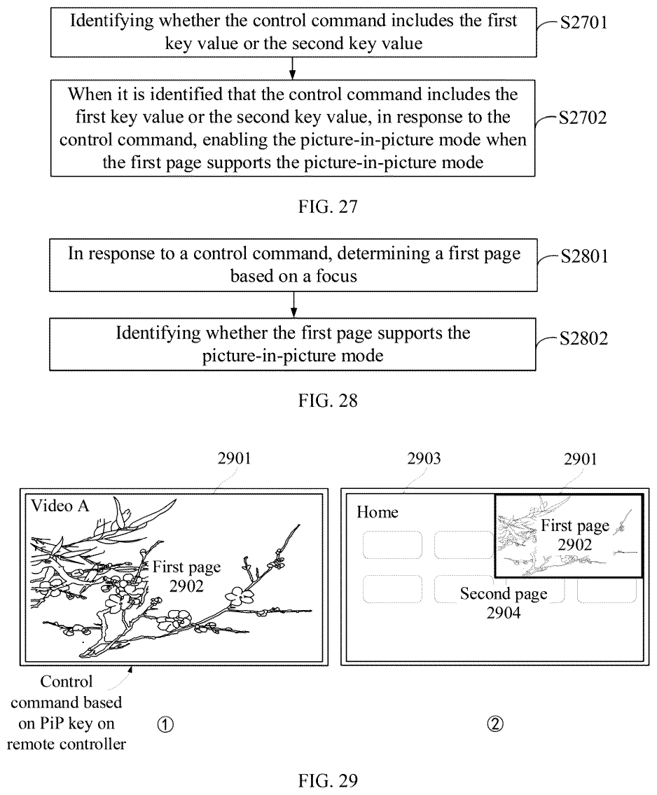

If the control command received by the display device includes a key value, the display device may enable the PiP mode according to the process shown in FIG. 27, and the specific steps may include but are not limited to the following.

S2701, whether the control command includes the first key value or the second key value is identified.

Based on the system architecture shown in FIG. 5C, the Bluetooth driver or infrared driver can receive the key event sent by the control device, and can send the key event to the framework layer. Alternatively, the application layer receives a click event (such as clicking the second button), and can send the click event to the framework layer. After receiving the key event or click event through the mobile phone window management class in the system service of the framework layer, the display device can determine whether it includes the first key value or the second key value through the key value.

The display device identifies whether the control command is a command input based on the first key of the control device based on the first key value. The display device identifies whether the control command is a command input based on the second key on the virtual keyboard based on the second key value.

S2702, when it is identified that the control command includes the first key value or the second key value, in response to the control command, the picture-in-picture mode is enabled when the first page supports the picture-in-picture mode.

If the display device identifies that the control command includes the first key value or the second key value, it can determine that the control command is a command for enabling the PiP mode. In response to the control command, the display device can call the PiP method in the page task management service through the mobile phone window management class to enable the PiP mode.

If the display device identifies that the control command does not include the first key value and the second key value, it needs to identify whether the control command is a command input based on the first entry in the system menu. If the display device determines that the control command is not a command for enabling the PiP mode, the PiP mode is not enabled.

S2602, in response to the control command, when the first page supports the picture-in-picture mode, the first window is reduced in size and the second window is displayed, where the first page is displayed in the reduced first window and the second page is displayed in the second window.

After enabling the PiP mode, the size of the first window can be reduced, and the second window with a lower window level can be exposed. The reduced first window and the second window in the full screen state are still in the same layer, and the window level of the reduced first window can still be higher than the window level of the second window in the full screen state. At this time, the reduced first window can be used as a PiP window, and the second window in the full screen state can be used as the main window. The first page can be displayed in the reduced first window, and the second page can be displayed in the second window, so that the first page can be displayed in the PiP mode and the second page can be displayed in the full screen state, and the user can view the first page and the second page at the same time.

The display device identifies whether the first page supports the PiP mode in response to the control command. When the first page supports the PiP mode, the display device may enable the PiP mode to ensure the validity of the PiP mode.

The display device may identify whether the first page supports the PiP mode according to the process shown in FIG. 28, and the specific steps may include but are not limited to the following.

S2801, in response to a control command, a first page is determined based on a focus.

The page where the focus is located is the page (Activity) currently being displayed. Based on the system architecture shown in FIG. 5C, the display device can obtain the root task stack where the focus is located through the page task management service in the system service of the framework layer, and obtain the page, i.e., the page where the focus is located, in the foreground interactive (resume) state through the root task stack. In this embodiment, the page where the focus is located is the first page.

S2802, identifying whether the first page supports the picture-in-picture mode.

The applications can declare pages that support the PiP mode in their respective manifest files based on business scenarios, such as recording the support relationship between the page and PiP mode in the manifest file, carrying an identifier on the page that supports the PiP mode, and recording the correspondence between the page and the identifier in the manifest file. The display device identifies whether the first page supports PiP mode by determining whether the first page is a page that supports PiP mode declared by the current application. For example, the system service can determine whether the first page supports the PiP mode through the ActivityRecordsupportsPictureInPicture() method.

If the display device identifies that the first page does not support the PiP mode, it displays a prompt message, and the prompt message is used to prompt that the first page does not support the PiP mode. At this time, the display device does not enable the PiP mode, that is, does not change the size of the first window.

In some embodiments, the first window may be an application window, and the first page may include an application page, a live program page, etc. In some other embodiments, the first window may be a main window of an operating system, and the first page may be a Launcher page, and for example, the display device is configured that the window level of the main window of the operating system is set to the highest level, or the display device currently only creates the first window and does not create the second window. The page that does not support the PiP mode may include a launcher page, etc.

In some embodiments, the display device may display the prompt message in the form of a pop-up window.

If the display device identifies that the page supports the PiP mode, that is, the first page supports the PiP mode, the display device enables the PiP mode. For example, the system service can switch the current page to the PiP window display through the enterPictureInPictureMode method of the ActivityTaskManagerService class to enable the PiP mode.

Before enabling the PiP mode, the display device identifies whether it is currently in the PiP mode. In this embodiment, the display device can determine that it is not currently in the PiP mode, and then the display device can enable the PiP mode.

Taking the display device as a TV and the control device as a remote controller as an example, the following example is used to explain how to enable the PiP mode on the display device.

### Example 5

As shown in \textcircled{1} in FIG. 29, the TV displays a first page 2902, e.g. a video page A, in a first window 2901, and displays a second page 2904, e.g., a Launcher page, in a second window 2903 (not shown in \textcircled{1} in FIG. 29). The first window 2901 is in the full screen state, and the first window 2901 and the second window 2903 are located in the same layer, and the window level of the first window 2901 is higher than that of the second window 2903. In this way, the TV preferentially displays the first window 2901, and the user can only view the first page 2902. The remote controller may include a first button, e.g., a PiP key, and the user inputs a control command to the TV by pressing the PiP key. After receiving the control command, the TV identifies that the control command includes a first key value, e.g., PiP, thereby determining that the control command is used to indicate enabling the PiP mode. In response to the control command, the TV identifies whether the first page 2902 supports the PiP mode. If the TV identifies that the first page 2902 supports the PiP mode, the TV identifies whether it is currently in the PiP mode. If the TV identifies that it is not currently in the PiP mode, it enables PiP mode. As shown in \textcircled{2} in FIG. 29, the TV reduces the first window 2901 in size and exposes the second window 2903 with a lower window level. The TV displays the first page 2902 in the reduced first window 2901 and displays the second page 2904 in the second window 2903 in the full screen state.

### Example 6

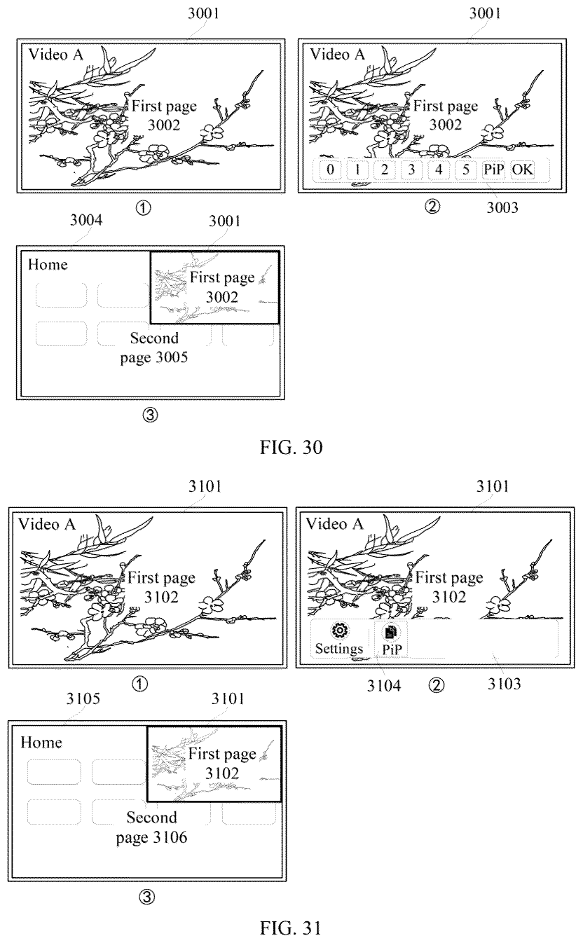

As shown in \textcircled{1} in FIG. 30, the TV displays a first page 3002, e.g., a video page A, in a first window 3001, and displays a second page 3005, e.g., a Launcher page, in a second window 3004 (not shown in \textcircled{1} in FIG. 30). The first window 3001 is in the full screen state, and the first window 3001 and the second window 3004 are located in the same layer, and the window level of the first window 3001 is higher than that of the second window 3004. In this way, the TV preferentially displays the first window 3001, and the user can only view the first page 3002. The user controls the TV to display a virtual keyboard 3003 on the first page 3002 through a remote controller, as shown in \textcircled{2} in FIG. 30, and the virtual keyboard 3003 includes a second button, e.g., a PiP key. The user moves the focus to the PiP key through the remote controller, and inputs a control command to the TV by pressing the OK key on the remote controller. After receiving the control command, the TV identifies that the control command includes a second key value, e.g., PiP, and thus can determine that the control command is used to indicate enabling the PiP mode. In response to the control command, the TV identifies whether the first page 3002 supports the PiP mode. If the TV identifies that the first page 3002 supports the PiP mode, the TV identifies whether it is currently in the PiP mode. If the TV identifies that it is not currently in the PiP mode, the PiP mode is enabled. As shown in \textcircled{3} in FIG. 30, the TV reduces the first window 3001 in size and exposes the second window 3004 with a lower window level. The TV displays the first page 3002 in the reduced first window 3001, and displays the second page 3005 in the second window 3004 in the full screen state.

### Example 7

As shown in \textcircled{1} of FIG. 31, the TV displays a first page 3102, e.g., a video page A, in a first window 3101, and displays a second page 3106, e.g., a Launcher page, in a second window 3105 (not shown in \textcircled{1} of FIG. 31). The first window 3101 is in the full screen state, and the first window 3101 and the second window 3105 are located in the same layer, and the window level of the first window 3101 is higher than that of the second window 3105. In this way, the TV preferentially displays the first window 3101, and the user can only view the first page 3102. The user controls the TV to display a system menu 3103 on the first page 3102 through a remote controller, as shown in \textcircled{2} of FIG. 31, and the system menu 3103 can be a shortcut menu, which can include a first entry, e.g., an option 3104 of the PiP mode. The user moves the focus to option 3104 through the remote controller, and inputs a control command to the TV by pressing the OK key on the remote controller. After receiving the control command, the TV identifies whether the first page 3102 supports the PiP mode in response to the control command. If the TV identifies that the first page 3102 supports the PiP mode, the TV identifies whether it is currently in the PiP mode. If the TV identifies that it is not currently in the PiP mode, the PiP mode is enabled. As shown in \textcircled{3} in FIG. 31, the TV reduces the first window 3101 in size and exposes the second window 3105 with a lower window level. The TV displays the first page 3102 in the reduced first window 3101, and displays the second page 3106 in the second window 3105 in the full screen state.

### Example 8

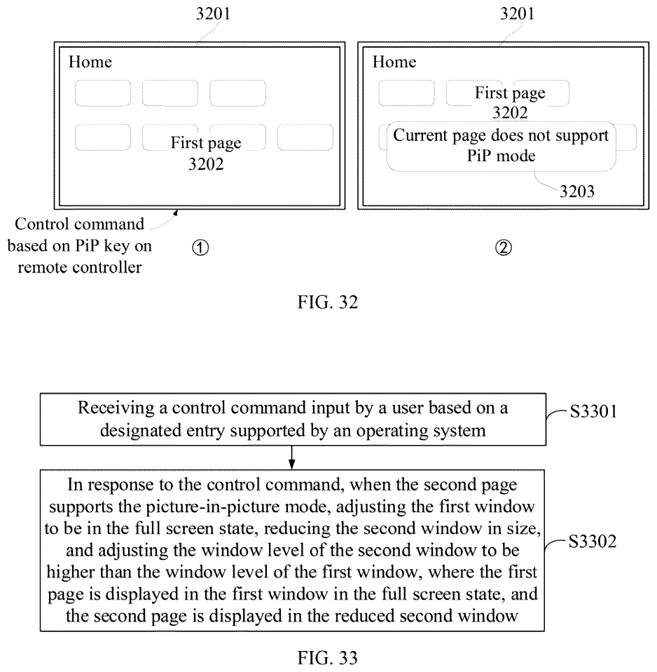

As shown in \textcircled{1} of FIG. 32, the TV displays, e.g., a Launcher page, a first page 3202 in a first window 3201 and displays a second page in a second window (not shown in \textcircled{1} of FIG. 32). Both the first window 3201 and the second window are in the full screen state, and the TV is configured to set the window level of the main window of the operating system to the highest level. The first window 3201 and the second window are located in one layer, and the window level of the first window 3201 is higher than that of the second window. In this way, the TV preferentially displays the first window 3201, and the user can only view the first page 3202. The remote controller may include a first button, e.g., a PiP key. Taking the example of a user inputting a control command to the TV based on the PiP key, the TV identifies whether the first page 3202 supports the PiP mode in response to the control command. If the Launcher page does not support the PiP mode, the TV does not enable the PiP mode, and displays a prompt message on the first page 3202. As shown in \textcircled{2} of FIG. 32, the TV may display a prompt message in the form of a pop-up window 3203, e.g., the current page does not support the PiP mode.

In some other embodiments, the display device is not in the PiP mode. The display device has created multiple windows, the multiple windows include at least a first window and a second window, the first page is displayed in the first window, and the second page is displayed in the second window. The multiple windows can be located in the same layer, the window level of the first window and the second window can be higher than the window level of other windows, the window level of the first window can be higher than the window level of the second window, and the first window is in the full screen state. In some embodiments, the second window can also be in the full screen state.

In some embodiments, the display device is not in the PiP mode. The display device has created a first window and a second window, and can display a first page in the first window, and can display a second page in the second window. The first window and the second window may be located in different layers, the level of the layer to which the first window belongs may be higher than the level of the layer to which the second window belongs, and the first window is in the full screen state. In some embodiments, the second window may also be in the full screen state. Therefore, the display device may preferentially display the first page in the first window. In this state, the user can only see the first page, and cannot see the second page. The display device can enable the PiP mode with reference to steps S2601-S2602, S2701-S2702, and S2801-S2802, which are not repeated here. The main difference is that the reduced first window and the second window in the full screen state are still located in different layers, where the level of the layer to which the reduced first window belongs may still be higher than the level of the layer to which the second window in the full screen state belongs.

In some other embodiments, the display device is not in the PiP mode. The display device has created multiple windows, the multiple windows at least include a first window and a second window, the first page is displayed in the first window, and the second page is displayed in the second window. The first window is in the full screen state, and in some embodiments, the second window may also be in the full screen state. The multiple windows may be located in at least two layers, the first window and the second window may be located in different layers, the level of the layer to which the first window belongs may be higher than the level of the layer to which the second window belongs, and the level of the layer to which the second window belongs may be higher than or equal to the level of the layers to which other windows belong. If the level of the layer to which the second window belongs is equal to the level of the layer to which other windows belong, the window level of the second window may be higher than the window level of other windows.

In some embodiments, the display device is in the PiP mode. The display device can display a first page in a first window, and can display a second page in a second window. The second window is in the full screen state, and the size of the first window can be smaller than the size of the second window, where the first window and the second window can be located in the same layer, and the window level of the first window can be higher than the window level of the second window. Therefore, the display device can preferentially display the first page in the first window. In this state, the first window can block the second window. The display device can adjust the PiP mode according to the process shown in FIG. 33, and the specific steps may include but are not limited to the following.

S3301, a control command input by a user is received based on a designated entry supported by an operating system.

This control command is used to indicate to enable the PiP mode.

Step S3301 is similar to step S2601 and will not be repeated here.

The process of the display device identifying the control command is similar to steps S2701-S2702 and will not be repeated here.

S3302, in response to the control command, when the second page supports the picture-in-picture mode, the first window is adjusted to be in the full screen state, the second window is reduced in size, and the window level of the second window is adjusted to be higher than the window level of the first window. The first page is displayed in the first window in the full screen state, and the second page is displayed in the reduced second window.

When the display device is in the PiP mode, the PiP mode can be adjusted to switch a page displayed in the PiP mode, that is, the current main window can be adjusted to a PiP window, and the page in the current main window can be displayed in the adjusted PiP window; and the current PiP window can be adjusted to a main window, and the page in the current PiP window can be displayed in the adjusted main window. The current main window can be the second window, and the current PiP window can be the first window. After enabling the PiP mode, by adjusting the first window to be in the full screen state, reducing the size of the second window, and adjusting the window level of the second window to be higher than the window level of the first window, the second window is displayed preferentially, and the first window is adjusted to the main window and the second window is adjusted to the PiP window. The display device displays the first page in the adjusted first window, and displays the second page in the adjusted second window. Moreover, since the size of the second window is smaller than the first window, the display device can display the pages in the first window and the second window at the same time, so as to switch the first page displayed in the PiP mode to the second page.

In some embodiments, the second window may be a main window of an operating system, and the second page may be a Launcher page. In some other embodiments, the second window may be an application window, and the second page may include an application page, a live program page, etc. The page that does not support the PiP mode may include a launcher page, etc.

Before enabling the PiP mode, the display device can identify whether the second page supports the PiP mode. The process can refer to steps S2801-S2802 and will not be repeated here.

If the display device identifies that the second page does not support the PiP mode, it can display a prompt message, which can be used to prompt that the second page does not support the PiP mode. At this time, the display device may not switch the page displayed in the PiP mode.

In some embodiments, the display device may display the prompt message in the form of a pop-up window.

Before adjusting the PiP mode, the display device may identify whether it is currently in the PiP mode. In some embodiments, the display device may determine that it is currently in the PiP mode, and the display device may start adjusting the PiP mode to switch the page displayed in the PiP mode.

Assuming that the display device is a TV and the control device is a remote controller, the remote controller may include a first button, e.g., a PiP key, and taking the user inputting control commands to the TV based on the PiP key as an example, the process of switching the display device to display a page in the PiP mode is explained in combination with the following examples.

### Example 9

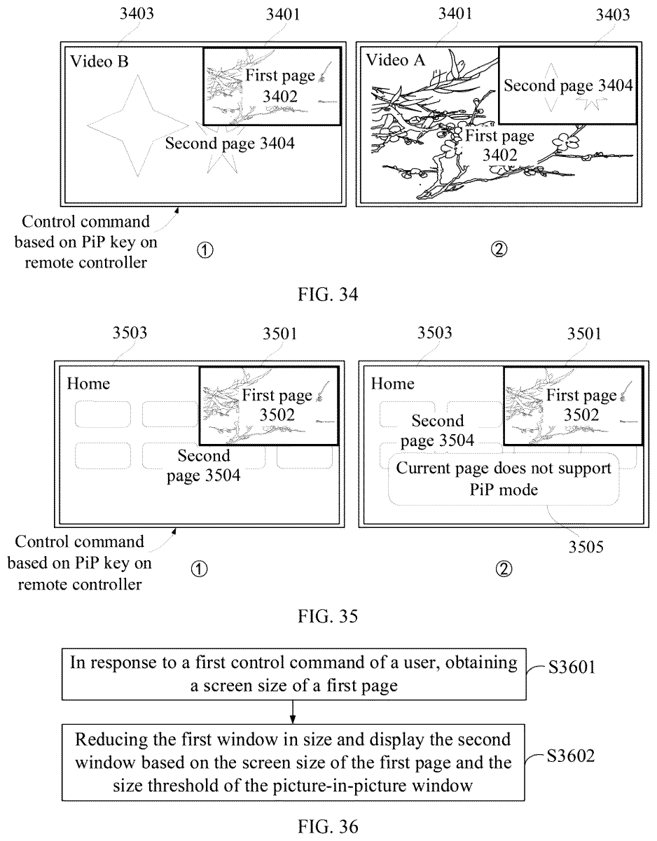

As shown in \textcircled{1} of FIG. 34, the TV displays the first page 3402, e.g., video page A, in the first window 3401, and displays the second page 3404, e.g., video page B, in the second window 3403. The second window 3403 is in the full screen state, and the size of the first window 3401 is smaller than the size of the second window 3403. The first window 3401 and the second window 3403 are located in the same layer, and the window level of the first window 3401 is higher than that of the second window 3403, that is, the first page 3402 is displayed in the PiP mode. The TV, in response to the control command input by the user based on the PiP key, identifies whether the second page 3404 supports PiP mode. If the TV determines that the second page 3404 supports PiP mode, the TV identifies whether it is currently in the PiP mode, and the TV determines that it is in the PiP mode, then the TV switches the page displayed in the PiP mode. As shown in \textcircled{2} of FIG. 34, the TV adjusts the first window 3401 to be in the full screen state, reduces the second window 3403 in size, and adjusts the window level of the second window 3403 to be higher than the window level of the first window 3401. The TV displays the second page 3404 in the reduced second window 3403 and displays the first page 3402 in the first window 3401 in the full screen state, so as to switch the display of the first page 3402 in the PiP mode to the display of the second page 3404.

### Example 10

As shown in \textcircled{1} of FIG. 35, the TV displays a first page 3502, e.g., a video page A, in a first window 3501, and displays a second page 3504, e.g., a Launcher page, in a second window 3503. The second window 3503 is in the full screen state, and the size of the first window 3501 is smaller than the size of the second window 3503. The first window 3501 and the second window 3503 are located in the same layer, and the window level of the first window 3501 is higher than that of the second window 3503, that is, the first page 3502 is displayed in the PiP mode. The TV, in response to the control command input by the user based on the PiP key, identifies whether the second page 3504 supports PiP mode. If the TV determines that the second page 3504 does not support PiP mode, the TV does not switch the page displayed in the PiP mode, and displays a prompt message. As shown in \textcircled{2} of FIG. 35, the TV can display a prompt message in a pop-up window 3505, such as the current page does not support PiP mode.

In some embodiments, the display device is in the PiP mode. The display device has created multiple windows, which may include a first window and a second window, and the first page may be displayed in the first window, and the second page may be displayed in the second window. The second window is in the full screen state, and the size of the first window may be smaller than the size of the second window, where the multiple windows may be located in the same layer, and the window levels of the first window and the second window may be higher than the window levels of other windows, and the window level of the first window may be higher than the window level of the second window. When adjusting the PiP mode, the display device may adjust the window level of the second window to be higher than the window level of the first window, and ensure that the window level of the first window is higher than the window level of other windows.

In some other embodiments, the display device is in the PiP mode. The display device can display a first page in a first window, and can display a second page in a second window. The second window is in the full screen state, and the size of the first window can be smaller than the size of the second window, where the first window and the second window can be located in different layers, and the level of the layer to which the first window belongs can be higher than the level of the layer to which the second window belongs. Therefore, the display device can preferentially display the first page in the first window. In this state, the first window can block the second window. The display device can adjust the PiP mode with reference to steps S3301-S3302. The main difference from step S3302 is that the display device adjusts the level of the layer to which the second window belongs to be higher than the level of the layer to which the first window belongs to, so as to preferentially display the second window. In this state, the second window can block the first window.

In some other embodiments, the display device is in the PiP mode. The display device has created multiple windows, the multiple windows include at least a first window and a second window, and the first page can be displayed in the first window, and the second page can be displayed in the second window. The second window is in the full screen state, the size of the first window can be smaller than the size of the second window, where the multiple windows can be located in at least two layers, the first window and the second window can be located in different layers, the level of the layer to which the first window belongs can be higher than the level of the layer to which the second window belongs, and the level of the layer to which the second window belongs can be higher than or equal to the level of the layer to which other windows belong. If the level of the layer to which the second window belongs can be equal to the level of the layer to which other windows belong, the window level of the second window can be higher than the window level of other windows. When adjusting the PiP mode, the display device adjusts the level of the layer to which the second window belongs to be higher than the level of the layer to which the first window belongs, and ensures that the level of the layer to which the first window belongs is higher than the level of the layer to which other windows belong, or when the level of the layer to which the first window belongs is the same as that of other windows, the window level of the first window is adjusted to the highest level in the layer.

Usually, when the display device enables the PiP mode, the width or height of the PiP window is fixed. When displaying a page in the PiP window, the size of the PiP window can only be adjusted by changing the aspect ratio of the PiP window based on the fixed width or height. Taking the first window after reduction as the PiP window as an example, the size of the first window after reduction is relatively fixed. Different pages have different requirements for the screen size, and the size of the PiP window may not match the page size of the displayed page, which will cause the page displayed in the PiP window to be incompletely displayed, unable to fill the PiP window, and out of proportion. Based on the system architecture shown in FIG. 5D, according to some embodiments of the present application, the display device can make the size of the PiP window match the screen size of the page displayed therein after enabling the PiP mode to improve the display quality of the page in the PiP window. Based on the system architecture shown in FIG. 5D, the customized content of the PiP parameter class, PiP tool and Wmshell is explained below.

The PiP parameter class can represent the parameters of the page of the application in the PiP mode initialization (such as when the current page enters the PiP mode) and update (such as when the current PiP window needs to be resized), which can implement the Parcelable interface, so the PiP parameters can be serialized to the content and inter-process communication (IPC) can be performed. In the customized PiP parameter class, width and height attributes are added, and the writeToParcel and Parcel constructors are modified, so that the width and height can be serialized and deserialized normally. Because the PiP parameter class is constructed using the builder pattern, it is also necessary to add corresponding attributes and methods in its internal classes (such as Builder).

The PiP tool is a bridge connecting the application layer and the framework layer. It mainly provides two methods for the display of the PiP window, including determining the size of the PiP window when the current page enters the PiP mode, and dynamically adjusting the size of the PiP window when the PiP window is displayed. The PiP tool holds a reference to the page of the application. When the current page enters the PiP mode, it can assemble the screen size, i.e., the PiP parameters, required for the current page and call the native interface of the page, e.g., the enterPictureInPictureMode method to carry the PiP parameters, to make the current page enter PiP mode. Based on the extended PiP parameter class, upper-level developers cannot directly call customized methods. To solve this problem, the PiP tool uses a reflection mechanism to call the setting method. When dynamically adjusting the size of the PiP window, it can assemble the changed PiP parameters, pass in the changed width and height, and update the size of the PiP window by calling the native interface of the page, such as the setPictureInPictureParams method.

Wmshell can provide a toolkit for more efficient window management, which can be located in the directory of framework/base/libs/WindowManager. Wmshell provides various window management tool sub-packages, such as PiP sub-package, SplitScreen sub-package, FreeForm sub-package, Compatibility User Interface (CompatUI), Desktop Mode, etc. In some embodiments, WMS customization can be in the PiP sub-package. After the PiP tool calls the enterPictureInPictureMode method or the setPictureInPictureParams method of the page, it passes the PiP parameters to WMS. The system user interface (SystemUI) initializes Wmshell through the system user interface factory (SystemUIFactory) class at startup, and calls the init method of the shell initialization (ShellInit) class, and calls the register organizer (registerOrganizer) method of the shell task organizer (ShellTaskOrganizer) class in its implementation class, such as the ShellInitImpt class. Among them, ShellTaskOrganizer is a subclass of task organizer (TaskOrganizer). Finally, the TaskOrganizer class registers the callback to WindowManagerService through the registerTaskOrganizer method of the ItaskOrganizerController. When the Task changes, TaskOrganizer receives the callback from WMS and then calls the corresponding method in TaskOrganizer. For example, when the Task appears, the onTaskAppeared method is called back; and when the Task changes, the onTaskInfoChanged method is called back. As a subclass of TaskOrganizer, ShellTaskOrganizer can receive these callbacks, and ShellTaskOrganizer can maintain a sparse array (SparseArray) object of task listener (TaskListener). In the ShellTaskOrganizer callback method, the TaskListener object can be taken out from the SparseArray and the corresponding method of the object can be executed.

The TaskListener registration of PiP under Wmshell is in the constructor of the PiPTaskOrganizer class. When WMS triggers a callback, PiPTaskOrganizer can also receive the corresponding callback.

In summary, the customization of Wmshell PiP mainly involves two parts: forwarding processing of WMS callbacks, which can include the parsing of the screen size, i.e. the size of the PiP window, and forwarding rules of callbacks. The storage and calculation of the screen size, i.e. the size of the PiP window, and the adjustment of the PiP window are included.

The forwarding process of WMS callback is explained.

From the above description, it can be known that the callback notification of WMS to Task is in Wmshell ShellTaskOrganizer. The PiPTaskOrganizer class registers the TaskLisenter callback of ShellTaskOrginzer, so PiPTaskOrganizer can receive the corresponding callback method. In some embodiments of the present application, it includes but is not limited to two callback methods: onTaskAppeared (ActivityManager. RunningTaskInfo info, SurfaceControl leash), and onTaskInfoChanged (ActivityManager. RunningTaskInfo info).

In some embodiments, the onTaskAppeared method is called back when the Task appears, and RunningTaskInfo is a description of the Task class, which holds the PiP parameter object. Therefore, in the onTaskAppeared method, the PiP parameters can be obtained, and then the event notification and forwarding are performed through the PiPParamsChangedForward object of the PiPTaskOrnagizer class.

In some embodiments, the OnTaskInfoChanged method is called back when the Task changes, such as when the window mode changes, or when the parameters change, etc. When adjusting the size of the PiP window, the Wmshell PiPTaskOrganizer can receive the callback by updating the PiP parameter object and calling the setPictureInPictureParams method of the page. Because onTaskInfoChanged can also get the RunningTaskInfo class, it can also get the PiP parameters, parse the PiP parameters, i.e., the screen size, and call the apply new PiP parameters (applyNewPictureInPictureParams) method to adjust the size of the PiP window. On the one hand, when executing the applyNewPictureInPictureParams method, it is determined whether the aspect ratio corresponding to the PiP parameters has changed, that is, whether the page ratio has changed. If it is determined that it has changed, the event can be forwarded through the PiPParamsChangedForwarder object. On the other hand, when executing the applyNewPictureInPictureParams method, it is determined whether the width and height corresponding to the PiP parameters have changed, that is, whether the screen size has changed. If it is determined that it has changed, the event can be forwarded through the PiPParamsChangedForwarder object.

The storage, calculation and adjustment of the PiP window of the customized screen size (PiP parameters) of the current page are explained.

The OnTaskAppeared callback of PiPTaskOrganizer can first call the setBoundsStateForEntry method to set the initial state of the PiP boundary state (PiPBoudsStates), which may include the component name (ComponentName), aspect ratio, etc. PiPBoudsStates is a state holding class for the current PiP window. It can add width and height fields by extending the attributes of PiPBoundsStates to store the width and height of the PiP window that matches the screen size, and allocate the size of the PiP window based on the stored width and height in the setBoundsStateForEntry method.

After calling the setBoundsStateForEntry method, the onTaskAppeared method can also call the PiP boundary algorithm (PiPBoudsAlgorithm) to get the target boundary of the entry (getEntryDestinationBounds) method to obtain the target position of the PiP window. The return type of this method is Rect, and the coordinates and size of the PiP window are directly specified by this method. Through the algorithm of PiPBoundsAlgorithm, judgment logic is added when calling getEntryDestinationBounds. When the PiPBoudsState object is set with a custom width and height, the width and height return the custom width and height.

After obtaining the coordinate size of the PiP window, the onTaskAppeared method specifies the scheduleAnimateResizePiP method and notifies the WindowManagerService to redraw the PiP window based on the currently requested width and height.

When adjusting the size of the PiP window, the PiPTaskOrganizer class can eventually call the applyNewPictureInPictureParams method. In some embodiments of the present application, the applyNewPictureInPictureParams method is customized, and the width and height of the PiPBoundsState are modified in the method so that the size of the PiP window can be modified to the adjusted size.

The event is forwarded through the notifyAspectRatioChanged method of PiPParamsChangedForwarder. In PiPController such as TvPiPController, you can set a callback listener for PiPParamsChangedForwarder to notify WindowManagerService to update the size of the PiP window based on the width and height of PiPBoundsState by updating the fixed task stack (updatePinnedStack) method in the notifyAspectRatioChanged method.

In some embodiments, the display device is not in the PiP mode. The display device has created a first window and a second window, and can display a first page in the first window, and a second page in the second window. The first window is in the full screen state, where the first window and the second window can be located in the same layer, and the window level of the first window can be higher than the window level of the second window. Alternatively, the display device has created a first window and a second window, and can display a first page in the first window, and can display a second page in the second window. The first window and the second window can both be in the full screen state, where the first window and the second window can be located in different layers, and the level of the layer to which the first window belongs can be higher than the level of the layer to which the second window belongs. In some embodiments, the second window can also be in the full screen state. Based on the system architecture shown in FIG. 5D, the display device can display the PiP window based on the process shown in FIG. 36, and the specific steps may include but are not limited to the following.

S3601, in response to a first control command of a user, a screen size of a first page is obtained.

The first control command may be used to indicate to enable the PiP mode.

Before obtaining the screen size of the first page, the display device determines whether to enable the PiP mode. This process is similar to steps S2601-S2602, S2701-S2702, S2801-S2802 and related contents, and will not be repeated here.

After the display device determines to enable the PiP mode, it can obtain the screen size of the first page in the PiP mode. The screen size of the first page can be a size customized by the application. If the entire first page are displayed in the PiP window, the screen size of the first page can be the size of the entire page, that is, the page size. If part of the first page is displayed in the PiP window, such as a video screen, the screen size of the first page can be the size of the video screen.

When the display device enables PiP mode, the application (such as the first application) to which the first page belongs passes the screen size of the first page in the PiP mode through the PiP tool when entering the PiP mode, thereby passing the PiP parameter object to WMS. The WMS listener is registered in Wmshell, and WMS calls back the parameter information to the registered listener Wmshell when the PiP task where the first application is located appears, thereby realizing the listening for the first application. After receiving the listening, Wmshell can obtain the PiP parameter object constructed for the size parameters passed by the first application when entering the PiP mode. The screen size of the first page can be obtained by parsing the PiP parameter object.

S3602, the first window is reduced in size and the second window is displayed based on the screen size of the first page and a size threshold of the picture-in-picture window. The aspect ratio of the reduced first window is equal to the aspect ratio of the first page, where the first page is displayed in the reduced first window, and the second page is displayed in the second window.

In some embodiments, the size threshold of the PiP window may include a width range of the PiP window, and the width range may be greater than or equal to one-third of the width of the display region of the display, and less than or equal to half of the width of the display region of the display; or the size threshold of the PiP window may include a height range of the PiP window, and the height range may be greater than or equal to one-third of the height of the display region of the display, and less than or equal to half of the height of the display region of the display; or the size threshold of the PiP window may include the width range and the height range of the PiP window. The size threshold of the PiP window may be used to prevent the PiP window from being too large or too small.

The display device can reduce the first window in size, and the reduced first window can match the screen size of the first page, that is, the aspect ratio of the reduced first window can be equal to the aspect ratio of the first page to ensure the screen ratio of the first page in the reduced first window; the reduced first window can meet the size threshold of the PiP window to avoid the size of the first window being too large or too small, affecting the user's viewing experience. After reducing the first window, the display device can expose a second window with a lower window level to enter PiP mode.

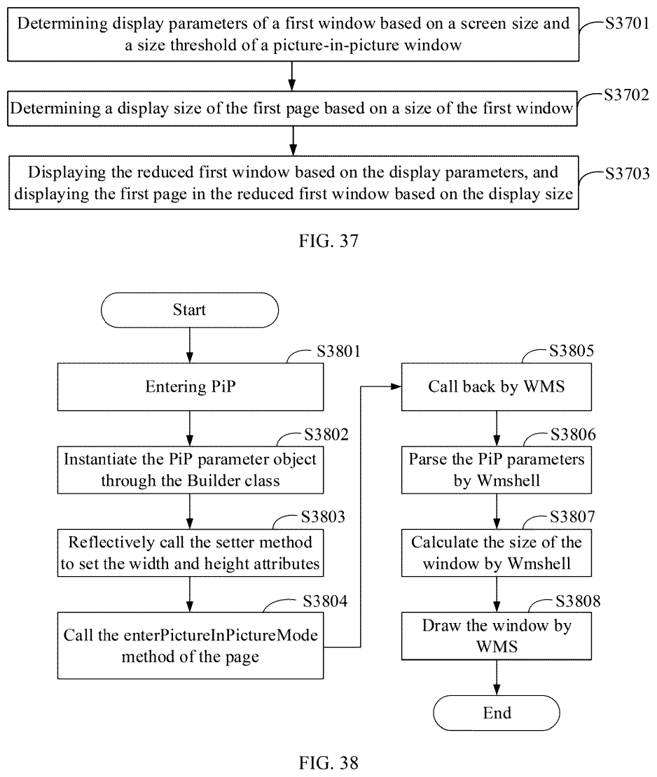

The display device may reduce the first window based on the process shown in FIG. 37, and the specific steps may include but are not limited to the following.

S3701, display parameters of a first window are determined based on a screen size and a size threshold of a picture-in-picture window.

The display parameters may include the size and display position of the reduced first window.

The display position of the reduced first window may be a preset position, such as the upper left corner, upper right corner, lower left corner, or lower right corner, etc., of the display.

The size of the reduced first window can meet the size threshold of the PiP window, and the aspect ratio thereof is equal to the aspect ratio of the first page. Based on the screen size of the first page, the required aspect ratio of the first page can be determined, and then the aspect ratio of the reduced first window can be determined. For example, the screen size of the first page can be w1×h1, then the aspect ratio of the first page can be w1/h1, and the aspect ratio of the reduced first window can also be w1/h1.

In some embodiments, if the screen size of the first page meets the size threshold of the PiP window, the size of the first window after reduction may be consistent with the screen size of the first page, that is, the width of the first window after reduction may be equal to the width of the first page, and the height of the first window after reduction may be equal to the height of the first page. For example, the screen size of the first page may be w1×h1, and if it meets the size threshold of the PiP window, the size of the first window after reduction may also be w1×h1.

In some other embodiments, if the screen size of the first page does not meet the size threshold of the PiP window, such as if the screen size of the first page is too large, the relationship between the size of the first window after reduction and the screen size of the first page may be proportional reduction. For example, if the screen size of the first page is w1×h1, which does not meet the size threshold of the PiP window, and the screen size of the first page is too large, the size of the first window after reduction may be a proportionally reduced size, such as (½*w1)×(½*h1).

In some other embodiments, if the screen size of the first page does not meet the size threshold of the PiP window, such as if the screen size of the first page is too small, the relationship between the size of the first window after reduction and the screen size of the first page may be proportionally enlarged. For example, if the screen size of the first page is w1×h1, which does not meet the size threshold of the PiP window, and the screen size of the first page is too small, the size of the first window after reduction may be a proportionally enlarged size, such as (2*w1)×(2*h1).

The display device determines the callback method. In some embodiments of the present application, the display device may determine that the callback method is a callback method for the occurrence of a task. When executing the callback method, the specific position of the first window after the reduction may be calculated based on the screen size by the PiP boundary algorithm.

S3702, a display size of the first page is determined based on a size of the first window.

In some embodiments, the display size of the first page is the size of the screen displayed in the reduced first window, and the display size matches the size of the reduced first window.

S3703, the reduced first window is displayed based on the display parameters, and the first page in the reduced first window is displayed based on the display size.

In some embodiments, the display parameters calculated by WMS can used to shrink the first window to obtain a PiP window, a second window with a lower window level can be exposed, the first page can be displayed in the first window based on the display size, and the second page can be displayed in the second window.

Based on the above method, when the PiP mode is enabled, the restrictions on the PiP window can be lifted so that the size of the PiP window matches the screen size of the page displayed therein.

In some embodiments, if the display device does not obtain the screen size of the first page, the size of the first window is reduced to a preset size.

If the display device does not obtain the screen size of the first page, it can be considered that the first page does not have a custom screen size, that is, the first page has no special requirements for the screen size. The display device can reduce the size of the first window to a preset size, which can be a width-height combination of one or more fixed width-height combinations, and the preset size can also be a width-height combination calculated based on a width or height of one or more fixed widths or heights and an aspect ratio of one or more fixed aspect ratios.

Taking a display device as a TV as an example, the process of displaying a PiP window when the display device enters the PiP mode is explained in combination with the following examples.

### Example 11

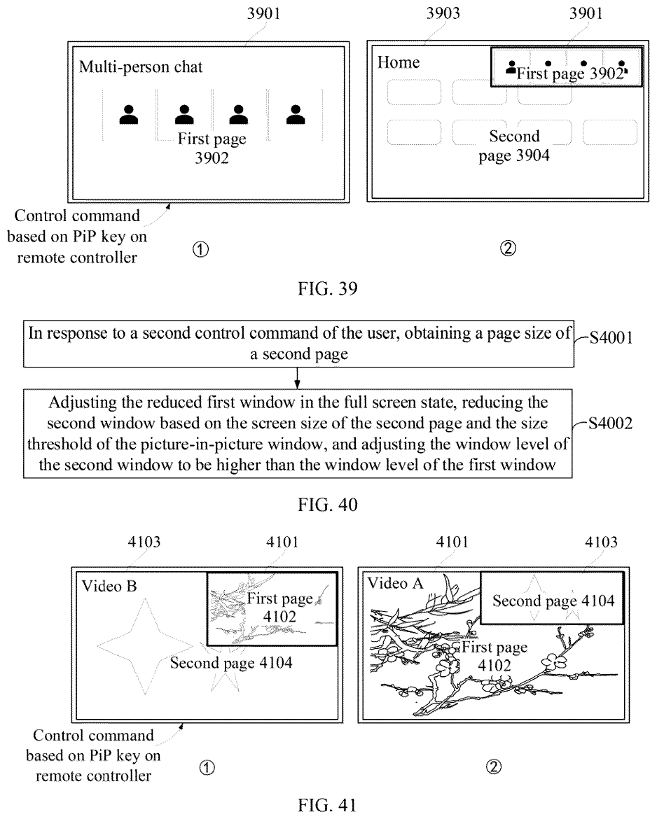

In conjunction with the process shown in FIG. 38, as shown in \textcircled{1} in FIG. 39, the TV displays a first page 3902, such as a page for multi-person chat, in a first window 3901, and displays a second page 3904 (not shown in \textcircled{1} in FIG. 39), such as a Launcher page, in a second window 3903. The first window 3901 is in the full screen state, the first window 3901 and the second window 3903 are located in the same layer, and the window level of the first window 3901 is higher than the window level of the second window 3903. As a result, the TV preferentially displays the first window 3901. The TV, in response to the first control command from the user, determines whether to enable the PiP mode. The process can refer to Examples 5-8 and will not be repeated here. If the TV determines to enable the PiP mode, the TV enters the PiP mode (S3801) and obtains the screen size of the first page 3902, such as a width of w1, a height of h1, and an aspect ratio of 21:3. Based on the screen size, the PiP parameter object (S3802) is instantiated through the Builder class. The setter method is reflectively called to set the width and height attributes (S3803). The enterPictureInPictureMode method of the page is called (S3804), WMS calls back (S3805), Wmshell parses the PiP parameters (S3806), and Wmshell calculates the display parameters of the reduced first window 3901 based on the screen size (S3807). For example, the display position of the reduced first window 3901 is in the upper middle region of the display, and the width of the reduced first window 3901 is w2 and the height thereof is h2. This size meets the size threshold of the PiP window, and w2/h2=21:3. WMS draws the window (S3808), as shown in \textcircled{2} in FIG. 39, reduces the first window 3901, and exposes the second window 3903. The reduced first window 3901 is displayed in the upper right corner. The TV displays the first page 3902 in the reduced first window 3901, the display size of the first page 3902 matching the width w2 and the height h2, and displays the second page 3904 in the second window 3903.

In some embodiments, the display device is already in the PiP mode. The display device has created a first window and a second window, and can display a first page in the first window, and a second page in the second window. The second window is in the full screen state, and the size of the first window can be smaller than the size of the second window. The first window and the second window can be located in the same layer, and the window level of the first window can be higher than the window level of the second window. Alternatively, the first window and the second window can be located in different layers, and the level of the layer to which the first window belongs can be higher than the level of the layer to which the second window belongs. Based on the system architecture shown in FIG. 5D, the display device can adjust the PiP mode based on steps S3301-S3302. At this time, the display device switches the page displayed in the PiP mode. In the process of switching the page displayed in the PiP mode, the display device can display the switched PiP window based on the process shown in FIG. 40. The specific steps may include but are not limited to the following.

S4001, in response to a second control command of the user, a page size of a second page is obtained.

The second control command may be used to indicate switching of a page displayed in the PiP mode.

S4002, the reduced first window is adjusted to be in the full screen state, the second window is reduced based on the screen size of the second page and the size threshold of the picture-in-picture window, and the window level of the second window is adjusted to be higher than the window level of the first window. The first page is displayed in the first window in the full screen state, and the second page is displayed in the reduced second window.

Steps S4001-S4002 are similar to steps S3301-S3302, where the display device obtains the screen size of the second page similarly to step S3601, and the display device reduces the second window similarly to the process of reducing the first window in step S3602, which are not repeated here.

Taking a display device being a TV as an example, the following example will be used to explain a process in which the display device displays a switched PiP window during a process in which a page displayed in the PiP mode is switched.

### Example 12

Combined with the process shown in FIG. 38, as shown in \textcircled{1} of FIG. 41, the TV displays the first page 4102, such as video page A, in the first window 4101, and displays the second page 4104, such as video page B, in the second window 4103. In this example, taking the first window 4101 and the second window 4103 being located in the same layer, and the window level of the first window 4101 being higher than the window level of the second window 4103 as an example, the second window 4103 is in the full screen state, and the size of the first window 4101 is smaller than the size of the second window 4103, that is, the first page 4102 is displayed in the PiP mode. In response to the second control command from the user, the TV determines whether to switch to the page displayed in the PiP mode. The process can refer to Examples 9-10, which will not be repeated here. If the TV determines to switch to a page displayed in the PiP mode, the TV obtains the screen size of the second page 4104, and as shown in \textcircled{2} in FIG. 41, adjusts the first window 4101 to be in the full screen state, reduces the second window 4103 in size, and adjusts the window level of the second window 4103 to be higher than the window level of the first window 4101. The aspect ratio of the reduced second window 4103 is equal to the aspect ratio of the second page 4104, and the size of the reduced second window 4103 meets the size threshold of the PiP window. The first page 4102 is displayed in the first window 4101, and the second page 4104 is displayed in the second window 4103. The process can refer to Example 11, which is not repeated here.

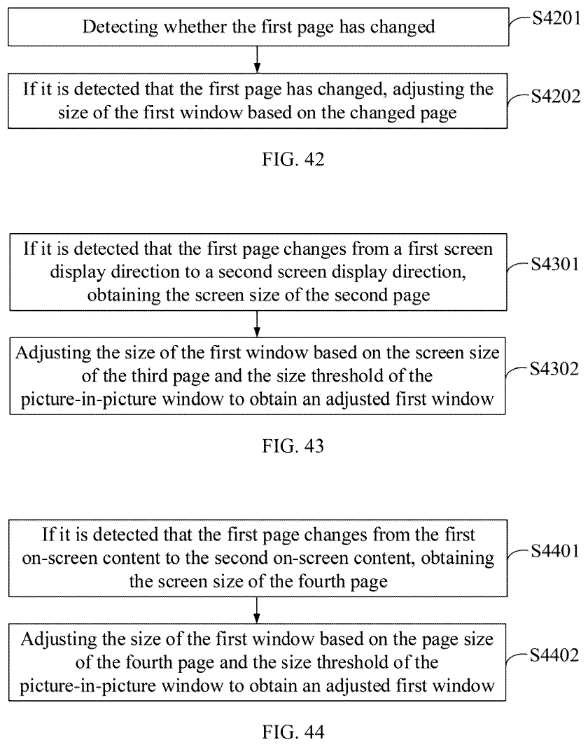

In some embodiments, the display device is already in the PiP mode, such as the display device can enter PiP mode based on steps S3601-S3602. At this time, the display device can display the first page in the first window and the second page in the second window, where the second window is in the full screen state and the size of the first window can be smaller than the size of the second window. The display device can dynamically adjust the size of the first window based on the changes of the page in the first window. The display device can adjust the size of the PiP window based on the process shown in FIG. 42, and the specific steps may include but are not limited to the following.

S4201, whether the first page has changed is detected.

The change of the first page may include a change of the screen display direction and a change of the on-screen content.

The screen display direction may include horizontal screen display and vertical screen display. In horizontal screen display, the width of the page may be greater than the height; in vertical screen display, the height of the page may be greater than the width.

Different on-screen contents require different screen sizes, such as movies and TV series require different screen sizes, and videos and multi-person chats require different screen sizes.

S4202, if it is detected that the first page has changed, the size of the first window is adjusted based on the changed page.

If it is detected that the first page has changed, it means that the current size of the first window may not match the screen size required by the changed page, which will affect the display quality of the changed page. In order to ensure the display quality of the changed page, the display device can adjust the size of the first window based on the changed page so that the size of the first window can match the screen size required by the changed page, that is, the aspect ratio of the adjusted first window can be equal to the aspect ratio of the changed page.

The display device may adjust the size of the PiP window based on the process shown in FIG. 43, and the specific steps may include but are not limited to the following.

S4301, if it is detected that the first page changes from a first screen display direction to a second screen display direction, the screen size of the second page is obtained.

The first screen display direction may be a horizontal screen display, and the second screen display direction may be a vertical screen display; or, the first screen display direction may be a vertical screen display, and the second screen display direction may be a horizontal screen display.

The third page may be a page after the first page changes to the second screen display direction, and the on-screen content of the third page may be the same as or different from that of the first page (e.g., different in page layout).

The process of the display device obtaining the screen size of the third page can refer to step S3601, which is not repeated here. If the display device determines that only the screen display direction has changed, the height of the first window before adjustment can be determined as the width of the first window after adjustment, and the width of the first window before adjustment can be determined as the height of the first window after adjustment.

S4302, the size of the first window is adjusted based on the screen size of the third page and the size threshold of the picture-in-picture window to obtain an adjusted first window.

The aspect ratio of the adjusted first window may be equal to the aspect ratio of the third page and meet the size threshold of the PiP window.

In this way, when the screen display direction of the page in the PiP window changes, the size of the PiP window can be automatically adjusted so that the size of the adjusted PiP window can match the screen size of the changed page, thereby ensuring the display quality of the changed page.

The display device may adjust the size of the PiP window based on the process shown in FIG. 44, and the specific steps may include but are not limited to the following.

S4401, if it is detected that the first page changes from the first on-screen content to the second on-screen content, the screen size of the fourth page is obtained.

The fourth page may be a page of the second on-screen content, and the screen display direction of the fourth page may be the same as that of the first page.

The process of the display device obtaining the screen size of the fourth page can refer to step S3601, which is not repeated here.

S4402, the size of the first window is adjusted based on the page size of the fourth page and the size threshold of the picture-in-picture window to obtain an adjusted first window.

The aspect ratio of the adjusted first window may be equal to the aspect ratio of the fourth page and meet the size threshold of the PiP window.

In this way, when the on-screen content of the page in the PiP window changes, the size of the PiP window can be automatically adjusted so that the adjusted size of the PiP window can match the screen size of the changed page, thereby ensuring the display quality of the changed page.

Taking a TV as an example, the process of adjusting the PiP window of the display device is explained in combination with the following examples.

### Example 13

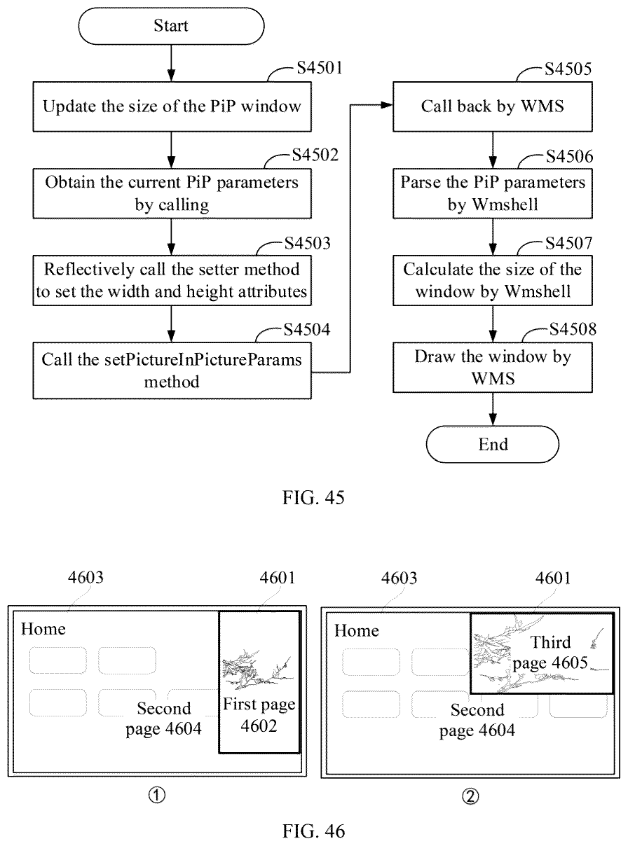

In conjunction with the process shown in FIG. 45, as shown in \textcircled{1} in FIG. 46, the TV displays a first page 4602, such as a video page A, in a first window 4601, and displays a second page 4604, such as a Launcher page, in a second window 4603. The second window 4603 is in the full screen state, and the size of the first window 4601 is smaller than the size of the second window 4603. Taking the first window 4601 and the second window 4603 being in one layer and the window level of the first window 4601 being higher than that of the second window 4602 as an example, the first page 4602 is displayed in the PiP mode. As shown in \textcircled{1} in FIG. 46, the first page 4602 is in the first screen display direction, such as a vertical display. If the TV detects that the screen display direction of the first page 4602 has changed, such as changing to a second screen display direction, such as a horizontal display, the TV can determine to adjust the size of the first window 4601, that is, update the size of the PiP window (S4501). The screen size of the third page 4605 is obtained, the current PiP parameters are obtained by calling (S4502), the setter method is reflectively called to set the width and height attributes (S4503), and the setPictureInPictureParams method is called (S4504). WMS calls back (S4505), and Wmshell parses the PiP parameters (S4506), and Wmshell calculates the size of the adjusted first window 4601 based on the screen size (S4507), such as the width of the adjusted first window 4601 is the height of the first window 4601 before adjustment, and the height of the adjusted first window 4601 is the width of the first window 4601 before adjustment. The aspect ratio of the adjusted first window 4601 is equal to the aspect ratio of the third page 4605. The WMS draws a window (S4508), as shown in \textcircled{2} in FIG. 46, and displays the adjusted first window 4601. The adjusted first window 4601 is also displayed in a horizontal screen direction, and the third page 4605 is displayed in the adjusted first window 4601.

### Example 14

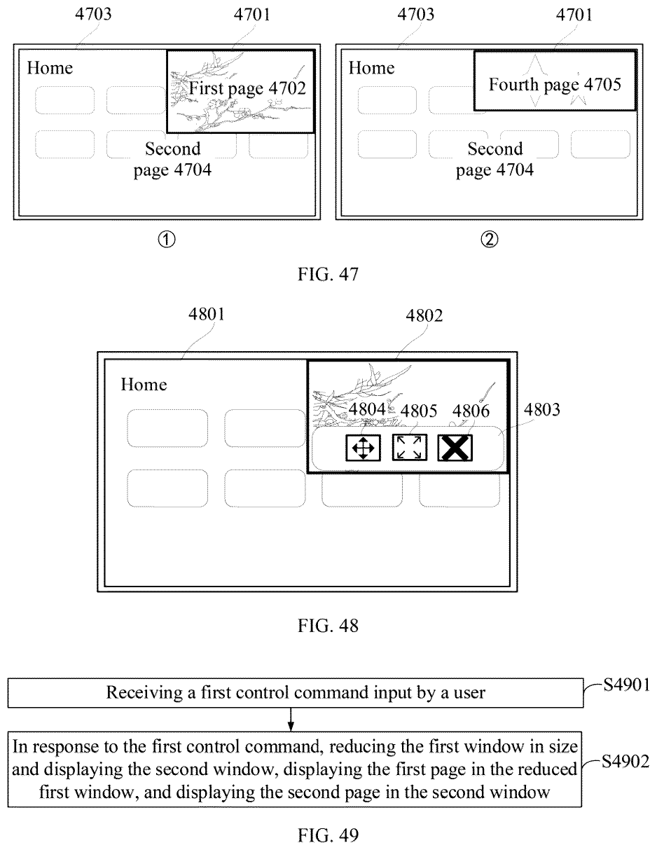

In combination with the process shown in FIG. 45, as shown in \textcircled{1} in FIG. 47, the TV displays the first page 4702, e.g., the video page A, in the first window 4701, and displays the second page 4704, e.g., the Launcher page, in the second window 4703. The second window 4703 is in the full screen state, and the size of the first window 4701 is smaller than the size of the second window 4703. For example, the first window 4701 and the second window 4703 are located in the same layer, the window level of the first window 4701 is higher than the window level of the second window 4703, and the first page 4702 is displayed in the PiP mode. As shown in \textcircled{1} in FIG. 47, the size of the first page 4702 is a width of w1 and a height of h1. If the TV detects that the on-screen content of the first page 4702 has changed, such as a change to a video page B, the TV can determine to adjust the size of the first window 4701. The screen size of the fourth page 4705, such as a width of w2 and a height of h2, is obtained. The TV adjusts the size of the first window 4701 based on the screen size of the fourth page and the size threshold of the PiP window. As shown in \textcircled{2} in FIG. 47, the width of the adjusted first window 4701 is w3, the height is h3, w3/h3=w2/h2, and the size threshold of the PiP window is met. The fourth page 4705 is displayed in the adjusted first window 4701. The process of obtaining the screen size of the fourth page 4705 and adjusting the first window 4701 based on the screen size and the size threshold of the PiP window can refer to Example 13, which is not repeated here.

When the display device displays the PiP window, it can also display a PiP menu in the PiP window. The PiP menu can be a system menu and can include a window control button. The window control button can be used to control the display state of the PiP window. The window control button may include a move button, a full screen button, a close button, etc. Taking the display device as a TV as an example, as shown in FIG. 48, when the TV displays a PiP window 4802 on a full-screen window 4801, a PiP menu 4803 can be displayed in the PiP window 4802. The PiP menu 4803 may include a move button 4804, a full screen button 4805, and a close button 4806. The user can move the display position of the PiP window 4802 based on the move button 4804; adjust the PiP window 4802 to be in the full screen state based on the full screen button 4805; and close the PiP window 4802 based on the close button 4806 to exit the PiP mode.

Since the application in the PiP window cannot obtain focus, the user cannot directly control the application in the PiP window. For example, when playing a video in the PiP window, since the PiP window cannot obtain focus, the user cannot directly control the playback of the video based on the PiP window. Based on the system architecture shown in FIG. 5E, the display device according to some embodiments of the present application can display a playback control menu in the PiP window, so that the user can directly control the playback state of the video in the PiP window based on the playback control menu.

In some embodiments, the display device is not in the PiP mode. The display device has created a first window and a second window, displays the first page in the first window, and displays the second page in the second window. The first window is in the full screen state, where the first window and the second window can be located in the same layer, and the window level of the first window can be higher than the window level of the second window, or the first window and the second window can be located in different layers, and the level of the layer to which the first window belongs can be higher than the level of the layer to which the second window belongs. The first page may belong to the first application. In some embodiments, the second window can also be in the full screen state. Based on the system architecture shown in FIG. 5E, the display device can display the PiP window based on the process shown in FIG. 49, and the specific steps may include but are not limited to the following.

S4901, a first control command input by a user is received.

The first control command can be used to indicate to enable the PiP mode. Step S4901 can refer to steps S2601, S2701-S2702, which are not repeated here. At this time, the first control command is the aforementioned control command input by the user based on the designated entry supported by the operating system. In some other embodiments, the first control command can also be a control command input through an entry provided by the application, etc. It can be understood that the input method of the first control command is not limited in the present application.

S4902, in response to the first control command, the first window is reduced in size and the second window is displayed. The first page is displayed in the reduced first window and the second page is displayed in the second window. When the first page is a video page, a playback control button is also displayed in the first window.

The process of the display device entering the PiP mode can refer to steps S2602, S2801-S2802, S3601-S3602, and S3701-S3702, which will not be repeated here.

The playback control buttons can be used to control the playback state of the video on the page in the PiP window. The playback control buttons may include a play button, a pause button, a fast forward button, a fast rewind button, etc. The playback state may include playing, paused, fast forward, fast rewind, etc.

In this way, when playing a video in the PiP window, that is, when the first page is a video page, playback control buttons can be provided in the PiP window so that the user can directly control the playback state of the video on the first page based on these playback control buttons.

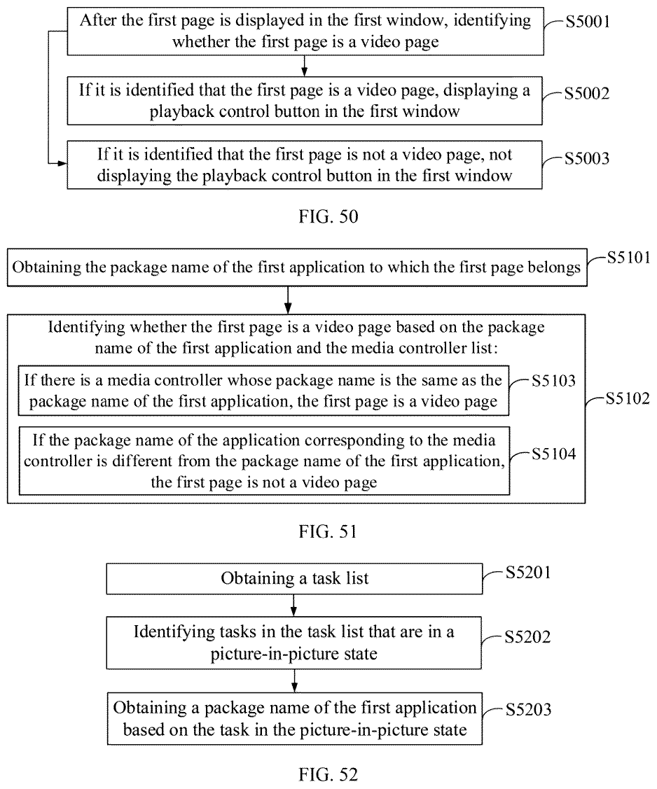

The display device may display the playback control button based on the process shown in FIG. 50, and the specific steps may include but are not limited to the following.

S5001, after the first page is displayed in the first window, whether the first page is a video page is identified.

When the display device enables the PiP mode, it first displays the first page in the reduced first window, that is, displays the first page in the PiP window. Then, the display device determines whether to display the playback control button based on whether the first page is the video page.

The display device may identify whether the first page is a video page based on the process shown in FIG. 51, and the specific steps may include but are not limited to the following.

S5101, the package name of the first application to which the first page belongs is obtained.

The display device can obtain the application of the top-level PiP window, such as the first application in the first window, through ActivityManager.

The display device may obtain the package name of the first application based on the process shown in FIG. 52, and the specific steps may include but are not limited to the following.

S5201, a task list is obtained.

The task list may include tasks that are currently running on the system.

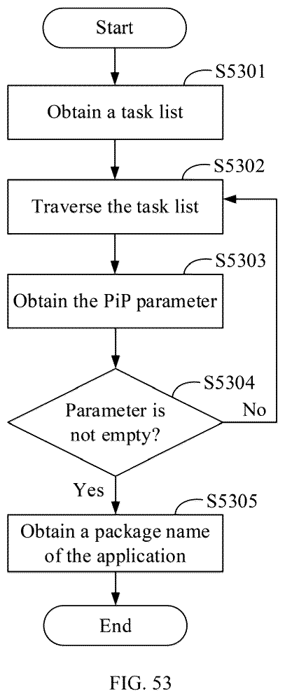

In conjunction with the process shown in FIG. 53, the display device can obtain the first application, and first needs to obtain the top-level window. The operating system provides an interface for ActivityManager obtaining the tasks that are currently running on the system (RunningTaskInfo). However, since the upper-layer application can only obtain the top-level window of the application itself, the application that the display device obtains the top-level application is a system application, such as SystemUI. In this way, the display device can obtain a task list including all application tasks (S5301).

S5202, tasks in the task list that are in a picture-in-picture state are identified.

The task in the PiP state corresponds to the first application displayed in the first window.

Still referring to the process shown in FIG. 53, after obtaining the task list, the task(s) currently in the PiP state can be determined by traversing the task list (S5302). In some embodiments, the PiP parameter of the current task can be obtained through the getPictureInPictureParams interface of the RunningTaskInfo parent class TaskInfo (S5303), and whether the task is in the PiP state can be determined based on whether the PiP parameter is empty (S5304). If the PiP parameter is not empty, it can be determined that the task is in the PiP state.

In some embodiments, if the acquired task list is empty, or there is no task in the PiP state in the task list, it means that no application is currently in the PiP mode, that is, the display device has not entered the PiP mode.

S5203, a package name of the first application is obtained based on the task in the picture-in-picture state.

The top-level page information, such as ComponentName, can be obtained through mTopActivity of TaskInfo, thereby obtaining the top-level window, such as the first window. Still referring to the process shown in FIG. 53, the package name of the application, such as the package name of the first application, in the top-level window can be obtained by calling the getPackageName method of this class (S5305), and then the application information of the first application can be obtained.

S5102, whether the first page is a video page is identified based on the package name of the first application and the media controller list.

When the application of the PiP menu enters the PiP mode, the system displays the playback control menu based on whether a video is being played, and after obtaining the package name of the first application, identifies whether the first page is a video page based on the package name of the first application and the media controller list, that is, identifies whether a video is being played.

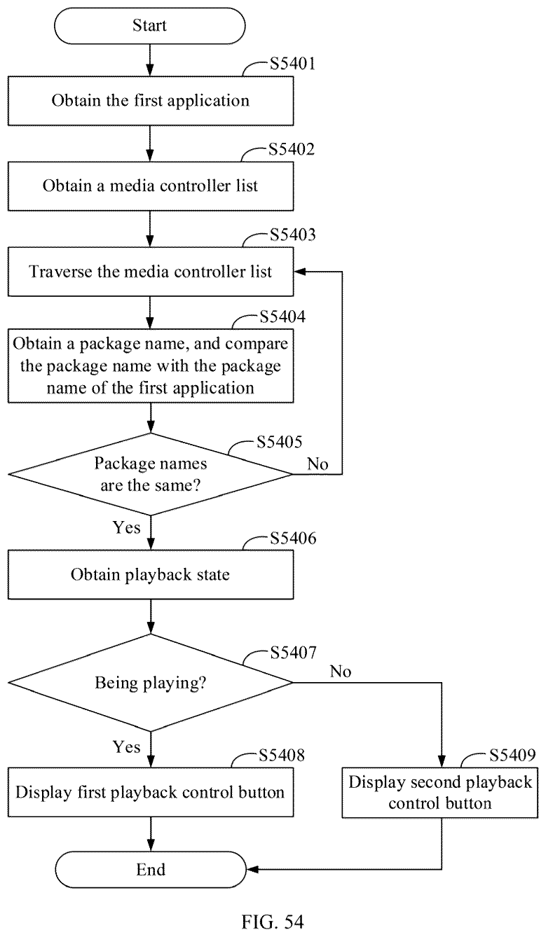

In conjunction with the process shown in FIG. 54, the process of displaying the playback control menu on the display device is explained.

The first application is obtained (S5401). An active media controller list is obtained through the MediaSessionManager. The media controller list may include a media controller for playing a video (S5402).

The media controller list is traversed (S5403), the getPackageName method of the media controller is called to obtain a package name of the corresponding application, and after obtaining the package name of the application corresponding to the media controller, the package name is compared with the package name of the first application (S5404), whether there is a package name that is the same as the package name of the first application is identified (S5405).

S5103, if there is a media controller whose package name is the same as the package name of the first application, the first page is a video page.

If there is a media controller whose application package name is the same as the package name of the first application, it means that the video played by the media controller is the video of the first application, and the first page is a video page.

S5104, if the package name of the application corresponding to the media controller is different from the package name of the first application, the first page is not a video page.

If the package name of the application corresponding to each media controller is different from the package name of the first application, it means that the video played by each media controller does not belong to the first application, and the first page is not a video page.

S5002, if it is identified that the first page is a video page, a playback control button is displayed in the first window.

If the first page is identified as a video page, it means that the video to which the first page belongs can be played and controlled. At this time, the display device can display a playback control button in the first window to provide the user with an entry for play control.

S5003, if it is identified that the first page is not a video page, the playback control button is not displayed in the first window.

If it is identified that the first page is not a video page, it means that there is no video basis for playing control. At this time, the display device does not display the playback control button in the first window to avoid affecting the normal display of the first page and avoiding misleading the user in operation.

In some embodiments, the display device may display the playback control button and the window control button within one PiP menu.

In some other embodiments, the display device may separately display the playback control button and the window control button in different PiP menus, and the different PiP menus may be displayed simultaneously or not.

In some other embodiments, the display device may display the playback control button when entering the PiP mode, and/or, display the playback control button when detecting that the focus is on the PiP window. Additionally, the display device may hide the playback control button when detecting that the playback control button is displayed for a preset time and the user has no operation on the PiP window, and/or, hide the playback control button when detecting that the focus leaves the PiP window.

In some embodiments, the display device may display the playback control button based on the playback state of the video in the PiP window, so that the displayed playback control button matches the playback state of the video, thereby providing the user with an effective playback control entry.

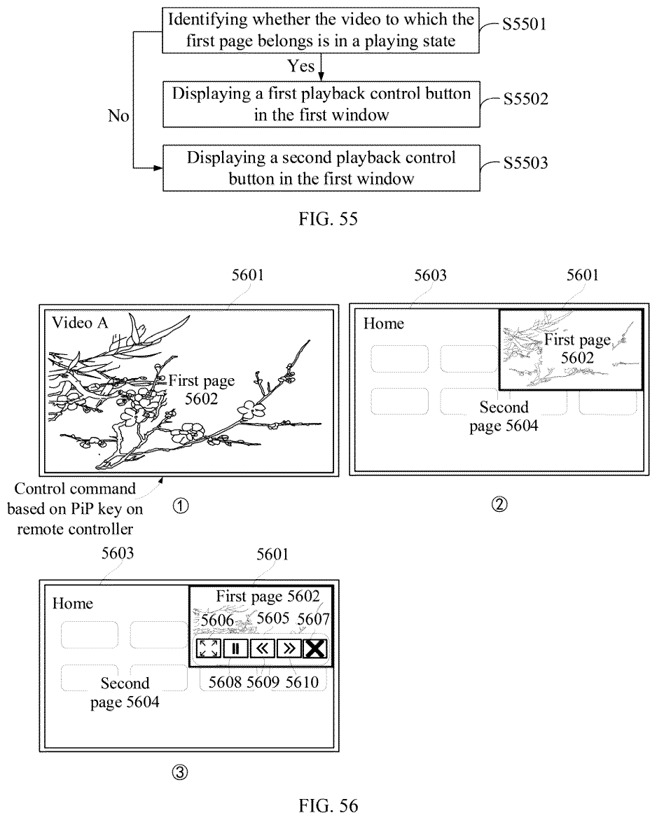

The display device may display different playback control buttons based on the process shown in FIG. 55, and the specific steps may include but are not limited to the following.

S5501, identifying whether the video to which the first page belongs is in a playing state.

In conjunction with the process shown in FIG. 54, after determining the media controller whose package name of the application is the same as the package name of the first application, the getPlaybackState method of the media controller is called to obtain the playback state of the video in the media controller (S5406). Whether the playback state is playing is determined (S5407). If the playback state is STATE_PLAYING, it means that it is in the playing state. If the playback state is STATE_PAUSED, it means that it is in the paused state, that is, it is not in the playing state. The playback control button may include a first playback control button and a second playback control button. The first playback control button can be used to control the playback state of the video in the playing state, and the first playback control button may include a pause button, a fast forward button, a fast rewind button, etc. The second playback control button can be used to control the playback state of the video that is not in the playing state, and the second playback control button may include a play button, etc.

S5502, if it is identified that the video to which the first page belongs is in a playing state, the first playback control button is displayed in the first window.

If it is identified that the video to which the first page belongs is in the playing state, the display device may display the first playback control button (S5408) and may not display the second playback control button to provide the user with an effective first playback control button, so that the user can control the video in the playing state to be paused, fast forwarded or rewound based on the first playback control button.

S5503, if it is identified that the video to which the first page belongs is not in the playing state, the second playback control button is displayed in the first window.

If it is identified that the video to which the first page belongs is not in the playing state, such as in a paused state, the display device may display the second playback control button (S5409) and may not display the first playback control button to provide the user with an effective second playback control button, so that the user can control the video in the paused state to start playing based on the second playback control button.

Taking a display device as a TV as an example, the process of displaying a PiP window on a display device is explained with reference to the following examples.

### Example 15

As shown in \textcircled{1} in FIG. 56, the TV displays a first page 5602, e.g., a video page A, in a first window 5601, and displays a second page 5604, e.g., a Launcher page, in a second window 5603 (not shown in \textcircled{1} in FIG. 56). The case where both the first window 5601 and the second window 5603 are in the full screen state, the first window 5601 and the second window 5603 are located in one layer, and the window level of the first window 5601 is higher than the window level of the second window 5603 is taken as an example. In response to the first control command from the user, the TV enters the PiP mode, as shown in \textcircled{2} in FIG. 56, shrinks the first window 5601, and exposes the second window 5603 with a lower window level. The first page 5602 is displayed in the shrunken first window 5601, and the second page 5604 is displayed in the second window 5603. The process can refer to the relevant contents in Examples 5-14, which will not be repeated here. After the TV displays the first page 5602 in the shrunken first window 5601, it identifies whether the first page 5602 is a video page. In this example, the TV can determine that the first page 5602 is a video page. The TV further identifies the playback state of the video to which the first page belongs 5602, e.g., identifying that it is in the playing state. As shown in \textcircled{3} in FIG. 56, the TV can display the PiP menu 5605 in the first window 5601, and display window control buttons, e.g., a full screen button 5606 and a close button 5607, as well as first playback control buttons, e.g., a pause button 5608, a fast forward button 5609, and a fast rewind button 5610, in the PiP menu 5605.

### Example 16

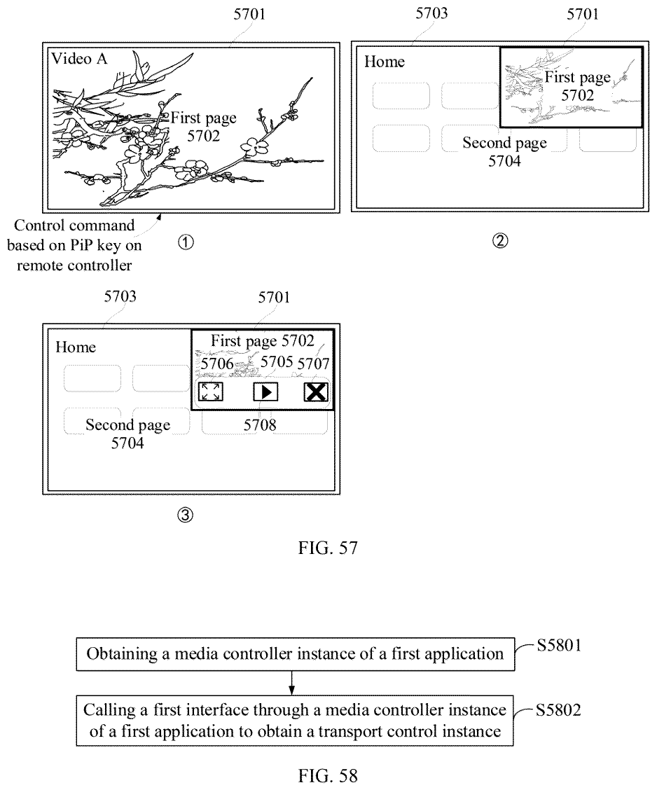

As shown in \textcircled{1} of FIG. 57, the TV displays a first page 5702, e.g., a video page A, in a first window 5701, and displays a second page 5704, e.g., a Launcher page in a second window 5703 (not shown in \textcircled{1} of FIG. 57). The case where both the first window 5701 and the second window 5703 are in the full screen state, the first window 5701 and the second window 5703 are located in the same layer, and the window level of the first window 5701 is higher than the window level of the second window 5703 is taken as an example. In response to the first control command from the user, the TV enters the PiP mode, as shown in \textcircled{2} of FIG. 57, shrinks the first window 5701, and exposes the second window 5703 with a lower window level. The first page 5702 is displayed in the shrunken first window 5701, and the second page 5704 is displayed in the second window 5703. This process can refer to the relevant content in Examples 5-14, which will not be repeated here. After the TV displays the first page 5702 in the reduced first window 5701, it identifies whether the first page 5702 is a video page. In this example, the TV can determine that the first page 5702 is a video page. The TV further identifies the playback state of the video to which the first page 5702 belongs, e.g., identifying that it is in a paused state. As shown in \textcircled{3} in FIG. 57, the TV can display a PiP menu 5705 in the first window 5701, and display window control buttons, e.g., a full screen button 5706 and a close button 5707, and a second playback control button, e.g., a play button 5708, in the PiP menu 5705.

After the display device displays the playback control buttons, corresponding playback control implementation methods can be configured for the playback control buttons so that the user can effectively control the playback state of the video in the PiP window based on these playback control buttons.

The display device can implement the playback control of the video based on the playback control button based on the process shown in FIG. 58, and the specific steps may include but are not limited to the following.

S5801, a media controller instance of a first application is obtained.

When acquiring the first application in the PiP window, the media controller instance of the first application may be acquired.

S5802, a first interface is called through the media controller instance of the first application to obtain a transport control instance.

The transport control (TranportControls) instance is allocated a value when the media controller instance of the first application is initialized to provide a second interface for the control button. The second interface can be used to call the session control instance to call the playback control operation of the media service through the session control instance.

The media controller instance can obtain the transport control instance through the getTransprotControlls interface. The transport control instance is allocated a value when the media controller instance object is initialized, can provide interfaces such as play, pause, video jump, fast forward, and fast rewind, and can internally call the session controller (IsessionController) internally to call the playback control operation of the media service.

In some embodiments, the display device may adjust the playback state of the video to which the first page belongs to the playback state corresponding to the target playback control button in response to the second control command input by the user based on the target playback control button.

For example, if the user inputs the second control command based on the pause button, the display device 200 can adjust the playback state of the video to which the first page belongs from the playing state to the paused state in response to the second control command. If the user inputs the second control command based on the play button, the display device 200 can adjust the playback state of the video to which the first page belongs from the paused state to the playing state in response to the second control command.

In some embodiments, when the playback state of the video changes, the display device may update the playback control buttons displayed in the first window to provide the user with effective playback control buttons.

If the playback state corresponding to the target playback control button is playing, the playback state of the video to which the first page belongs can be adjusted to the playing state, and the first playback control button can be hidden, and the second playback control button can be displayed.

If the playback state corresponding to the target playback control button is pausing, the playback state of the video to which the first page belongs can be adjusted to the paused state, and the second playback control button can be hidden, and the first playback control button can be displayed.

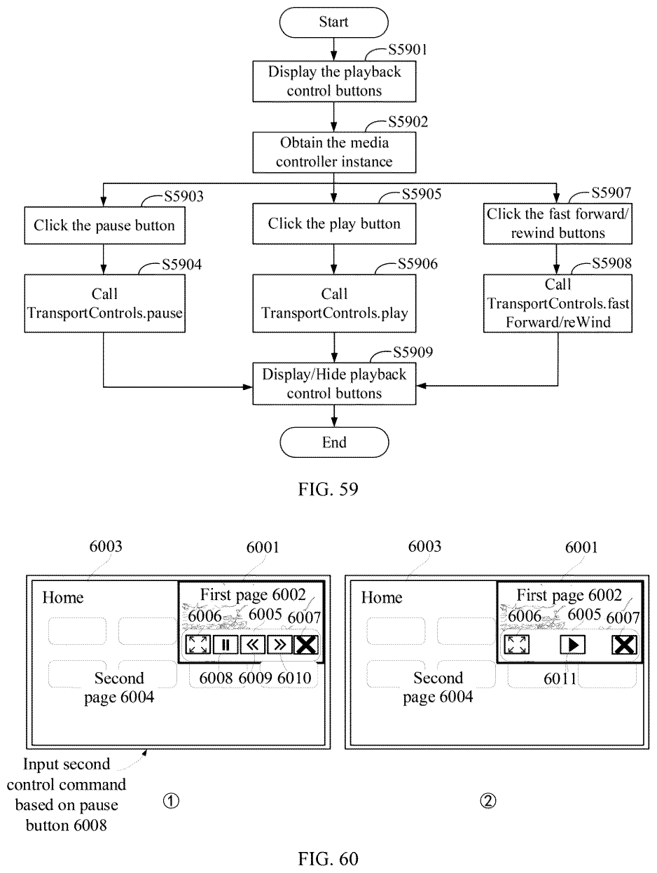

Combined with the process shown in FIG. 59, the display device can display the PiP menu in Wmshell, that is, display the playback control button (S5901), and obtain the media controller instance (S5902), when the video is in the playing state, if the user inputs the second control command based on the pause button, such as clicking the pause button (S5903), then the pause interface of MediaController. TransportControls can be called to pause the video (S5904), and the first playback control button, such as the pause button, the fast forward button, the fast rewind button, etc., can be displayed, and the second playback control button, such as the play button, etc., can be displayed (S5909). When the video is in the playing state, if the user inputs the second control command based on the fast forward button, such as clicking the fast forward button (S5907), then the fastForward interface of TransportControls can be called to fast forward the video (S5908), and when the video ends, the skipToNext interface of TransportControls can be called to jump to the next video. When the video is in the playing state, if the user inputs the second control command based on the fast rewind button, such as clicking the fast rewind button (S5907), the reWind interface of TransportControls can be called to fast rewind the video (S5908), and when the video is fast rewound to the beginning of the video, TransprotControls skipToPrevious can be called to jump to play the previous video. When the video is in the paused state, if the user inputs the second control command based on the play button, such as clicking the play button (S5905), the play interface of TransprotControls can be called to play the video (S5906), and the second playback control button, such as the play button, can be hidden, and the first playback control button, such as the pause button, the fast forward button, the fast rewind button, etc., can be displayed (S5909).

Taking a display device as a TV as an example, the process of updating a playback control button of the display device is explained in combination with the following examples.

### Example 17

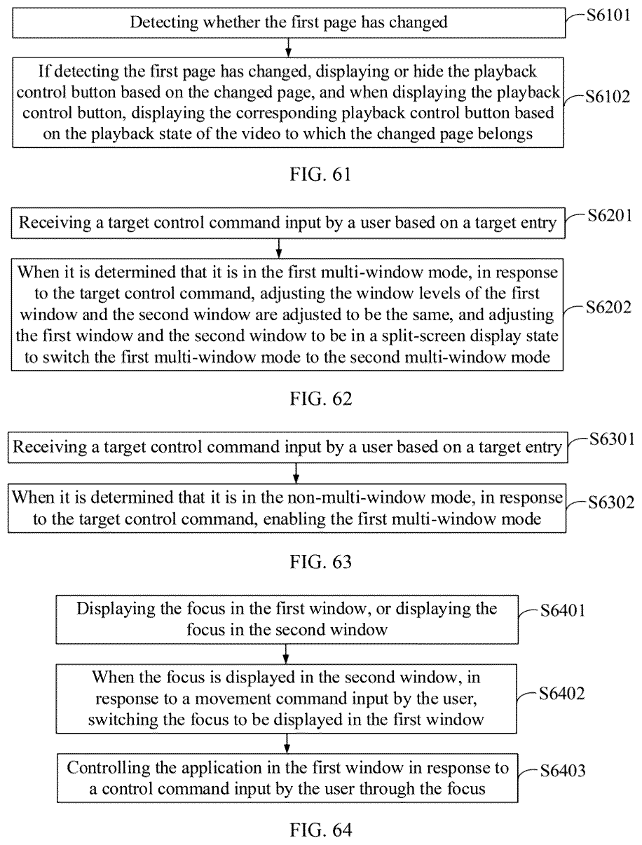

The TV can enter the PiP mode in response to the first control command based on the process shown in Example 15. As shown in \textcircled{1} in FIG. 60, the TV displays the first page 6002, such as the video page A, in the first window 6001, and displays the second page 6004, such as the Launcher page, in the second window 6003. The TV also displays the PiP menu 6005 in the first window 6001, and displays window control buttons, such as the full screen button 6006 and the close button 6007, and the first playback control buttons, such as the pause button 6008, the fast forward button 6009, and the fast rewind button 6010 in the PiP menu 6005. If the user inputs the second control command based on the pause button 6008, the TV, in response to the second control command, pauses the video and hides the pause button 6008, the fast forward button 6009, and the fast rewind button 6010, and displays the play button 6011 as shown in \textcircled{2} in FIG. 60. In some embodiments, when the page in the first window changes, the display device can update the playback control buttons displayed in the first window to provide the user with effective playback control buttons. The display device may update the playback control button based on the process shown in FIG. 61, and the specific steps may include but are not limited to the following.

S6101, whether the first page has changed is detected.

The change of the first page may include changing from a video page to a non-video page, or changing from a non-video page to a video page.

S6102, if detecting the first page has changed, the playback control button is displayed or hidden based on the changed page, and when displaying the playback control button, display the corresponding playback control button based on the playback state of the video to which the changed page belongs.

If the display device detects that the first page has changed, it can re-determine whether to display the playback control button based on the changed page, and when determining to display the playback control button, determine the playback control button to be displayed.

For example, if the first page is a video page and the display device 200 detects that the first page changes to a non-video page, the display device 200 may not display the playback control button in the first window.

For another example, if the first page is a non-video page and the display device 200 detects that the first page changes to a video page, the display device 200 may display a playback control button in the first window. If the display device 200 detects that the video to which the changed page belongs is in a playing state, the first playback control button may be displayed in the first window; and if the display device 200 detects that the video to which the changed page belongs is in a paused state, the second playback control button may be displayed in the first window.

The display device can be configured with a variety of multi-window modes, such as PiP mode and split screen mode. Since the multi-window modes cannot be switched directly, if the user wants to switch from the current multi-window mode to other multi-window modes, it is necessary to first exit the current multi-window mode, and then enable the other multi-window mode based on the enabling entry of the other multi-window mode. It can be seen that the switching process between multi-window modes is relatively cumbersome. Based on the system architecture shown in FIG. 5F, the display device based on some embodiments of the present application can provide a unified entry, so that the user can input the control command based on the unified entry, and the display device can directly switch between different multi-window modes, thereby simplifying the switching process between multi-window modes. For the convenience of subsequent description, the unified entry can be recorded as the target entry, and the control command input based on the unified entry can be recorded as the target control command.

In some embodiments, the display device is in a first multi-window mode. In the first multi-window mode, the display device can display a first window and a second window, and can display a first page in the first window and a second page in the second window. The second window is in the full screen state, and the size of the first window can be smaller than the size of the second window. The first window and the second window can be located in the same layer, and the window level of the first window can be higher than the window level of the second window, that is, the display device is in the PiP mode. Based on the system architecture shown in FIG. 5F, the display device can switch the multi-window mode based on the process shown in FIG. 62, and the specific steps may include but are not limited to the following.

S6201, a target control command input by a user is received based on a target entry.

The target entry is a designated entry supported by the operating system. The target entry may include a multi-window button (such as a global multi-screen key) on a control device, a multi-window button (such as a split-screen global key) on a virtual keyboard of a display device, and an entry in a system menu. The multi-window button corresponds to a key value, and the key value corresponds to enabling or switching the multi-window mode. In some embodiments, the system menu may be a shortcut menu, and the target entry may be an option for the multi-window mode in the shortcut menu. The target entry is unrelated to the application itself and is not affected by the application itself. Therefore, the target entry is a unified entry for enabling and switching the multi-window mode between applications.

A global multi-screen key is defined in the system PhoneWindowManager, where the global multi-screen key can be any special key, can correspond to any key value, and can be used to trigger a multi-window service. The multi-window service can be a customized service or a functional module for triggering switching of the multi-window mode.

Before the first multi-window mode is enabled, the display device is in non-multi-window mode. In non-multi-window mode, the display device has created a first window and a second window, and can display a first page in the first window, and can display a second page in the second window. The first window and the second window are both in the full screen state, where the first window and the second window can be located in the same layer, and the window level of the first window can be higher than the window level of the second window. The display device can enter the first multi-window mode based on the process shown in FIG. 63, and the specific steps may include but are not limited to the following.

S6301, a target control command input by a user is received based on a target entry.

S6302, when it is determined that it is in the non-multi-window mode, in response to the target control command, the first multi-window mode is enabled.

After receiving the target control command, the display device may first identify whether it is currently in the multi-window mode. If the display device determines that it is not in multi-window mode (i.e., in the non-multi-window mode), it may determine that the target control command indicates to enable the multi-window mode. If the display device determines that it is in multi-window mode, it may determine that the target control command indicates to switch the multi-window mode.

In some embodiments, the multi-screen service can be configured with an enabling priority for the multi-window mode. For example, when it is not in the multi-window mode, the first multi-window mode can be enabled first. When the multi-screen service determines that the current working state is not in the multi-window mode, it can reset the state to be switched, that is, the first multi-window mode, based on the enabling priority of the multi-window mode. The multi-screen service can obtain information about the first application and the second application in the Activity stack that support the multi-window mode based on the application manager. The first application can be an application in the first window, and the second application can be an application in the second window. Through the information obtained, the multi-screen service can trigger handlePictureInPicture in MultiWindowManager to enter the first multi-window mode.

The process of the display device enabling the first multi-window mode can refer to steps S2602, S3601-S3602, S4902 and related content, which will not be repeated here.

S6202, when it is determined that it is in the first multi-window mode, in response to the target control command, the window levels of the first window and the second window are adjusted to be the same, and the first window and the second window are adjusted to be in a split-screen display state to switch the first multi-window mode to the second multi-window mode.

When the display device is determined to be in the first multi-window mode, it can be determined that the target control command indicates switching the multi-window mode, i.e., switching the first multi-window mode to the second multi-window mode. The second multi-window mode can be a split-screen mode.

The multi-screen service resets the state that needs to be switched, that is, the second multi-window mode. Based on the system architecture shown in FIG. 5F, the multi-screen service can obtain the information of the first application and the second application in the Activity stack that support the multi-window mode based on the application manager. The first application can be an application in the first window, and the second application can be an application in the second window. The multi-screen service can trigger handleSplitScreen in MultiWindowManager through the information obtained to enter the second multi-window mode.

The display device can enlarge the first window in size, reduce the second window in size, and adjust the display positions of the first window and the second window so that the first window and the second window are displayed in a split-screen state. The split-screen display state of the first window and the second window can include left-right split screen or top-bottom split screen. The display device can also adjust the window levels of the first window and the second window to be the same to ensure that the first window and the second window can be displayed simultaneously in one layer.

After the display device switches to the second multi-window mode, the first page can be displayed in the first window, and the second page can be displayed in the second window. That is, during the process of switching the display device between the first multi-window mode and the second multi-window mode, the first application and the second application may never exit the multi-window mode.

When the display device is in the first multi-window mode, the application in the first window cannot obtain focus. As a result, the user cannot directly control the application in the first window, that is, cannot directly control the application in the PiP window. However, when the display device is in the second multi-window mode, the applications in the first window and the second window can both obtain focus. Based on this, the user can switch the first multi-window mode to the second multi-window mode so that the applications in the first window and the second window can obtain focus, and then the applications in the first window and the second window are controlled.

After the display device is switched from the first multi-window mode to the second multi-window mode, the application in the first window may be controlled based on the process shown in FIG. 64, and the specific steps may include but are not limited to the following.

S6401, the focus is displayed in the first window, or the focus is displayed in the second window.

After the display device switches to the second multi-window mode, applications in the first window and the second window can both obtain focus. The display device can display the focus in the first window or the second window based on a preset rule. The preset rule may include: displaying the focus in the second window first, or displaying the focus in the first window first.

S6402, when the focus is displayed in the second window, in response to a movement command input by the user, the focus is switched to be displayed in the first window.

If the display device preferentially displays the focus in the second window, the user can input a movement command to the display device to indicate to switch the focus to the first window. For example, the user can long press the global multi-screen key and input the movement command to trigger the focus behavior of the FocusManager to switch the window.

S6403, the application in the first window is controlled in response to a control command input by the user through the focus.

In the second multi-window mode, when the focus is displayed in the first window, the user can control the application based on the focus.

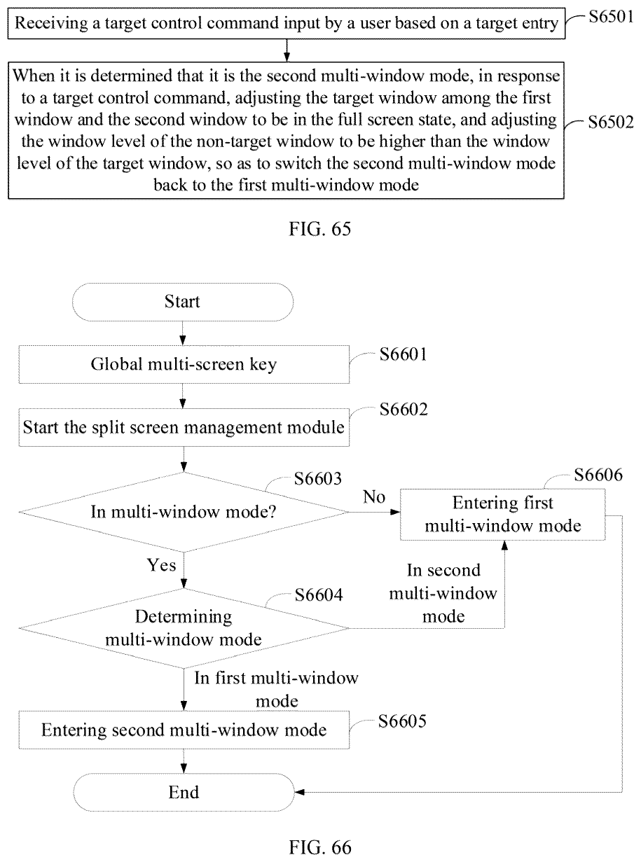

In some embodiments, the display device may switch from the second multi-window mode to the first multi-window mode based on the process shown in FIG. 65, and the specific steps may include but are not limited to the following.

S6501, a target control command input by a user is received based on a target entry.

Step S6501 can refer to step S6201 and will not be repeated here.

S6502, when it is determined that it is in the second multi-window mode, in response to a target control command, the target window among the first window and the second window is adjusted to be in the full screen state, and the window level of the non-target window is adjusted to be higher than the window level of the target window, so as to switch the second multi-window mode back to the first multi-window mode.

When the display device determines that it is in the second multi-window mode, the display device can determine that the target control command indicates switching the multi-window mode, i.e., switching the second multi-window mode to the first multi-window mode.

When the display device enters the first multi-window mode, the display device can determine a target window, and the target window can be a system default window of the first window and the second window, a window at a specified position, a window currently having focus, or a window currently not having focus, etc.

The multi-screen service resets the state that needs to be switched, that is, the first multi-window mode. Based on the system architecture shown in FIG. 5F, the multi-screen service can obtain information about the first application and the second application in the Activity stack that support the multi-window mode based on the application manager. The first application can be an application in the first window, and the second application can be an application in the second window. The multi-screen service can trigger handlePictureInPicture in MultiWindowManager through the information obtained to enter the first multi-window mode.

After the display device switches back to the first multi-window mode, the first page can be displayed in the first window, and the second page can be displayed in the second window. That is, during the process of switching the display device between the second multi-window mode and the first multi-window mode, the first application and the second application may never exit the multi-window mode.

Based on the above-mentioned process of entering the multi-window mode and switching between the multi-window modes, it can be known that the user can indicate the display device to enter the multi-window mode and directly switch between the multi-window modes based on one target entry. The user operation is simple and fast, and the multi-window mode switching efficiency of the display device is high.

Taking the display device as a TV and the control device as a remote controller, which is configured with a target entry, such as a global multi-screen key, as an example, the process of switching the display device to a multi-window mode is explained.

### Example 18

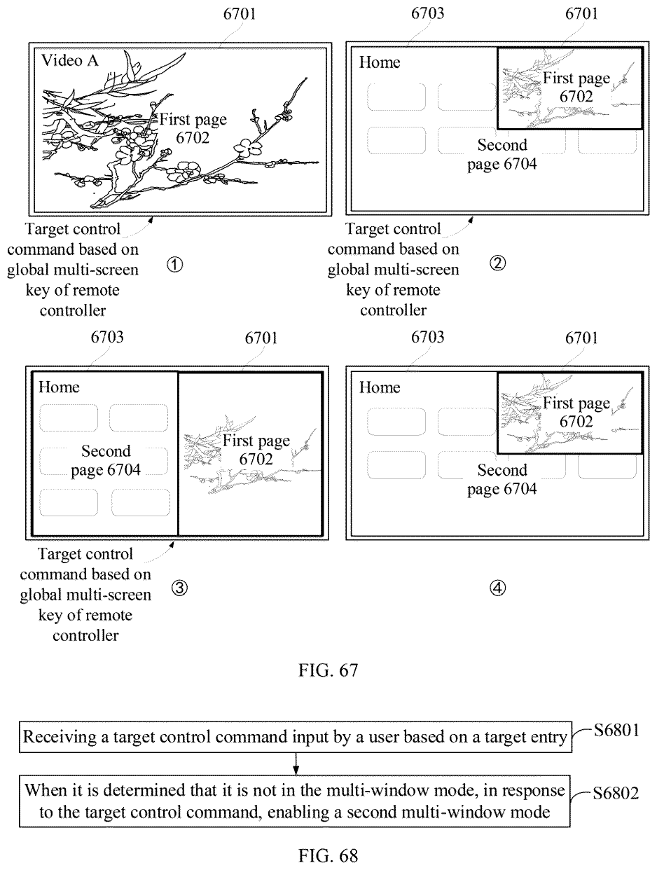

In conjunction with the process shown in FIG. 66, as shown in \textcircled{1} in FIG. 67, the TV displays a first page 6702, such as a video page A, in a first window 6701, and displays a second page 6704, such as a Launcher page, in a second window 6703 (not shown in \textcircled{1} in FIG. 67). The case where both the first window 6701 and the second window 6703 are in the full screen state, the first window 6701 and the second window 6703 are located in the same layer, and the window level of the first window 6701 is higher than the window level of the second window 6703 is taken as an example. The user can input a target control command to the TV based on the global multi-screen key of the remote controller (S6601), the TV starts the split screen management module (S6602), identifies whether it is currently in multi-window mode (S6603), and if it is identified that it is not currently in multi-window mode, determines that the target control command indicates entering multi-window mode. If the TV is configured to enable the first multi-window mode first, as shown in \textcircled{2} in FIG. 67, the TV shrinks the first window 6701, exposes the second window 6703 with a lower window level, displays the first page 6702 in the shrunken first window 6701, and displays the second page 6704 in the full-screen second window 6703, so as to enter the first multi-window mode, i.e., PiP mode (S6604). At this time, the application in the second window 6703 can obtain the focus, and the application in the first window 6701 cannot obtain the focus.

The user can input a target control command to the TV based on the global multi-screen key of the remote controller, and the TV identifies that it is currently in the first multi-window mode, and determines that the target control command indicates switching the multi-window mode, that is, switching the first multi-window mode to the second multi-window mode (S6605). As shown in \textcircled{3} in FIG. 67, the TV adjusts the window levels of the first window 6701 and the second window 6703 to be the same, and adjusts the first window 6701 and the second window 6703 to be in a split-screen display state, such as a left-right split-screen display state. The TV displays the first page 6702 in the first window 6701 and the second page 6704 in the second window 6703 to switch from the first multi-window mode to the second multi-window mode, that is, the split-screen mode. At this time, both the applications in the first window 6701 and the second window 6703 can obtain focus. If the application in the second window 6703 obtains focus first, the user can input a movement command to the TV through the remote controller to indicate the TV to switch the focus to the first window 6701 for display, and at this time, the user can control the application in the first window 6701 based on the focus.

The user can input a target control command to the TV based on the global multi-screen key of the remote controller. The TV identifies that it is currently in the second multi-window mode and determines that the target control command indicates switching the multi-window mode, i.e., switching the second multi-window mode to the first multi-window mode (S6606). The TV determines the target window, such as the TV determines the target window based on the window where the focus is located. Taking the focus in the second window 6703 as an example, the TV can determine that the second window 6703 is the target window. As shown in \textcircled{4} in FIG. 67, the TV adjusts the second window 6703 to be in the full screen state, and adjusts the window level of the first window 6701 to be higher than the window level of the second window 6703. The TV displays the first page 6702 in the first window 6701 of smaller size, and displays the second page 6704 in the second window 6703 in the full screen state to switch from the second multi-window mode back to the first multi-window mode.

In some embodiments, the display device is in a first multi-window mode. In the first multi-window mode, the display device may display a first window and a second window, and may display a first page in the first window and a second page in the second window. The second window is in the full screen state, and the size of the first window may be smaller than the size of the second window. The first window and the second window may be located in different layers, and the level of the layer to which the first window belongs may be higher than the level of the layer to which the second window belongs, that is, the display device is in the PiP mode. Based on the system architecture shown in FIG. 5F, the display device may switch the first multi-window mode to the second multi-window mode with reference to steps S6201-S6202. The display device may only adjust the sizes of the first window and the second window so that the first window and the second window are displayed side by side without adjusting the levels of the layers to which the first window and the second window belong.

In some embodiments, the display device is in a second multi-window mode. The display device can display a first window and a second window, and can display a first page in the first window and a second page in the second window. The first window and the second window can be displayed side by side, where the first window and the second window can be located in the same layer, and the window levels of the first window and the second window can be the same, that is, the display device is in a split-screen mode. Based on the system architecture shown in FIG. 5F, the display device can switch from the second multi-window mode to the first multi-window mode based on the process shown in FIG. 65, which is not repeated here.

Before enabling the second multi-window mode, the display device is in the non-multi-window mode. In the non-multi-window mode, the display device has created a first window and a second window, and can display a first page in the first window, and can display a second page in the second window. The first window and the second window are both in the full screen state, where the first window and the second window can be located in different layers, and the level of the layer to which the first window belongs can be higher than the level of the layer to which the second window belongs. The display device can enter the second multi-window mode based on the process shown in FIG. 68, and the specific steps may include but are not limited to the following.

S6801, a target control command input by a user is received based on a target entry.

S6802, when it is determined that it is not in the multi-window mode, in response to the target control command, a second multi-window mode is enabled.

In some embodiments, the multi-screen service may be configured with an enabling priority of the multi-window mode, such as when not in the multi-window mode, the second multi-window mode may be enabled first. Thus, when the multi-screen service determines that it is not in the multi-window mode, it may enter the second multi-window mode first. In the second multi-window mode, the display device may control the application in each window based on steps S6401-S6402.

When the display device enters the first multi-window mode from the second multi-window mode, the target window may be determined first, and the target window may be the main window in the first multi-window mode. The target window may be a window currently having the focus of the first window and the second window, a window currently not having focus, or a window at a specified position.

In some embodiments, the display device can switch from the first multi-window mode back to the second multi-window mode based on the process shown in FIG. 62, which is not repeated here.

Taking the display device as a TV and the control device as a remote controller, which is configured with a target entry, such as a global multi-screen key, as an example, the process of switching the display device to a multi-window mode is explained.

### Example 19

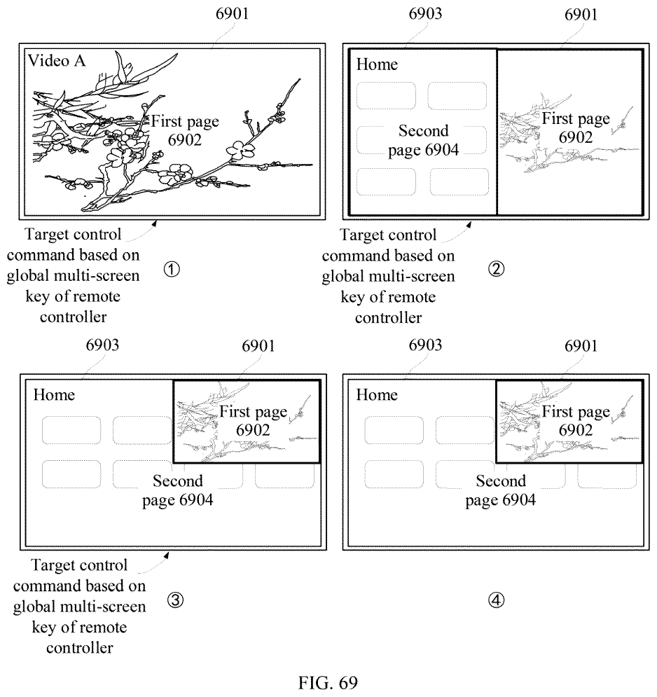

As shown in \textcircled{1} of FIG. 69, the TV displays a first page 6902, such as a video page A, in a first window 6901, and displays a second page 6904, such as a Launcher page, in a second window 6903 (not shown in \textcircled{1} of FIG. 69). The case where both the first window 6901 and the second window 6903 are in the full screen state, the first window 6901 and the second window 6903 are located in the same layer, and the window level of the first window 6901 is higher than the window level of the second window 6903 is taken as an example. The user can input a target control command to the TV based on the global multi-screen key of the remote controller, and the TV identifies that it is not currently in multi-window mode, and determines that the target control command indicates entering multi-window mode. If the TV is configured to enable the second multi-window mode first, as shown in \textcircled{2} of FIG. 69, the TV adjusts the window levels of the first window 6901 and the second window 6903 to be the same, and displays the first window 6901 and the second window 6903 in split screen. The first page 6902 is displayed in the first window 6901, and the second page 6904 is displayed in the second window 6903, so as to enter the second multi-window mode, i.e., the split-screen mode. At this time, both the applications in the first window 6901 and the second window 6903 can obtain the focus. The user can input a movement command to the TV through the remote controller to indicate the TV to switch the display focus between the first window 6901 and the second window 6903, and the user can control the application in the window with the focus based on the focus.

The user can input a target control command to the TV based on the global multi-screen key of the remote controller. The TV identifies that it is currently in the second multi-window mode and determines that the target control command indicates switching the multi-window mode, i.e., switching the second multi-window mode to the first multi-window mode. The TV determines the target window, such as the TV determines the target window based on the window where the focus is located. Taking the focus in the second window 6903 as an example, the TV can determine the second window 6903 as the target window. As shown in \textcircled{3} in FIG. 69, the TV adjusts the second window 6903 to be in the full screen state and adjusts the window level of the first window 6901 to be higher than the window level of the second window 6903. The TV displays the first page 6902 in the first window 6901 of smaller size and displays the second page 6904 in the second window 6903 in the full screen state to switch from the second multi-window mode to the first multi-window mode, i.e., PiP mode. At this time, the application in the second window 6903 can obtain focus, and the application in the first window 6901 cannot obtain focus.

The user can input a target control command to the TV based on the global multi-screen key of the remote controller. The TV identifies that it is currently in the first multi-window mode and determines that the target control command indicates switching the multi-window mode, i.e., switching the first multi-window mode to the second multi-window mode. As shown in \textcircled{4} of FIG. 69, the TV readjusts the window levels of the first window 6901 and the second window 6903 to be the same, and adjusts the first window 6901 and the second window 6903 to be in a split-screen display state, such as a left-right split-screen display state. The TV displays the first page 6902 in the first window 6901 and the second page 6904 in the second window 6903 to switch the first multi-window mode back to the second multi-window mode.

In some embodiments, the display device is in the second multi-window mode. In the second multi-window mode, the display device may display the first window and the second window side by side, and may display the first page in the first window and the second page in the second window. The first window and the second window may be located in different layers, and the level of the layer to which the first window belongs may be higher than the level of the layer to which the second window belongs, that is, the display device is in the split-screen mode. Based on the system architecture shown in FIG. 5F, the display device may switch the second multi-window mode to the first multi-window mode with reference to steps S6501-S6502. The display device may adjust the level of the layer to which the target window belongs to be higher than the level of the layer to which the non-target window belongs. For example, if the target window is the first window, the display device 200 does not need to adjust the levels of the layers to which the first window and the second window belong. If the target window is the second window, the display device 200 needs to adjust the level of the layer to which the second window belongs to be higher than the level of the layer to which the first window belongs.

For the convenience of explanation, the above description has been made in conjunction with specific embodiments. However, the above discussion in some embodiments is not intended to be exhaustive or limit the embodiments to the specific forms disclosed above. Based on the above teachings, various modifications and variations can be obtained. The selection and description of the above embodiments are intended to better explain the content of this disclosure, so that those skilled in the art can better use the embodiments.

What is claimed is:

1. A display device, comprising:
a display, configured to, in a multi-window mode, display a first window and a second window, wherein a first audio or video is played in the first window;
a memory, configured to store computer instructions and/or data associated with the display device; and
at least one processor, connected to the display and the memory, and configured to execute the computer instructions to cause the display device to:
in response to detecting that a focus is on the first window, display a volume control button in the first window, wherein the volume control button comprises a volume up key and a volume down key;
receive a control command input by a user based on the volume control button, wherein the control command indicates a first trend of adjusting a volume, and the first trend is to increase the volume or decrease the volume;
in response to the control command, identify whether an audio or video is played in the second window; and
in response to identifying that a second audio or video is played in the second window, adjust an amplitude ratio of the first audio or video based on the first trend, and adjust an amplitude ratio of the second audio or video based on a second trend opposite to the first trend, wherein a sum of the adjusted amplitude ratio of the first audio or video and the adjusted amplitude ratio of the second audio or video is equal to a preset total ratio.

2. The display device according to claim 1, wherein the at least one processor is further configured to execute the computer instructions to cause the display device to:
in response to the control command being a command input by the user single clicking the volume control button, adjust the amplitude ratio of the first audio or video in equal steps based on the first trend, and adjust the amplitude ratio of the second audio or video in the equal steps based on the second trend; and
in response to the control command being a command input by the user continuously clicking or long pressing the volume control button, adjust the amplitude ratio of the first audio or video in gradient steps based on the first trend, and adjust the amplitude ratio of the second audio or video in the gradient steps based on the second trend.

3. The display device according to claim 1, wherein the at least one processor is further configured to execute the computer instructions to cause the display device to:
in response to identifying that no audio or video is played in the second window, adjust an amplitude of the first audio or video based on the first trend.

4. The display device according to claim 1, wherein the at least one processor is further configured to execute the computer instructions to cause the display device to:
during adjusting the volume based on the first trend, when the amplitude ratio of the first audio or video reaches the preset total ratio or 0 and the control command indicates to continue adjusting the volume based on the first trend, adjust a system volume based on the first trend in response to the control command.

5. The display device according to claim 4, wherein the at least one processor is further configured to execute the computer instructions to cause the display device to:
obtain the adjusted amplitude ratio of the first audio or video and the adjusted amplitude ratio of the second audio or video;
display the adjusted amplitude ratio of the first audio or video in the first window, and display the adjusted amplitude ratio of the second audio or video in the second window; and
when the amplitude ratio of the first audio or video reaches the preset total ratio or 0 and the control command indicates to continue adjusting the volume based on the first trend, display a volume bar of the system volume in response to the control command, and adjust the system volume based on the first trend.

6. The display device according to claim 1, wherein during said adjusting the amplitude ratio of the first audio or video based on the first trend, and during said adjusting the amplitude ratio of the second audio or video based on a second trend opposite to the first trend, the at least one processor is further configured to execute the computer instructions to cause the display device to:
maintain a system volume of the display device unchanged.

7. The display device according to claim 1, wherein the at least one processor is further configured to execute the computer instructions to cause the display device to:
after switching to adjusting a system volume of the display device, in response to the control command, adjust the system volume to a specified volume based on the second trend, and switch back to adjusting the amplitude ratio of the first audio or video based on the second trend.

8. The display device according to claim 1, wherein the at least one processor is further configured to execute the computer instructions to cause the display device to:
control the first window and the second window to be located in one layer, wherein a window level of the first window is higher than a window level of the second window.

9. The display device according to claim 1, wherein the at least one processor is further configured to execute the computer instructions to cause the display device to:
control the first window and the second window to be located in different layers, wherein a level of the layer to which the first window belongs is higher than a level of the layer to which the second window belongs.

10. The display device according to claim 1, wherein the at least one processor is further configured to execute the computer instructions to cause the display device to:
control the first window to be displayed above the second window; wherein
when the multi-window mode is a picture-in-picture (PiP) mode, the second window is in a full screen state, and a size of the first window is smaller than a size of the second window; or
when the multi-window mode is a split-screen mode, the first window and the second window are displayed in a split-screen state.

11. A processing method of a display device, wherein the display device displays a first window and a second window in a multi-window mode, wherein a first audio or video is played in the first window; and the method comprises:
in response to detecting that a focus is on the first window, displaying a volume control button in the first window, wherein the volume control button comprises a volume up key and a volume down key;
receiving a control command input by a user based on the volume control button, wherein the control command indicates a first trend of adjusting a volume, and the first trend is to increase the volume or decrease the volume;
in response to the control command, identifying whether an audio or video is played in the second window; and
in response to identifying that a second audio or video is played in the second window, adjusting an amplitude ratio of the first audio or video based on the first trend, and adjusting an amplitude ratio of the second audio or video based on a second trend opposite to the first trend, wherein a sum of the adjusted amplitude ratio of the first audio or video and the adjusted amplitude ratio of the second audio or video is equal to a preset total ratio.

12. The processing method of the display device according to claim 11, wherein said adjusting the amplitude ratio of the first audio or video based on the first trend, and adjusting the amplitude ratio of the second audio or video based on the second trend opposite to the first trend, comprises:
in response to the control command being a command input by the user single clicking the volume control button, adjusting the amplitude ratio of the first audio or video in equal steps based on the first trend, and adjusting the amplitude ratio of the second audio or video in the equal steps based on the second trend; and
in response to the control command being a command input by the user continuously clicking or long pressing the volume control button, adjusting the amplitude ratio of the first audio or video in gradient steps based on the first trend, and adjusting the amplitude ratio of the second audio or video in the gradient steps based on the second trend.

13. The processing method of the display device according to claim 11, further comprising:
in response to identifying that no audio or video is played in the second window, adjusting an amplitude of the first audio or video based on the first trend.

14. The processing method of the display device according to claim 11, further comprising:
during adjusting the volume based on the first trend, when the amplitude ratio of the first audio or video reaches the preset total ratio or 0 and the control command indicates to continue adjusting the volume based on the first trend, adjusting a system volume based on the first trend in response to the control command.

15. The processing method of the display device according to claim 14, wherein said adjusting the system volume comprises:
obtaining the adjusted amplitude ratio of the first audio or video and the adjusted amplitude ratio of the second audio or video;
displaying the adjusted amplitude ratio of the first audio or video in the first window, and displaying the adjusted amplitude ratio of the second audio or video in the second window; and
when the amplitude ratio of the first audio or video reaches the preset total ratio or 0 and the control command indicates to continue adjusting the volume based on the first trend, displaying a volume bar of the system volume in response to the control command, and adjusting the system volume based on the first trend.

16. The processing method of the display device according to claim 11, further comprising:
during said adjusting the amplitude ratio of the first audio or video based on the first trend, and during said adjusting the amplitude ratio of the second audio or video based on a second trend opposite to the first trend,
maintaining a system volume of the display device unchanged.

17. The processing method of the display device according to claim 11, further comprising:
after switching to adjusting a system volume of the display device, in response to the control command, adjusting the system volume to a specified volume based on the second trend, and switching back to adjusting the amplitude ratio of the first audio or video based on the second trend.

18. The processing method of the display device according to claim 11, further comprising:
controlling the first window and the second window to be located in one layer, wherein a window level of the first window is higher than a window level of the second window.

19. The processing method of the display device according to claim 11, further comprising:
controlling the first window and the second window to be located in different layers, wherein a level of the layer to which the first window belongs is higher than a level of the layer to which the second window belongs.

20. The processing method of the display device according to claim 11, further comprising:
controlling the first window to be displayed above the second window; wherein
when the multi-window mode is a picture-in-picture (PiP) mode, the second window is in a full screen state, and a size of the first window is smaller than a size of the second window; or
when the multi-window mode is a split-screen mode, the first window and the second window are displayed in a split-screen state.
